(19) United States
(12) Patent Application Publication
(10) Pub. No.: US 2026/0353984 A1
(43) Pub. Date: Nov. 5, 2026

(54) Composition For Protective Layer, Protective Layer, And Display Device

(71) Applicant: Duk San Neolux Co., Ltd., Cheonan-si (KR)

(72) Inventors: Kyung Soo KIM, Cheonan-si (KR); Ju Cheol KWON, Cheonan-si (KR); Yeon Soo LEE, Cheonan-si (KR); Jun BAE, Cheonan-si (KR); Hyo Jung SON, Cheonan-si (KR); Do Eon KIM, Cheonan-si (KR)

(21) Appl. No.: 19/650,525

(22) Filed: Apr. 17, 2026

(30) Foreign Application Priority Data
Apr. 18, 2025 (KR) 10-2025-0051093
Apr. 3, 2026 (KR) 10-2026-0061129

(51) Int. Cl. H10K 59/80; C09D 11/38

(52) U.S. Cl. CPC H10K 59/873; C09D 11/38

(57) ABSTRACT

A composition for protective layer, a protective layer, and a display device can comprise a colorant and an oxygen-containing cyclic group, wherein the oxygen-containing cyclic group comprises a first monomer comprising an epoxy group and a second monomer comprising an oxetane group, thereby achieving high hardness after curing.

### CROSS REFERENCE TO RELATED APPLICATION

This application claims the priorities of Korean Patent Application No. 10-2025-0051093, filed on Apr. 18, 2025, and Korean Patent Application No. 10-2026-0061129, filed on Apr. 3, 2026, which are hereby incorporated by reference in their entirety for all purposes as if fully set forth herein.

### BACKGROUND

### Field

The present invention relates to a composition for protective layer, a protective layer, and a display device.

### Description of Related Art

A display panel must be protected from external impact, scratches, abrasion, and the like, and for this purpose, a protective layer may be disposed under the display panel. The protective layer plays an important role in protecting sensitive electronic components of a display device from an external environment, providing structural stability, and extending the lifespan of the display device. In particular, the hardness of the protective layer is a key physical property that determines resistance to external stimuli, and a protective layer having high hardness may be used to prevent damage caused by scratches and impact and to improve the stability and durability of the display device.

A colorant may be used to suppress light scattering and realize deep and clear black in a display panel manufacturing process. In particular, a black pigment of high optical density, such as carbon black, has a high light absorption rate to provide excellent light-shielding performance and improves the optical performance of a display device. However, a composition comprising a black pigment must maintain a stable dispersion state and must be designed to exhibit uniform coating and high hardness after curing.

### SUMMARY

Embodiments of the present invention may provide a composition for protective layer capable of forming a protective layer having high hardness after curing by comprising a colorant and an oxygen-containing cyclic group.

Embodiments of the present invention may provide a composition for protective layer capable of improving scratch and impact resistance of a protective layer.

Embodiments of the present invention may provide a composition for protective layer capable of providing stable physical properties in a manufacturing process of a display panel and improving durability and lifespan of the display panel.

Embodiments of the present invention may provide a composition for protective layer suitable for manufacturing a large-area display panel and capable of process optimization by reducing energy consumption and improving production efficiency.

Embodiments of the present invention may provide a protective layer comprising the composition for protective layer and a display device.

The problems to be solved by the embodiments of the present invention are not limited to the problems mentioned in the present specification, and other problems not mentioned will be clearly understood by those skilled in the art from the description below.

A composition for protective layer according to embodiments of the present invention may comprise a colorant and an oxygen-containing cyclic group.

The oxygen-containing cyclic group may comprise a first monomer comprising an epoxy group and a second monomer comprising an oxetane group.

The first monomer is a compound represented by Chemical Formula 1 below, and the second monomer may be a compound represented by Chemical Formula 2 below.

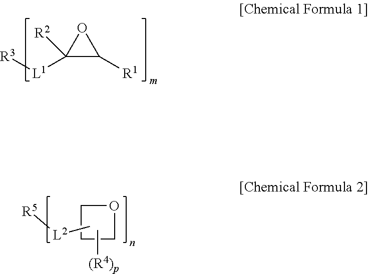

A protective layer according to embodiments of the present invention may comprise a composition for protective layer.

A display device according to embodiments of the present invention may comprise a substrate, a pixel array layer, and a protective layer disposed under the substrate.

According to embodiments of the present invention, by comprising a colorant and an oxygen-containing cyclic group, a composition for protective layer capable of forming a protective layer having high hardness and light-shielding performance after curing may be provided.

According to embodiments of the present invention, a composition for protective layer capable of improving scratch and impact resistance of a protective layer may be provided.

According to embodiments of the present invention, a composition for protective layer capable of providing stable physical properties in a manufacturing process of a display panel and improving durability and lifespan of the display panel may be provided.

According to embodiments of the present invention, a composition for protective layer suitable for manufacturing a large-area display panel and capable of process optimization by reducing energy consumption and improving production efficiency may be provided.

According to embodiments of the present invention, a protective layer and a display device comprising the composition for protective layer may be provided.

Effects of the embodiments of the present invention are not limited to the effects mentioned above, and other effects not mentioned will be clearly understood by those skilled in the art from the recitation of the claims.

### BRIEF DESCRIPTION OF THE DRAWINGS

The content of the present invention will be more completely understood from the detailed description and accompanying drawings provided below, and the detailed description and accompanying drawings are provided for explanation only and do not limit the content of the present invention.

FIG. 1 is an exemplary cross-sectional view schematically illustrating a display device according to embodiments of the present invention.

FIG. 2 is an exemplary cross-sectional view illustrating an enlarged cross-section of region A shown in FIG. 1.

FIGS. 3A and 3B are views illustrating light paths in a display device according to embodiments of the present invention and a display device according to a comparative example.

FIGS. 4A to 4D are exemplary process diagrams schematically illustrating manufacturing steps of a display device according to embodiments of the present invention.

### DETAILED DESCRIPTION

Hereinafter, some embodiments of the present invention will be described in detail with reference to exemplary drawings. In adding reference numerals to components in each drawing, the same components may have the same numerals as much as possible even if they are displayed on different drawings.

In describing the present invention, if it is determined that a detailed description of a related known configuration or function may obscure the gist of the present invention, the detailed description thereof may be omitted. When “comprises”, “has”, “consists of”, or the like mentioned in the present specification is used, another part may be added unless “only” is used. When a component is expressed in the singular, it may comprise the case of comprising the plural unless there is a special explicit description.

In describing the components of the present invention, terms such as first, second, A, B, (a), and (b) may be used. These terms are only for distinguishing the component from other components, and the essence, order, sequence, or number of the corresponding component is not limited by the terms.

In the description of the positional relationship of components, when it is described that two or more components are “connected”, “coupled”, or “joined”, it should be understood that the two or more components may be directly “connected”, “coupled”, or “joined”, but another component may be further “interposed” between the two or more components to be “connected”, “coupled”, or “joined”. Here, the other component may be included in one or more of the two or more components that are “connected”, “coupled”, or “joined” to each other.

When a component such as a layer, a film, a region, or a plate is said to be “on” or “above” another component, it should be understood that this may include not only the case where it is “directly on” the other component but also the case where another component is present therebetween. Conversely, when a component is said to be “directly on” another part, it should be understood to mean that there is no other part therebetween.

In the description of a temporal flow relationship related to components, an operation method, a manufacturing method, or the like, for example, when a temporal or flow sequence relationship is described as “after”, “following”, “next to”, “before”, or the like, a non-continuous case may be included unless “immediately” or “directly” is used.

When a numerical value or corresponding information (e.g., a level, etc.) for a component is mentioned, even if there is no separate explicit description, the numerical value or the corresponding information may be interpreted as including an error range that may occur due to various factors (e.g., process factors, internal or external shocks, noise, etc.).

Terms used in the present specification and the appended claims may be defined as follows unless otherwise stated within a range that does not depart from the spirit of the present invention.

The term “halo” or “halogen” used in the present invention comprises fluorine (F), chlorine (Cl), bromine (Br), iodine (I), and the like, unless otherwise explained, but is not limited thereto.

The term “alkyl” or “alkyl group” used in the present invention means a radical of a saturated aliphatic functional group having 1 to 60 carbons connected by a single bond, including a straight-chain alkyl group, a branched-chain alkyl group, a cycloalkyl (alicyclic) group, an alkyl-substituted cycloalkyl group, and a cycloalkyl-substituted alkyl group, unless otherwise explained, but is not limited thereto.

The term “haloalkyl group” or “halogen alkyl group” used in the present invention means an alkyl group substituted with a halogen, unless otherwise explained.

The term “alkenyl” or “alkynyl” used in the present invention has a double bond or a triple bond, respectively, comprising a straight-chain or branched-chain group, and has 2 to 60 carbon atoms, unless otherwise explained, but is not limited thereto.

The term “cycloalkyl” used in the present invention means an alkyl forming a ring having 3 to 60 carbon atoms, unless otherwise explained, but is not limited thereto.

The term “alkoxy group” or “alkyloxy group” used in the present invention means an alkyl group to which an oxygen radical is bonded, and has 1 to 60 carbon atoms unless otherwise explained, but is not limited thereto.

The term “alkenoxyl group”, “alkenoxy group”, “alkenyloxyl group”, or “alkenyloxy group” used in the present invention means an alkenyl group to which an oxygen radical is attached, and has 2 to 60 carbon atoms unless otherwise explained, but is not limited thereto.

The terms “aryl group” and “arylene group” used in the present invention each have 6 to 60 carbon atoms unless otherwise explained, but are not limited thereto. In the present invention, the aryl group or the arylene group comprises a single cyclic group, a ring assembly, a fused multi-ring system compound, and the like. For example, the aryl group may comprise a phenyl group, a monovalent functional group of biphenyl, a monovalent functional group of naphthalene, a fluorenyl group, and a substituted fluorenyl group, and the arylene group may comprise a fluorenylene group and a substituted fluorenylene group, but are not limited thereto.

The term “fused multi-ring system” used in the present invention refers to a fused ring form sharing at least two atoms, and comprises a form in which two or more hydrocarbon ring systems are fused and a form in which at least one heterocyclic system comprising at least one heteroatom is fused. Such a fused multi-ring system may be an aromatic ring, a heteroaromatic ring, an aliphatic ring, or a combination of these rings. For example, in the case of an aryl group, it may be a naphthalenyl group, a phenanthrenyl group, a fluorenyl group, or the like, but is not limited thereto.

The term “spiro compound” used in the present invention has a “spiro union”, and the spiro union refers to a connection formed by two rings sharing only one atom. In this case, the atom shared by the two rings is referred to as a “spiro atom”, and depending on the number of spiro atoms contained in one compound, these are referred to as “monospiro-”, “dispiro-”, and “trispiro-” compounds, respectively.

The terms “fluorenyl group”, “fluorenylene group”, and “fluorentriyl group” used in the present invention refer to a monovalent, divalent, or trivalent functional group, respectively, in which R¹, R², R³, and R⁴ are all hydrogen in the structure below unless otherwise explained, and “substituted fluorenyl group”, “substituted fluorenylene group”, or “substituted fluorentriyl group” means that at least one of substituents R¹, R², R³, and R⁴ is substituted with a substituent other than hydrogen, and comprises a case where R¹ and R² are bonded to each other to form a spiro compound together with the carbon to which they are bonded. In the present invention, the fluorenyl group, the fluorenylene group, and the fluorentriyl group may all be named a fluorene group regardless of the valence such as monovalent, divalent, or trivalent.

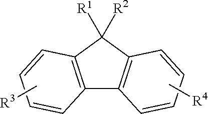

In addition, the substituents R¹, R², R³, and R⁴ may each independently be an alkyl group having 1 to 20 carbon atoms, an alkenyl group having 1 to 20 carbon atoms, an aryl group having 6 to 30 carbon atoms, or a heterocyclic group having 2 to 30 carbon atoms, but are not limited thereto. For example, the aryl group may be phenyl, biphenyl, naphthalene, anthracene, or phenanthrene, and the heterocyclic group may be pyrrole, furan, thiophene, pyrazole, imidazole, triazole, pyridine, pyrimidine, pyridazine, pyrazine, triazine, indole, benzofuran, quinazoline, or quinoxaline, but are not limited thereto. For example, the substituted fluorenyl group and the substituted fluorenylene group may be a monovalent functional group or a divalent functional group of 9,9-dimethylfluorene, 9,9-diphenylfluorene, and 9,9′-spirobi[9H-fluorene], respectively.

The term “heterocyclic group” used in the present invention comprises not only an aromatic ring such as a “heteroaryl group” or a “heteroarylene group” but also a non-aromatic ring, and refers to a ring having 2 to 60 carbon atoms each comprising one or more heteroatoms unless otherwise explained, but is not limited thereto. The term “heteroatom” used in the present invention refers to oxygen (O), nitrogen (N), sulfur (S), silicon (Si), or phosphorus (P) unless otherwise explained, but is not limited thereto. The heterocyclic group refers to a single cyclic group comprising a heteroatom, a ring assembly, a fused multi-ring system, a spiro compound, and the like, but is not limited thereto. For example, the heterocyclic group may also comprise a compound comprising a heteroatom group such as SO₂, P═O, and the like, instead of carbon forming a ring, as in the compounds below.

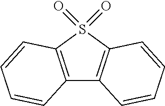 [SMILES: O=S1(=O)c2ccccc2-c2ccccc21]

The term “ring” used in the present invention comprises monocyclic and polycyclic rings, comprises a hydrocarbon ring as well as a heterocyclic group comprising at least one heteroatom, and comprises aromatic and non-aromatic rings.

The term “polycyclic” used in the present invention comprises ring assemblies such as biphenyl and terphenyl, fused multi-ring systems, and spiro compounds, comprises not only aromatic but also non-aromatic, and comprises a hydrocarbon ring as well as a heterocyclic group comprising at least one heteroatom.

The term “aliphatic ring group” used in the present invention refers to a cyclic hydrocarbon excluding aromatic hydrocarbons, and comprises a single cyclic group, a ring assembly, a fused multi-ring system, a spiro compound, and the like, and refers to a ring having 3 to 60 carbon atoms unless otherwise explained, but is not limited thereto. For example, even a case where benzene, which is an aromatic ring, and cyclohexane, which is a non-aromatic ring, are fused corresponds to an aliphatic ring.

In addition, when prefixes are named consecutively, it means that substituents are listed in the order described first. For example, an arylalkoxy group refers to an alkoxy group substituted with an aryl group, an alkoxycarbonyl group refers to a carbonyl group substituted with an alkoxy group, and an arylcarbonylalkenyl group refers to an alkenyl group substituted with an arylcarbonyl group, where the arylcarbonyl group is a carbonyl group substituted with an aryl group.

In the term “substituted or unsubstituted” used in the present invention, “substituted” means substituted with one or more substituents selected from the group consisting of deuterium, a halogen group, a hydroxy group (—OH), a nitrile group (—CN), a nitro group (—NO2), a carbonyl group (—C(═O)—), an ether group (—O—), an ester group (—C(═O)O—), a C₁-C₃₀ alkyl group, a C₁-C₃₀ alkoxy group, a C₁-C₃₀ alkylamine group, a C₁-C₃₀ alkylsilyl group, a C₁-C₃₀ alkylthiophene group, a C₂-C₃₀ alkenyl group, a C₂-C₃₀ alkynyl group, a C₃-C₃₀ cycloalkyl group, a C₆-C₃₀ aryl group, a C₆-C₃₀ aryloxy group, a C₆-C₃₀ arylamine group, a C₆-C₃₀ arylsilyl group, a C₆-C₃₀ arylthiophene group, a C₆-C₃₀ aryl group substituted with deuterium, a C₇-C₃₀ arylalkyl group, a C₈-C₃₀ arylalkenyl group, a silane group, a siloxane group, a boron group, a thiol group, a germanium group, and a C₂-C₃₀ heterocyclic group comprising at least one heteroatom selected from the group consisting of O, N, S, Si, and P, but is not limited to these substituents.

The term “substituted” used in the present invention may comprise a case of being continuously substituted with one or more substituents selected from the above-described substituents. For example, a substituted substituent may be further substituted with one or more substituents selected from the above-described substituents, and may comprise a case where the further substituted substituent is further substituted with one or more substituents selected from the above-described substituents.

In the present invention, a “functional group name” corresponding to an aryl group, an arylene group, a heterocyclic group, and the like exemplified as examples of each symbol and its substituent may be described as a “name of a functional group reflecting valence”, but may also be described as a “parent compound name”. For example, in the case of “phenanthrene”, which is a type of aryl group, the name of the group may be described by distinguishing the valence, such as a monovalent “group” being “phenanthryl (group)” and a divalent group being “phenanthrylene (group)”, but may also be described as “phenanthrene”, which is the parent compound name, regardless of the valence.

Similarly, in the case of pyrimidine, it may be described as “pyrimidine” regardless of the valence, or may be described as a “name of a group” of the corresponding valence, such as pyrimidinyl (group) in the case of monovalent and pyrimidinylene (group) in the case of divalent. Therefore, in the present invention, when the type of substituent is described as a parent compound name, it may refer to an n-valent “group” formed by the elimination of a hydrogen atom bonded to a carbon atom and/or a heteroatom of the parent compound.

In the present disclosure, numbers or alphabets indicating positions may be omitted when describing compound names or substituent names. For example, pyrido[4,3-d]pyrimidine may be described as pyridopyrimidine, benzofuro[2,3-d]pyrimidine as benzofuropyrimidine, and 9,9-dimethyl-9H-fluorene as dimethylfluorene. Accordingly, both benzo[g]quinoxaline and benzo[f]quinoxaline may be described as benzoquinoxaline.

Further, unless explicitly stated otherwise, the chemical formulas used in the present disclosure are applied identically to the definitions of substituents by the index definitions of the chemical formulas below.

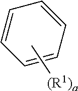

Here, when ‘a’ is an integer of 0, it means that the substituent R¹ is absent. That is, when ‘a’ is 0, it means that hydrogen atoms are all bonded to the carbon atoms forming a benzene ring, and in this case, the indication of hydrogen bonded to carbon may be omitted when describing a chemical formula or a compound. Further, when ‘a’ is an integer of 1, one substituent R¹ is bonded to any one of the carbon atoms forming the benzene ring. When ‘a’ is an integer of 2 or 3, for example, it may be bonded as shown below. When ‘a’ is an integer of 4 to 6, it may also be bonded to the carbon atoms of the benzene ring in a similar manner. When ‘a’ is an integer of 2 or more, the R¹ groups may be the same or different from each other.

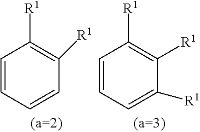

In the present disclosure, unless otherwise specified, forming a ring means that adjacent groups are bonded to each other to form a single ring or multiple fused rings. The single ring and the formed multiple fused rings comprise hydrocarbon rings as well as heterocyclic groups comprising at least one heteroatom, and may comprise aromatic and non-aromatic rings.

Further, in the present disclosure, unless otherwise specified, when indicating a fused ring, the number in ‘number-fused ring’ indicates the number of rings that are fused. For example, a form in which three rings are fused to each other, such as anthracene, phenanthrene, and benzoquinazoline, may be denoted as a 3-fused ring.

Meanwhile, the term “bridged bicyclic compound” as used in the present disclosure, unless otherwise specified, refers to a compound in which two rings share three or more atoms to form a ring. In this case, the shared atoms may comprise carbon or a heteroatom.

In the present disclosure, a display device may be implemented in various forms. For example, the display device may comprise an organic light-emitting diode (OLED) display, a liquid crystal display (LCD), an e-ink display, a microLED display, and a quantum dot (QD) display. Further, such a display device may be provided in various forms, such as not only a flat display but also a curved, flexible, foldable, or rollable display. Furthermore, special purpose displays such as small displays for wearable devices, head-up displays (HUD) for vehicles, head-mounted displays (HMD) for augmented reality (AR) and virtual reality (VR), and transparent displays may also be comprised.

In the present disclosure, an electronic device may refer to a panel comprising the display device described above, or may comprise a panel and a circuit. For example, the electronic device may comprise personal electronic devices such as a smartphone, a tablet, a laptop, and a desktop computer, and may also comprise large electronic devices such as a television, a monitor, and digital signage. Further, special purpose electronic devices such as vehicle electronic devices like a head-up display (HUD) and an instrument panel display for automobiles, wearable devices (e.g., smartwatches), head-mounted displays (HMD) for virtual reality (VR) and augmented reality (AR) devices, medical monitors, and industrial control panels may also be comprised.

Hereinafter, embodiments of the present disclosure will be described in detail. However, these are presented as examples, and the present disclosure is not limited thereby, but is defined only by the scope of the claims described later.

A composition for protective layer according to embodiments of the present disclosure may comprise a colorant and an oxygen-containing cyclic group.

The composition for protective layer may be applied to a protective layer provided at a lower portion of a display panel. The protective layer may comprise the composition for protective layer in a cured form. For example, the protective layer may be provided at a lower portion of a substrate comprised in the display panel.

If the protective layer provided at the lower portion of the display panel does not have sufficient hardness and durability, it may not effectively protect the display panel from external impact, scratches, and abrasion. Further, if a black pigment is comprised in a composition forming the protective layer to maintain optical characteristics of the display panel, there may be a problem of reduced dispersibility and coating properties.

A colorant may suppress light scattering and realize deep and clear black. A composition for protective layer comprising the colorant may be applied to a protective layer of the display panel to minimize light reflection due to internal light at a lower portion of the display panel, thereby preventing color interference and oxidation of electrodes.

An oxygen-containing cyclic group may improve chemical stability and mechanical strength of the composition for protective layer. The oxygen-containing cyclic group increases the hardness of the composition for protective layer during a curing process, thereby enhancing resistance to external impact and scratches, and may provide thermal and chemical resistance in a manufacturing process of a display device. The oxygen-containing cyclic group may also improve the durability of the composition for protective layer, thereby ensuring long-term stability.

The composition for protective layer may be formed on a lower surface of a substrate by a printing technique. The printing technique may enable precise pattern formation and mass production. For example, the printing technique may include a screen printing method or an inkjet printing method. The screen printing method or the inkjet printing method may uniformly apply the composition for protective layer comprising the colorant and the oxygen-containing cyclic group to the substrate, and rapid curing is possible at a low temperature. Such a printing technique provides compatibility with various substrate materials, and may reduce energy consumption and increase production efficiency.

Hereinafter, each component will be described in detail.

### 1. Protective Layer Composition

A composition for protective layer according to embodiments of the present invention may comprise a colorant and an oxygen-containing cyclic group.

The composition for protective layer each independently comprises components to be described later.

### (1) Colorant

In embodiments of the present invention, the composition for protective layer may comprise a colorant. The colorant may comprise a black pigment.

For example, the black pigment may include lactam black, aniline black, perylene black, titanium black, carbon black, and the like, but is not limited thereto.

The black pigment may be used together with a color corrector such as an anthraquinone-based pigment, a perylene-based pigment, a phthalocyanine-based pigment, an azo-based pigment, and the like.

The colorant in the composition for protective layer may further comprise a dye. For example, the dye may comprise a phthalocyanine-based compound.

The pigment and the dye may be used alone or in combination of two or more thereof, but are not limited thereto.

Among these, a black pigment may be used to efficiently perform light blocking of the protective layer. When the black pigment is used, it may also be used together with a color corrector such as an anthraquinone-based pigment, a perylene-based pigment, a phthalocyanine-based pigment, an azo-based pigment, and the like.

A dispersant may be used together to disperse the pigment in the composition for protective layer. Specifically, the pigment may be used after being surface-treated with the dispersant in advance, or the dispersant may be added and used together with the pigment when preparing the composition for protective layer.

As the dispersant, a nonionic dispersant, an anionic dispersant, a cationic dispersant, or the like may be used. For example, the dispersant may include polyalkylene glycol and esters thereof, polyoxyalkylene, polyhydric alcohol ester alkylene oxide adducts, alcohol alkylene oxide adducts, sulfonic acid esters, sulfonates, carboxylic acid esters, carboxylates, alkylamide alkylene oxide adducts, alkylamines, and the like, and these may be used alone or in combination of two or more thereof.

Examples of commercially available products of the dispersant include DISPERBYK-101, DISPERBYK-130, DISPERBYK-140, DISPERBYK-160, DISPERBYK-161, DISPERBYK-162, DISPERBYK-163, DISPERBYK-164, DISPERBYK-165, DISPERBYK166, DISPERBYK-170, DISPERBYK-171, DISPERBYK-182, DISPERBYK-2000, and DISPERBYK-2001 from BYK; EFKA-47, EFKA-47EA, EFKA-48, EFKA-49, EFKA-100, EFKA-400, and EFKA-450 from EFKA Chemical; Solsperse 5000, Solsperse 12000, Solsperse 13240, Solsperse 13940, Solsperse 17000, Solsperse 20000, Solsperse 24000GR, Solsperse 27000, and Solsperse 28000 from Zeneca; or PB711 and PB821 from Ajinomoto.

The dispersant may be comprised in an amount of 0.1 wt % to 15 wt % based on a total weight of the composition for protective layer. When the dispersant is comprised within the above-described range, stability, developability, and flatness are excellent during manufacture of the protective layer as dispersibility of the composition is excellent.

A pigment may be pre-treated and used. When the pigment is pre-treated and used, the average particle diameter of the pigment may be refined.

The pre-treatment may be performed through a step of kneading the pigment with a water-soluble inorganic salt and a wetting agent, and a step of filtering and washing the pigment obtained in the kneading step.

The kneading may be performed at a temperature of 40 °C to 100 °C, and the filtration and washing may be performed by washing the inorganic salt using water or the like, and then filtering.

Examples of the water-soluble inorganic salt include, but are not limited to, sodium chloride, potassium chloride, and the like.

The wetting agent may serve as a medium in which the pigment and the water-soluble inorganic salt are uniformly mixed, and the pigment may be easily pulverized. For example, the wetting agent may comprise an alkylene glycol monoalkyl ether such as ethylene glycol monoethyl ether, propylene glycol monomethyl ether, diethylene glycol monomethyl ether, and the like; an alcohol such as ethanol, isopropanol, butanol, hexanol, cyclohexanol, ethylene glycol, diethylene glycol, polyethylene glycol, glycerin polyethylene glycol, and the like. These may be used alone or in a mixture of two or more.

The pigment that has undergone the kneading step may have an average particle diameter of 20 nm to 110 nm. When the average particle diameter of the pigment is within the above-described range, a clear coating layer with excellent heat resistance and light resistance may be effectively formed.

The pigment may be comprised in an amount of 1 to 40 wt %, more specifically 2 to 30 wt %, or 3 to 20 wt %, or 5 to 15 wt %, or 7 to 12 wt %, or 7 to 10 wt % with respect to the total amount of the composition for protective layer. When the pigment is comprised within the above-described range, excellent color reproducibility, curability, and adhesion of the coating layer are achieved.

### (2) Monomer

In embodiments of the present disclosure, the composition for protective layer may comprise a monomer. The monomer may comprise different monomers comprising oxygen and a cyclic group. The monomer may comprise a first monomer comprising an oxygen-containing cyclic group and a second monomer comprising an oxygen-containing cyclic group. For example, the monomer may comprise a first monomer comprising an epoxy group and a second monomer comprising an oxetane group. The first monomer may be a compound represented by the following Chemical Formula 1.

### [Chemical Formula 1]

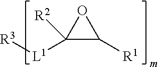

The symbols described in Chemical Formula 1 may be defined as follows.

m may be an integer from 1 to 4.

R¹ and R² may each independently be selected from the group consisting of hydrogen; deuterium; a carbonyl group; an ether group; an ester group; a C₁-C₃₀ alkyl group; a C₂-C₃₀ alkenyl group; a C₂-C₃₀ alkynyl group; a C₃-C₃₀ cycloalkyl group; a C₁-C₃₀ alkoxy group; a C₁-C₃₀ alkylamine group; a C₆-C₃₀ aryl group; a C₂-C₃₀ heterocyclic group comprising at least one heteroatom selected from O, N, S, Si, and P; a C₆-C₃₀ aryloxy group; a C₆-C₃₀ arylamine group; and combinations thereof.

R³ may be selected from the group consisting of hydrogen; deuterium; a carbonyl group; an ether group; an ester group; a C₁-C₃₀ alkyl group; a C₂-C₃₀ alkenyl group; a C₂-C₃₀ alkynyl group; a C₃-C₃₀ cycloalkyl group; a C₁-C₃₀ alkoxy group; a C₁-C₃₀ alkylamine group; a C₆-C₃₀ aryl group; a C₂-C₃₀ heterocyclic group comprising at least one heteroatom selected from O, N, S, Si, and P; a C₆-C₃₀ aryloxy group; a C₆-C₃₀ arylamine group; and combinations thereof.

L¹ may be selected from the group consisting of a single bond; a carbonyl group; an ether group; an ester group; a C₁-C₃₀ alkylene group; a C₂-C₃₀ alkenylene group; a C₂-C₃₀ alkynylene group; a C₃-C₃₀ cycloalkylene group; a C₃-C₃₀ cycloalkenylene group; a C₁-C₃₀ alkoxylene group; a C₁-C₃₀ alkylamine group; a C₆-C₃₀ arylene group; a C₂-C₃₀ heterocyclic group comprising at least one heteroatom selected from O, N, S, Si, and P; a C₆-C₃₀ aryloxy group; a C₆-C₃₀ arylamine group; and combinations thereof.

R¹ and L¹ may be bonded to each other to form a ring.

In R¹ to R³ and L¹, the alkyl group, alkenyl group, alkynyl group, cycloalkyl group, alkoxy group, alkylamine group, aryl group, heterocyclic group, aryloxy group, arylamine group, alkylene group, alkenylene group, alkynylene group, cycloalkylene group, cycloalkenylene group, alkoxylene group, and arylene group may each independently be substituted with one or more substituents selected from the group consisting of deuterium, a halogen group, a hydroxy group, a nitrile group, a nitro group, a C₁-C₃₀ alkyl group, a C₁-C₃₀ alkoxy group, a C₁-C₃₀ alkylamine group, a C₁-C₃₀ alkylsilyl group, a C₁-C₃₀ alkylthiophene group, a C₂-C₃₀ alkenyl group, a C₂-C₃₀ alkynyl group, a C₃-C₃₀ cycloalkyl group, a C₆-C₃₀ aryl group, a C₆-C₃₀ aryloxy group, a C₆-C₃₀ arylamine group, a C₆-C₃₀ arylsilyl group, a C₆-C₃₀ arylthiophene group, a C₆-C₃₀ aryl group substituted with deuterium, a C₇-C₃₀ arylalkyl group, a C₈-C₃₀ arylalkenyl group, a silane group, a siloxane group, a boron group, a thiol group, a germanium group, and a C₂-C₃₀ heterocyclic group, and the substituted substituent may be further substituted with one or more substituents selected from the substituents. For example, these substituted substituents may be additionally substituted with one or more substituents selected from the substituents, and the additionally substituted substituent may be further substituted with one or more substituents selected from the substituents.

The compound represented by Chemical Formula 1 may be one or more of the following compounds.

The first monomer may be one or more of compounds represented by Chemical Formulas P-1-1 to P-1-140 below.

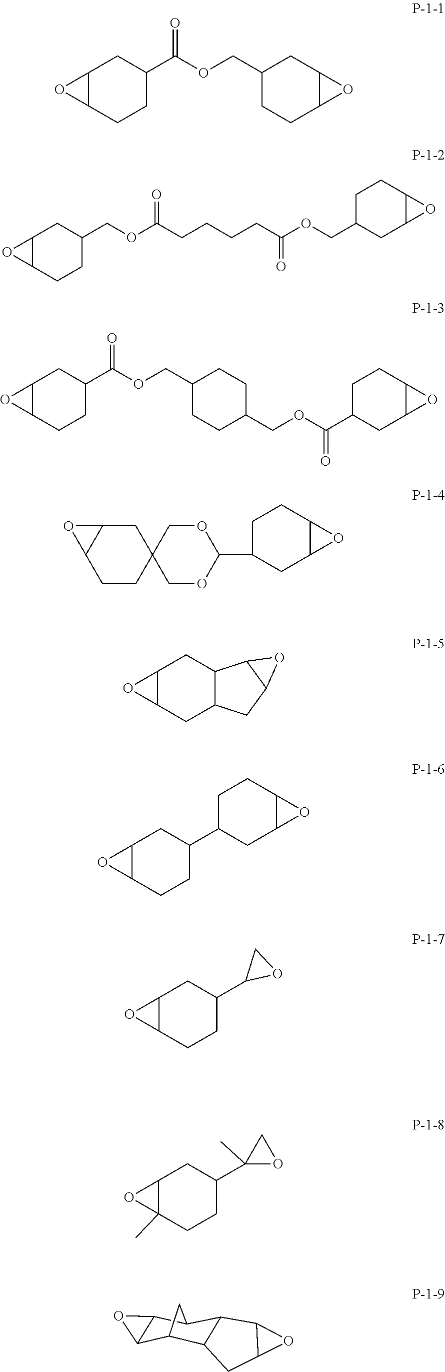

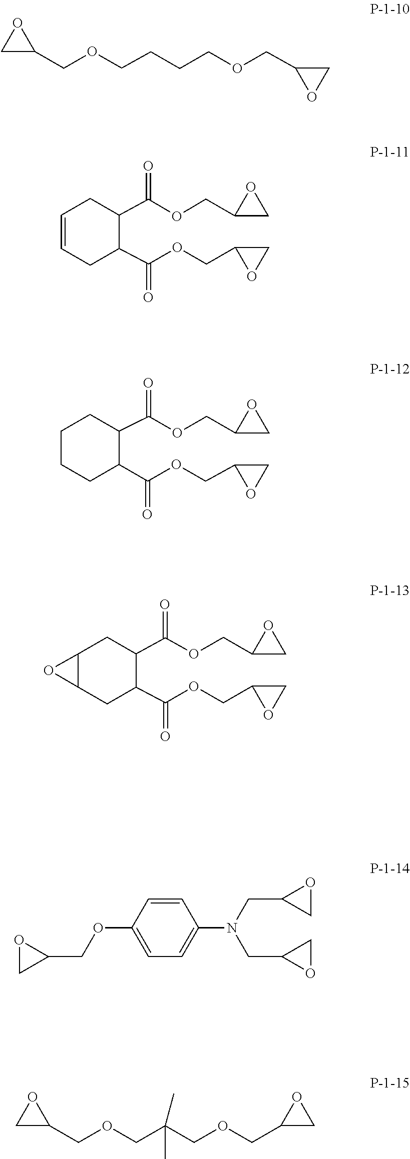

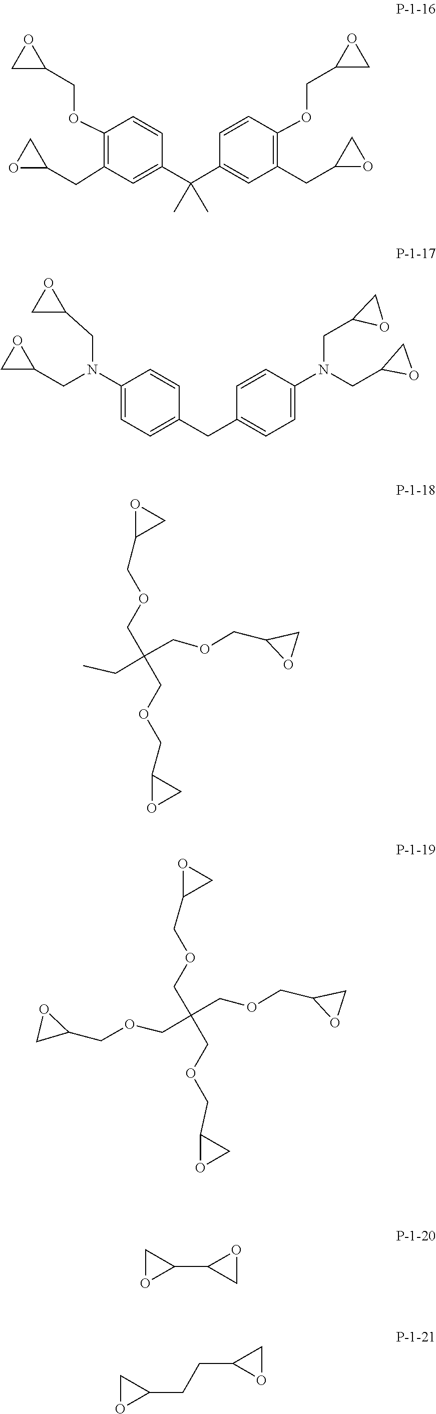 [SMILES: CC(C)(c1ccc(OCC2CO2)c(CC2CO2)c1)c1ccc(OCC2CO2)c(CC2CO2)c1 ; c1cc(N(CC2CO2)CC2CO2)ccc1Cc1ccc(N(CC2CO2)CC2CO2)cc1 ; CCC(COCC1CO1)(COCC1CO1)COCC1CO1 ; C(OCC(COCC1CO1)(COCC1CO1)COCC1CO1)C1CO1 ; C1OC1C1CO1 ; C(CC1CO1)C1CO1]

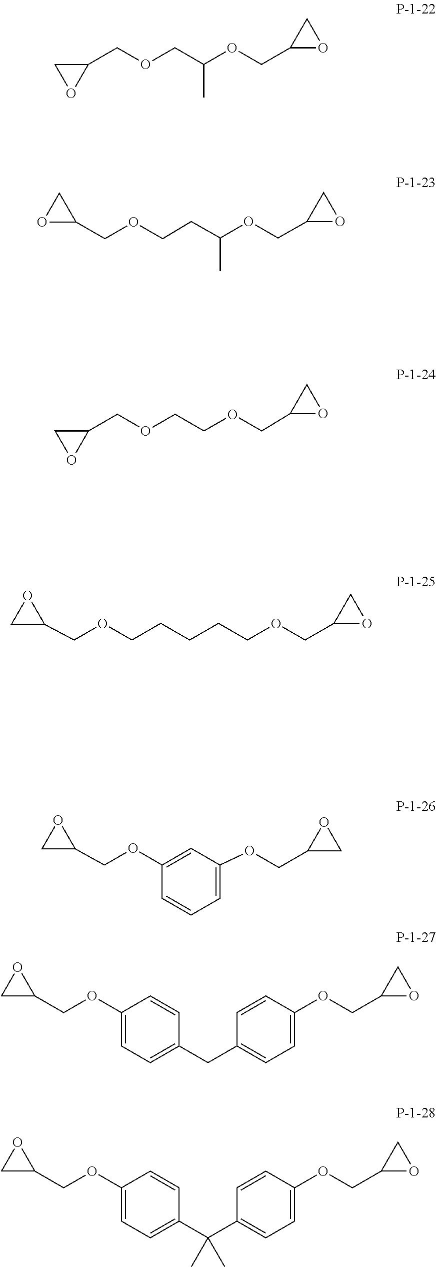

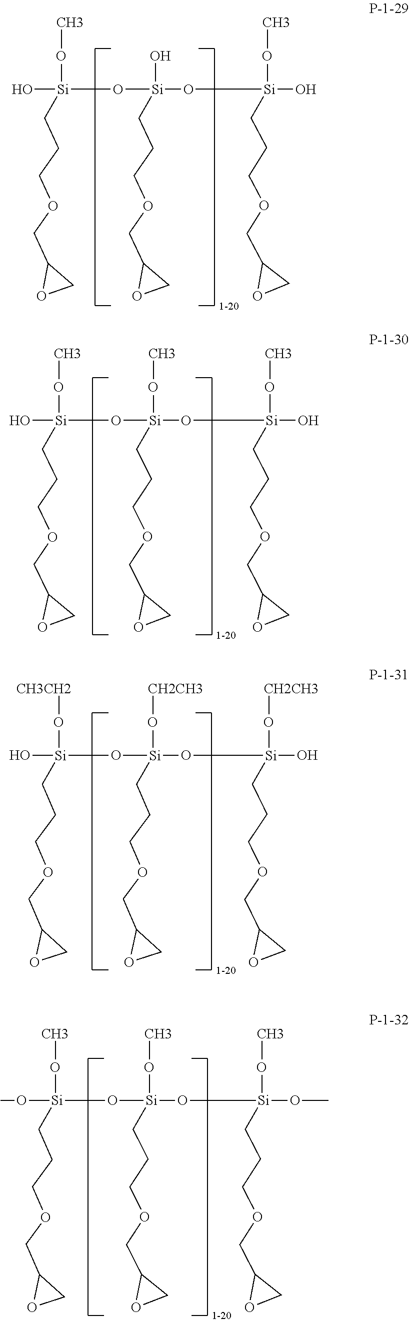

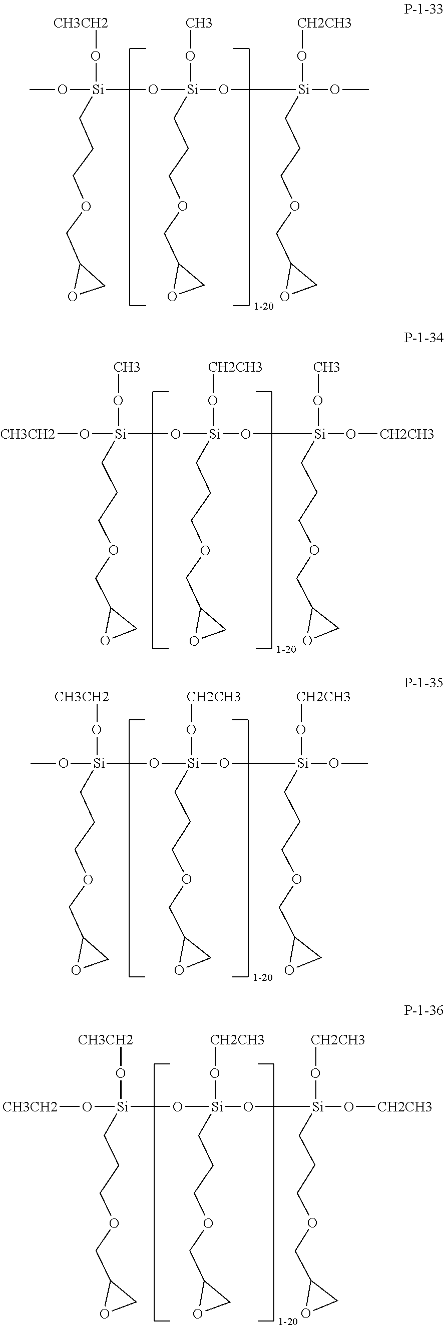

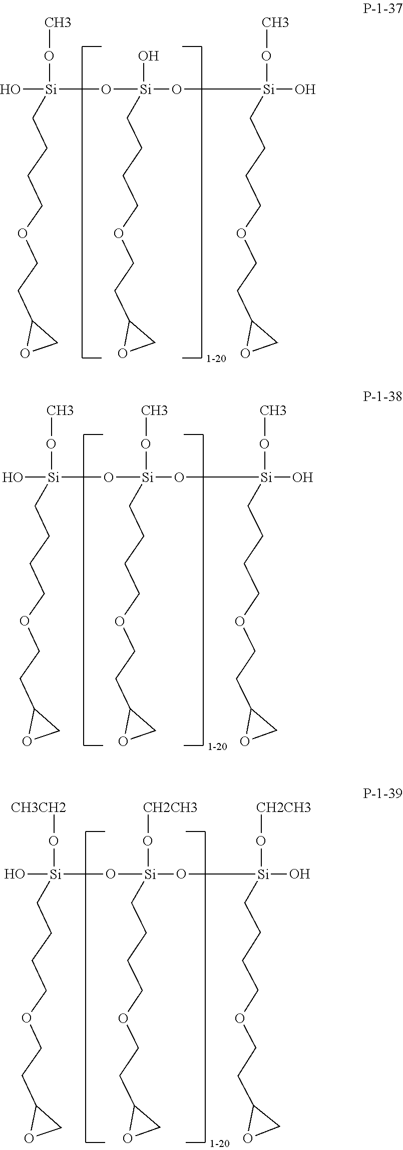

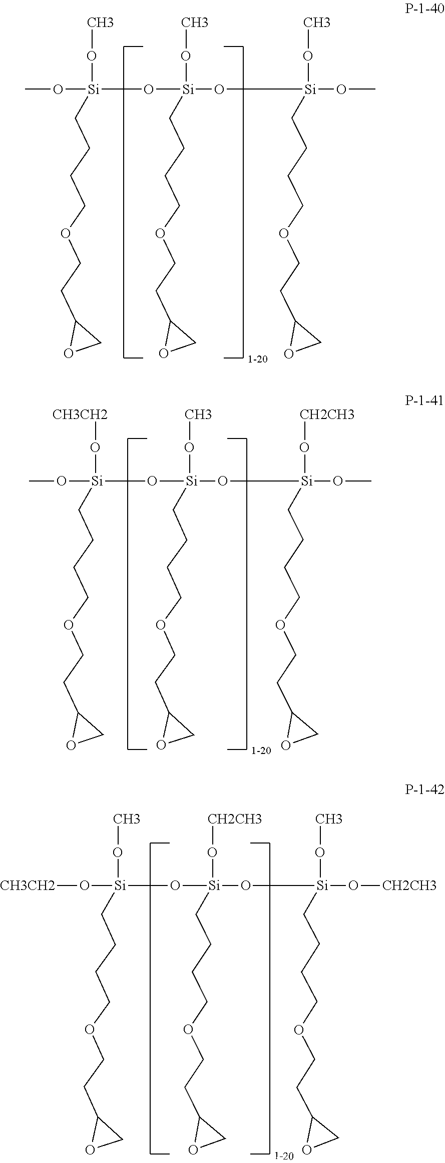

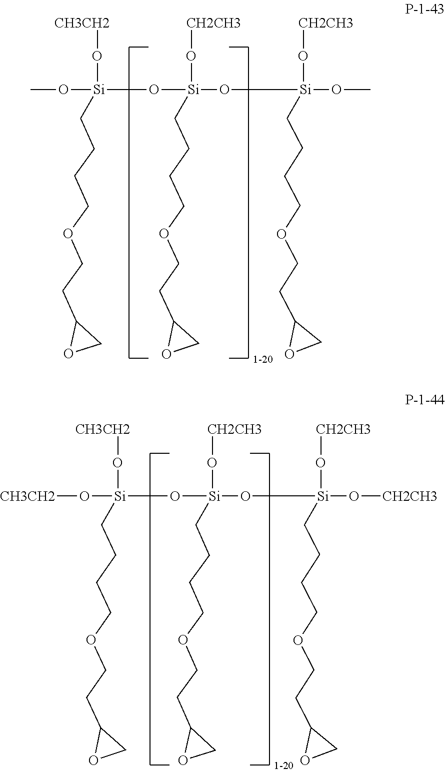

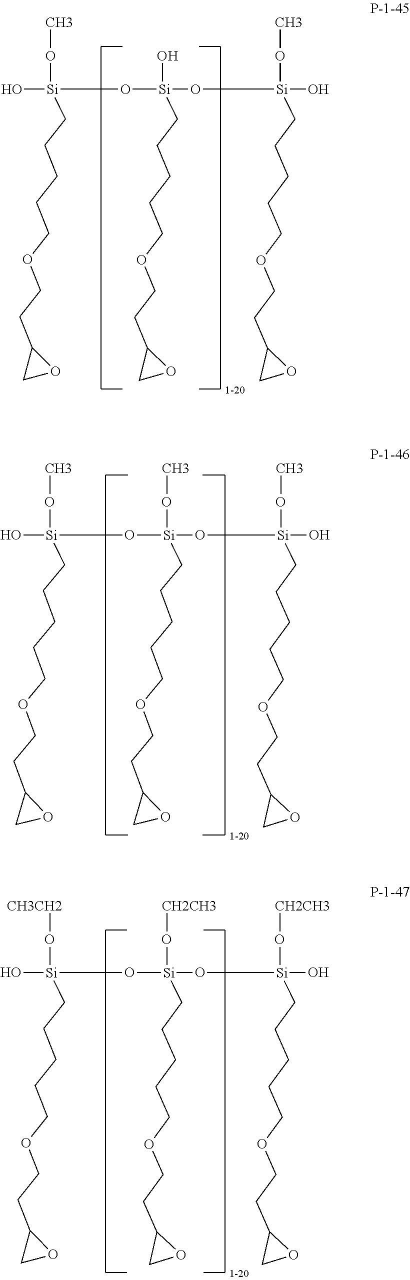

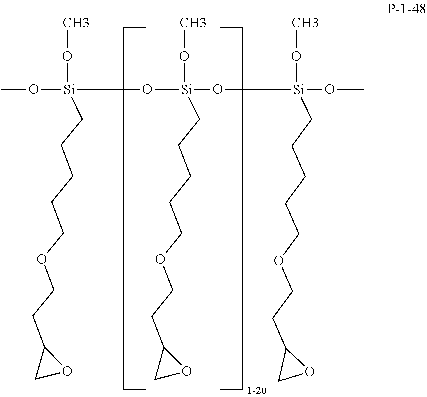

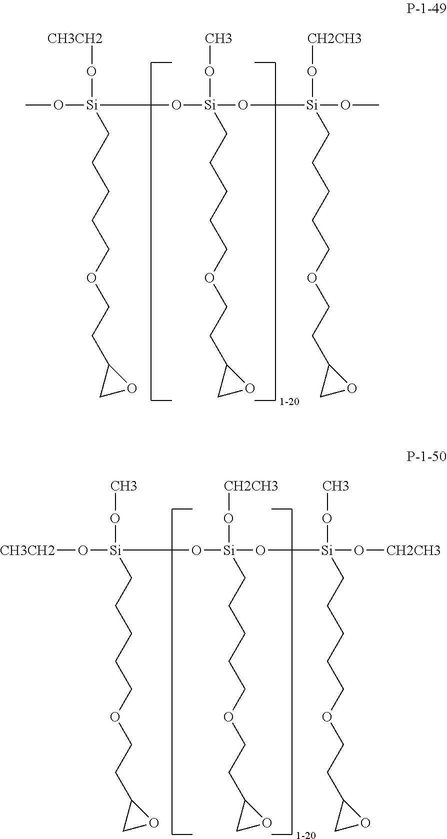

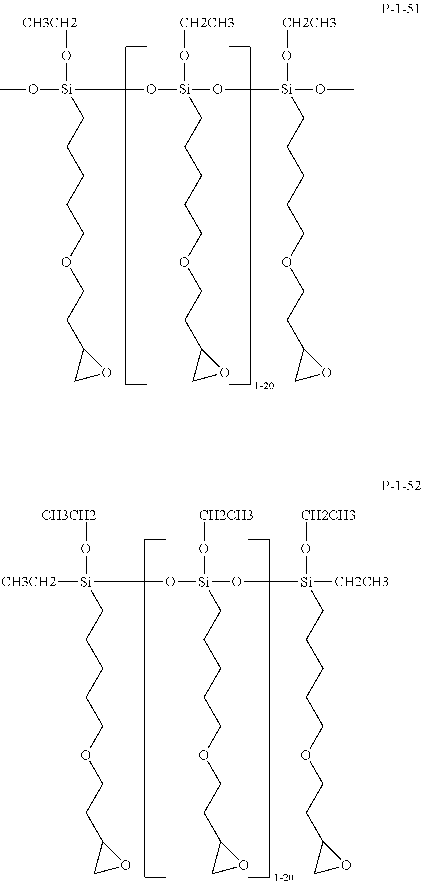

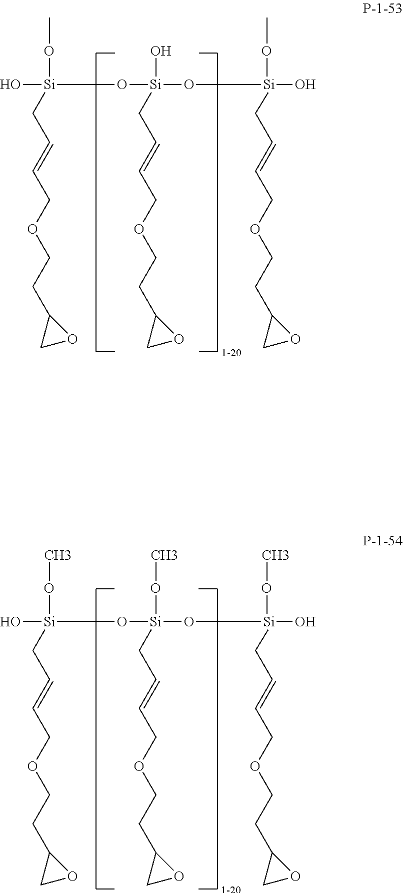

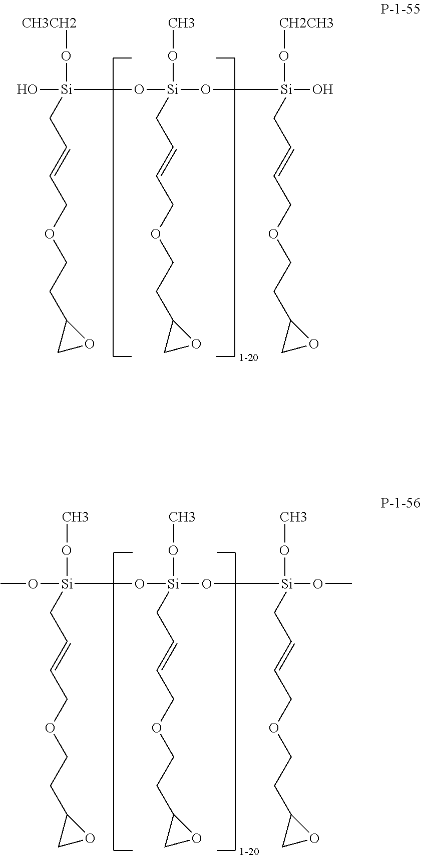

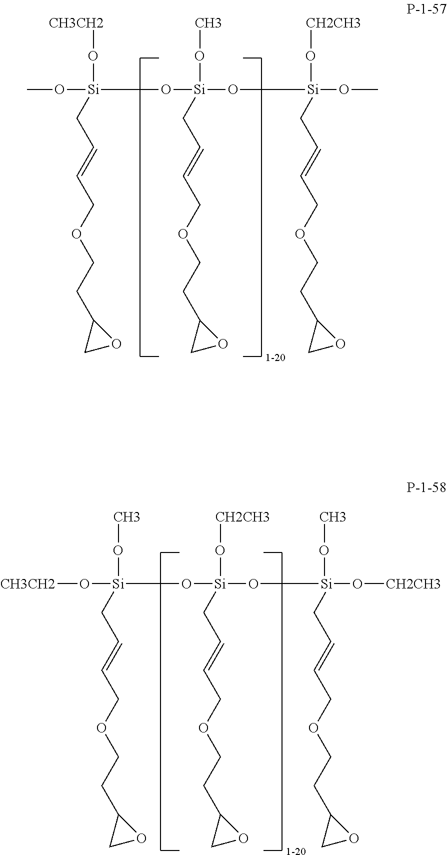

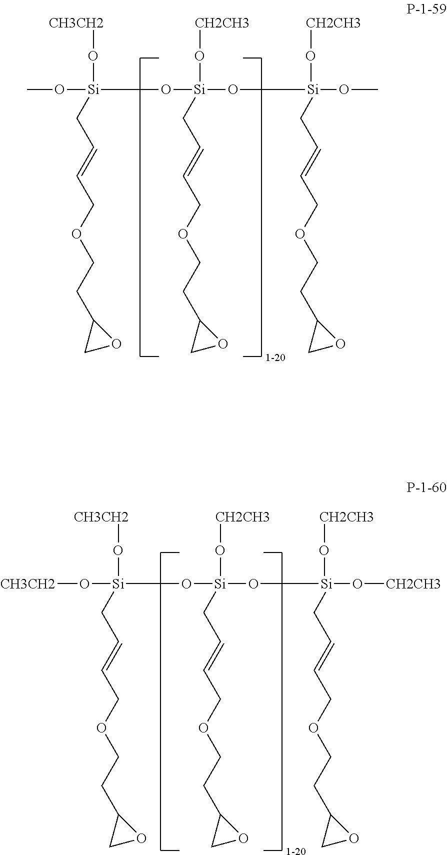

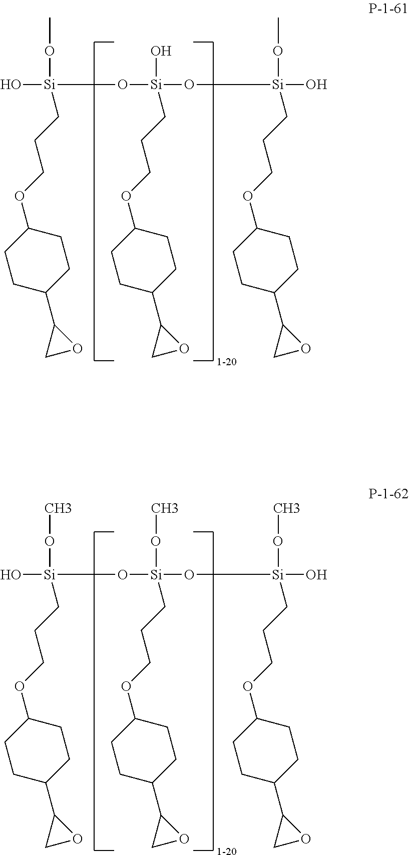

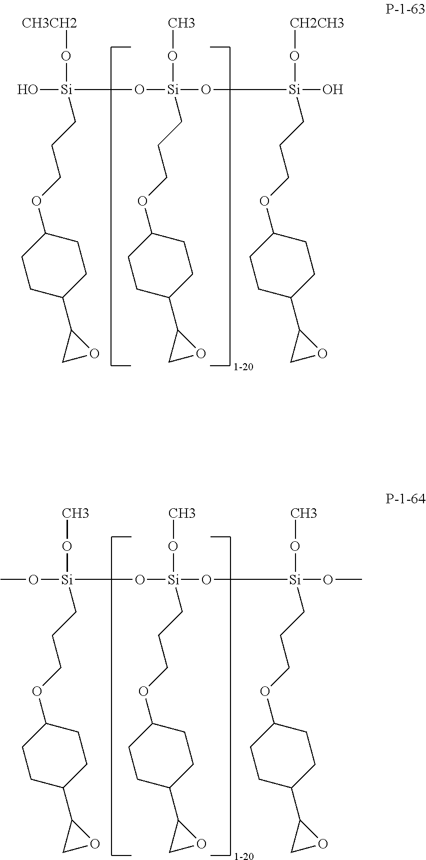

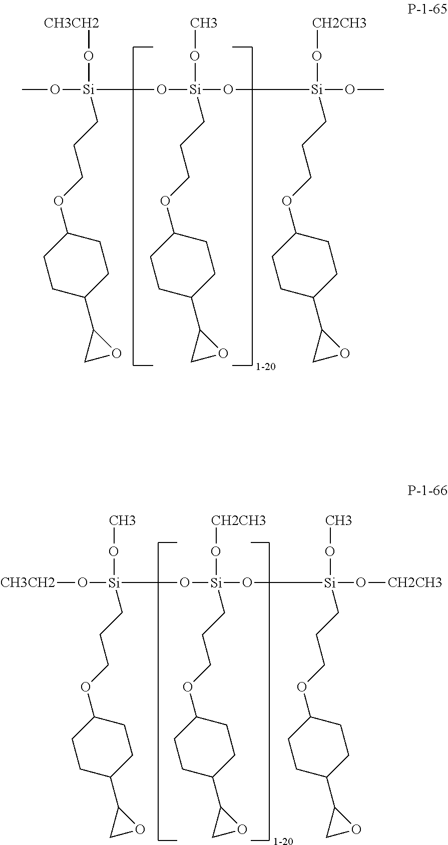

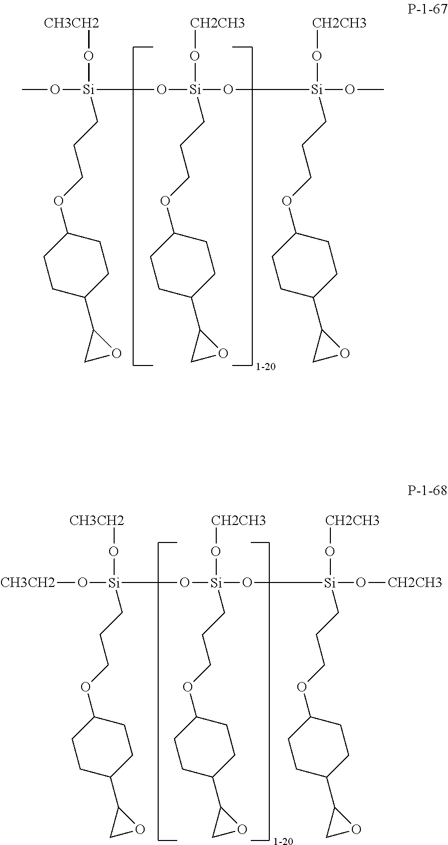

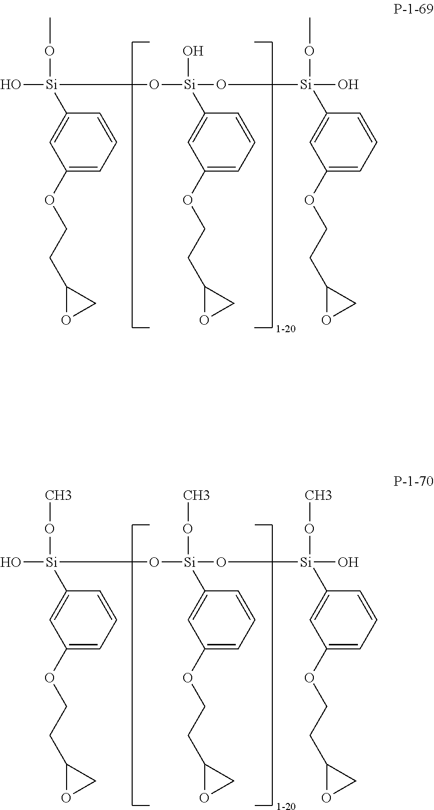

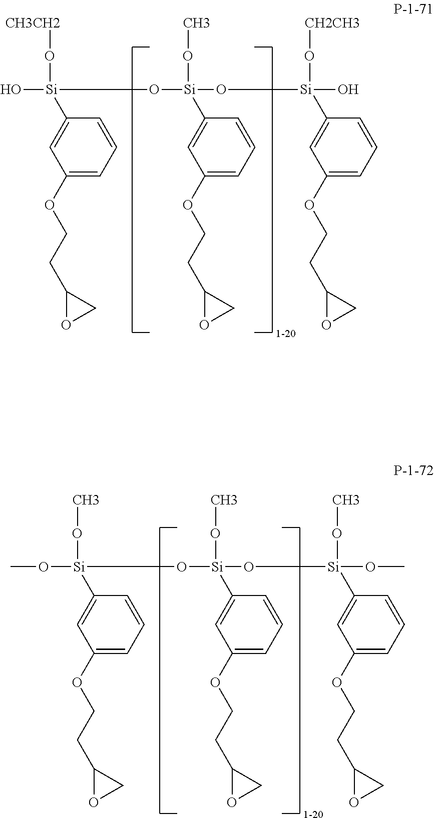

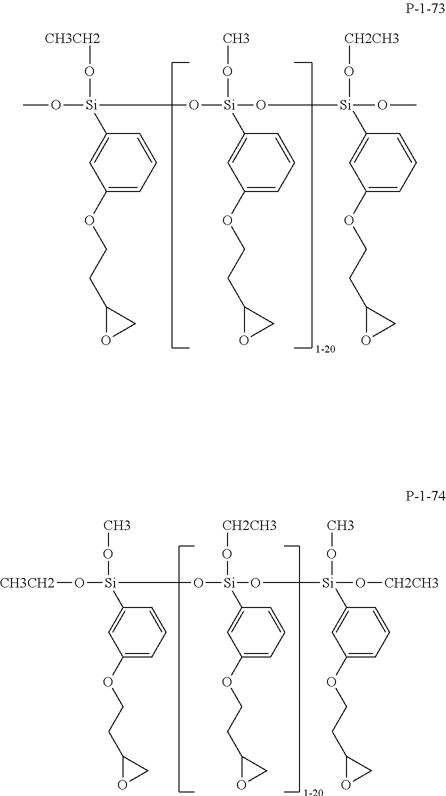

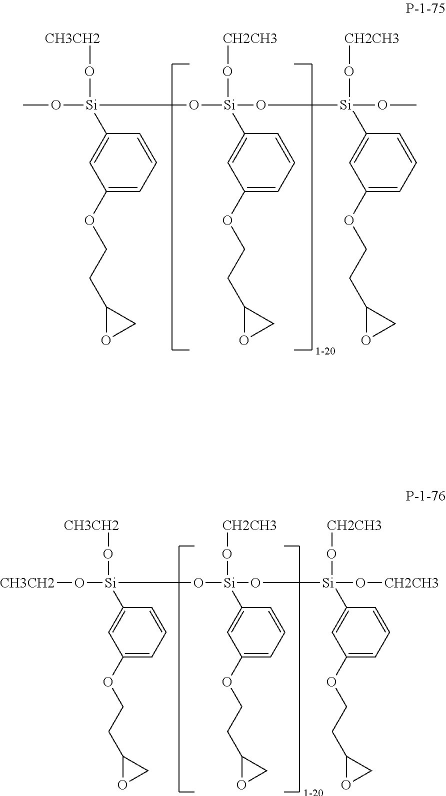

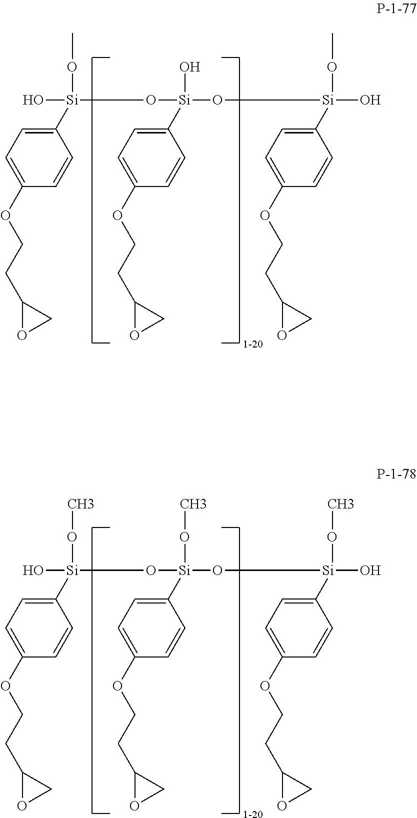

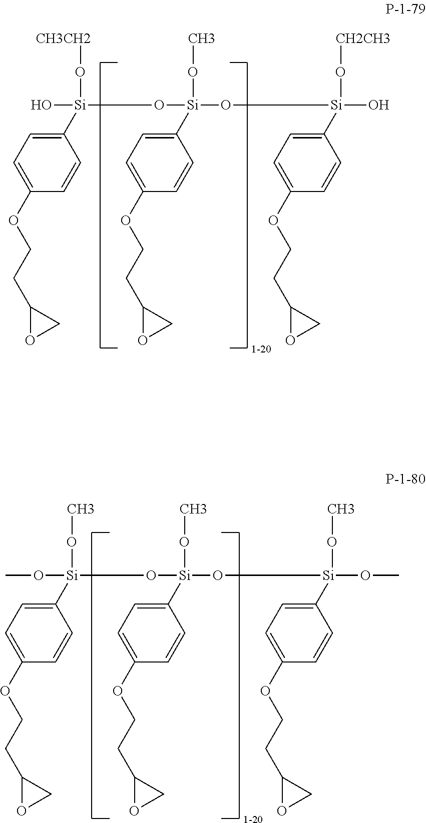

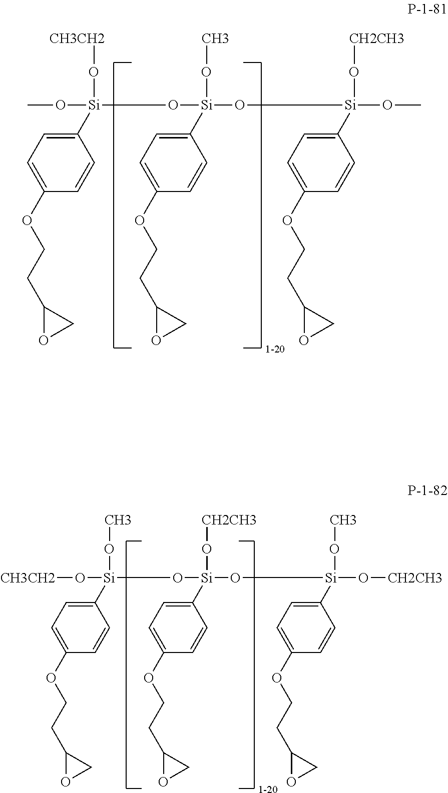

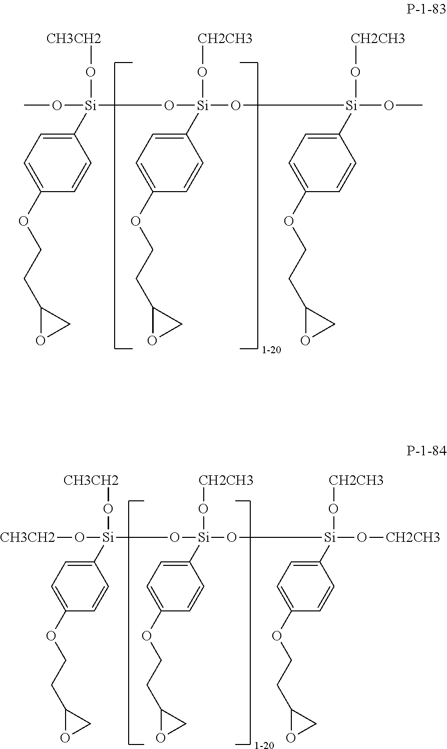

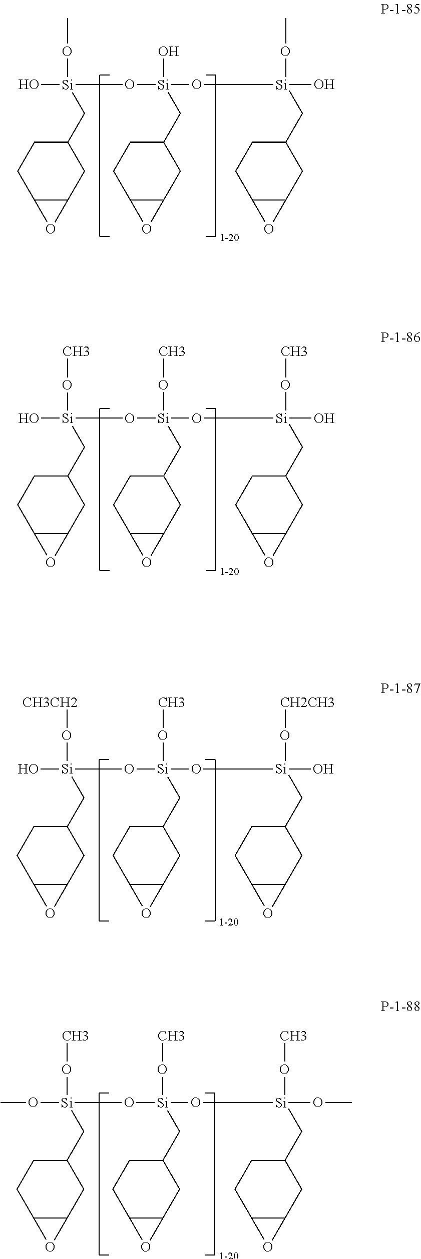

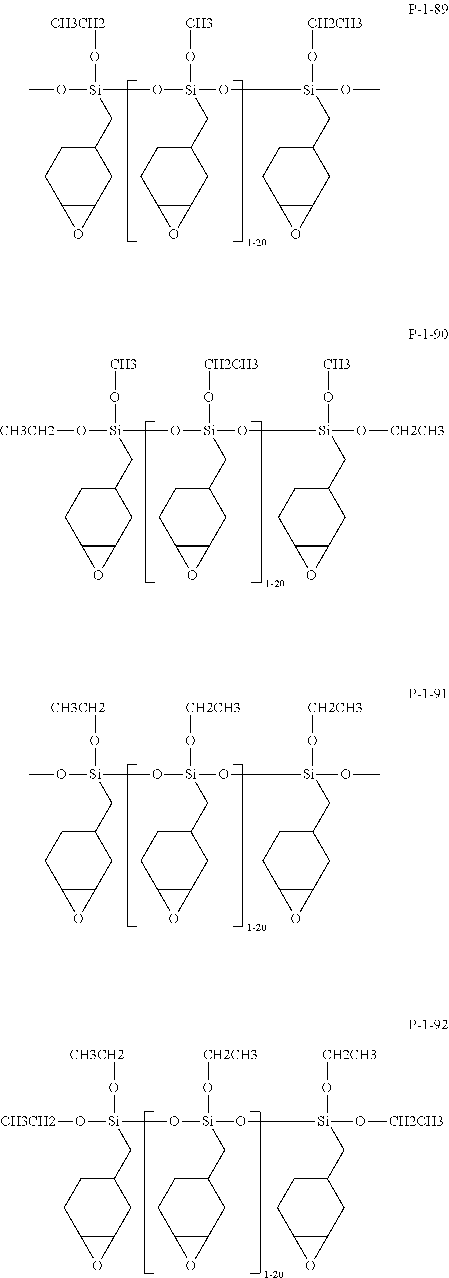

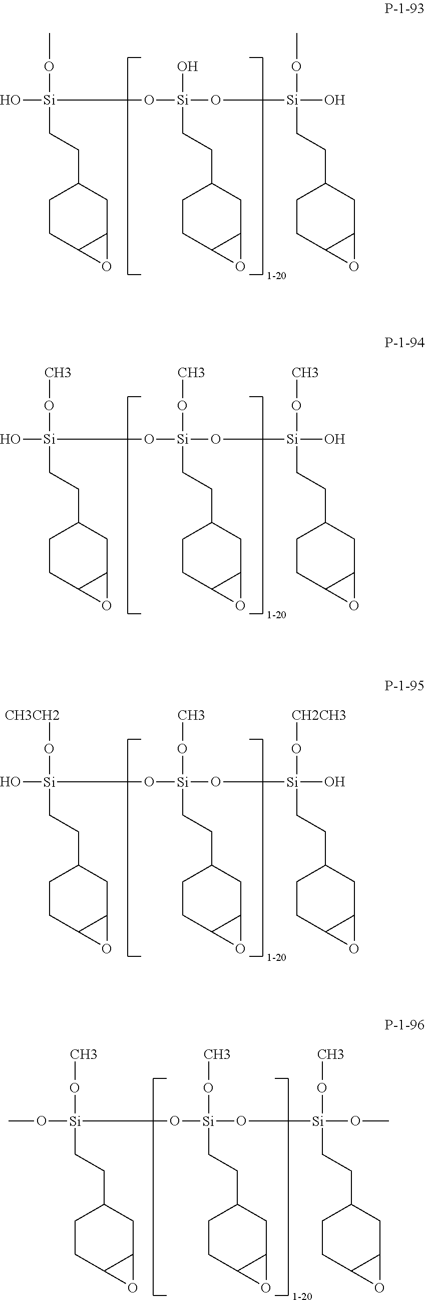

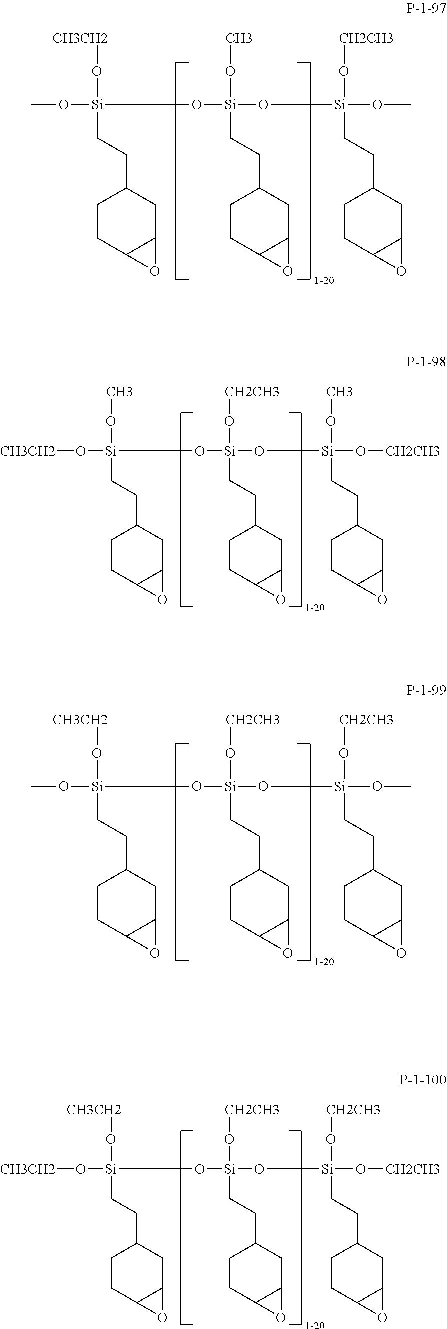

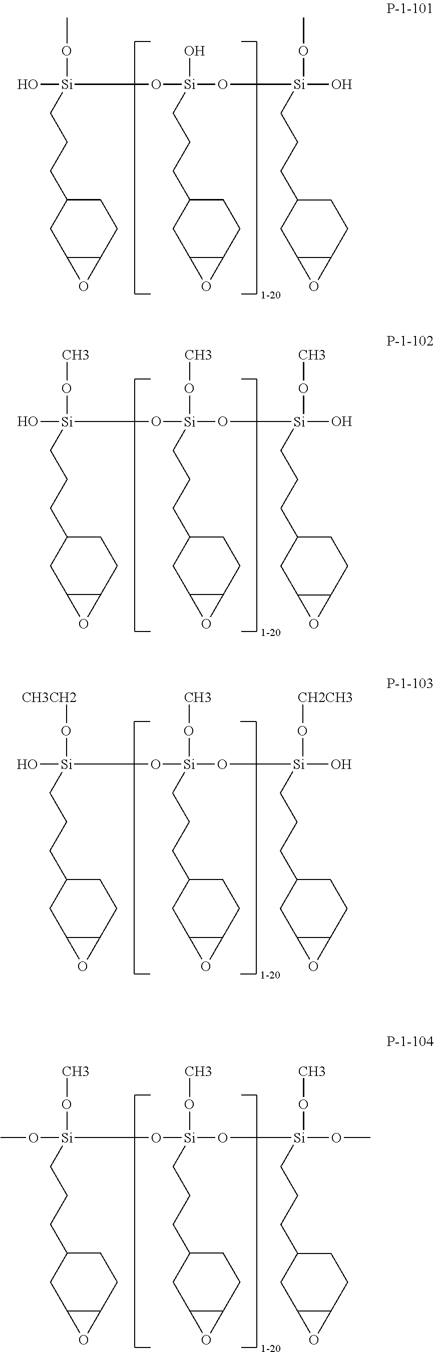

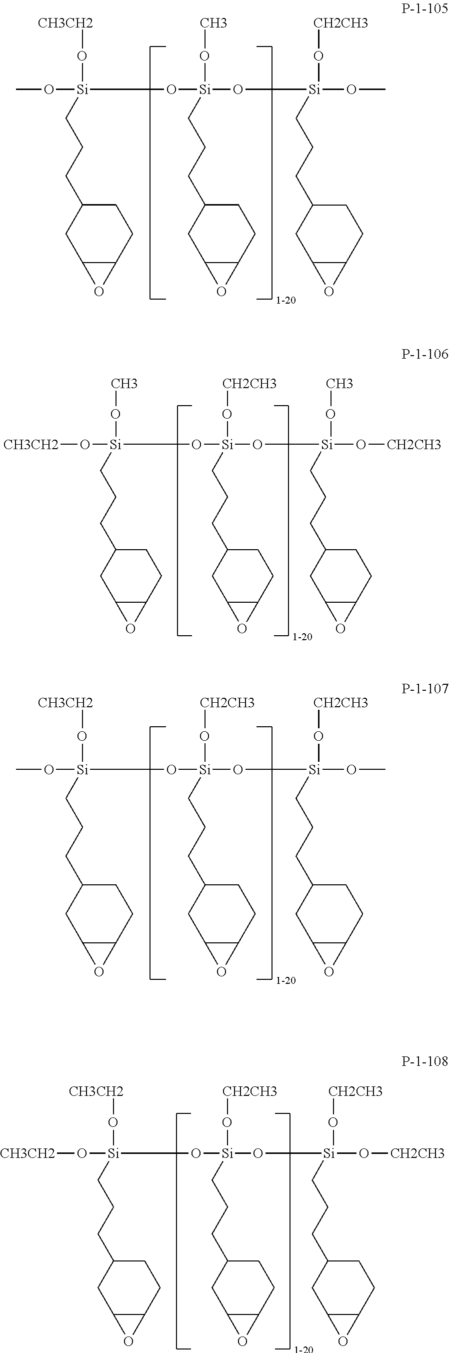

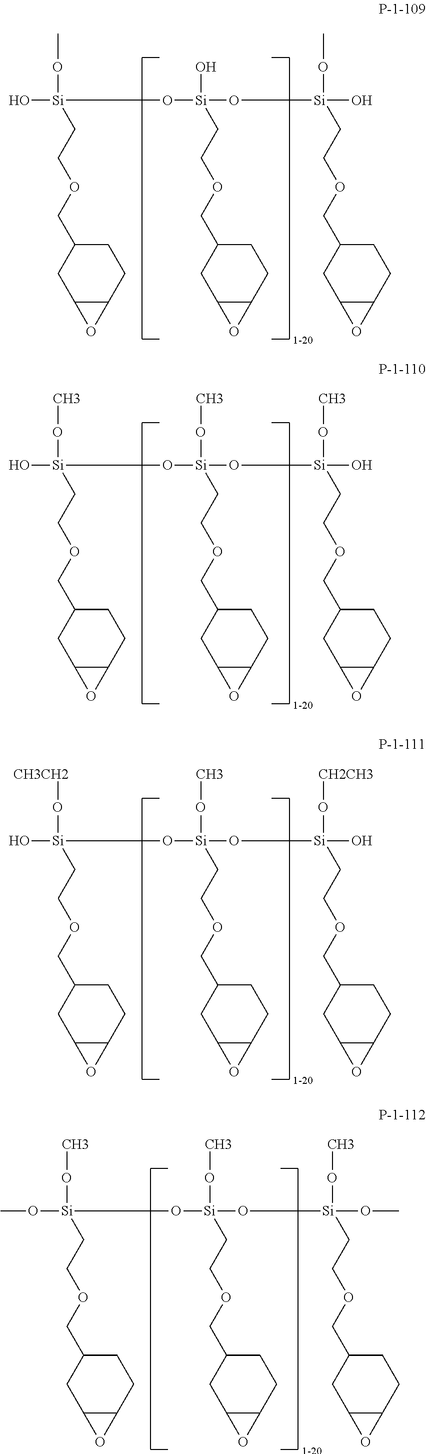

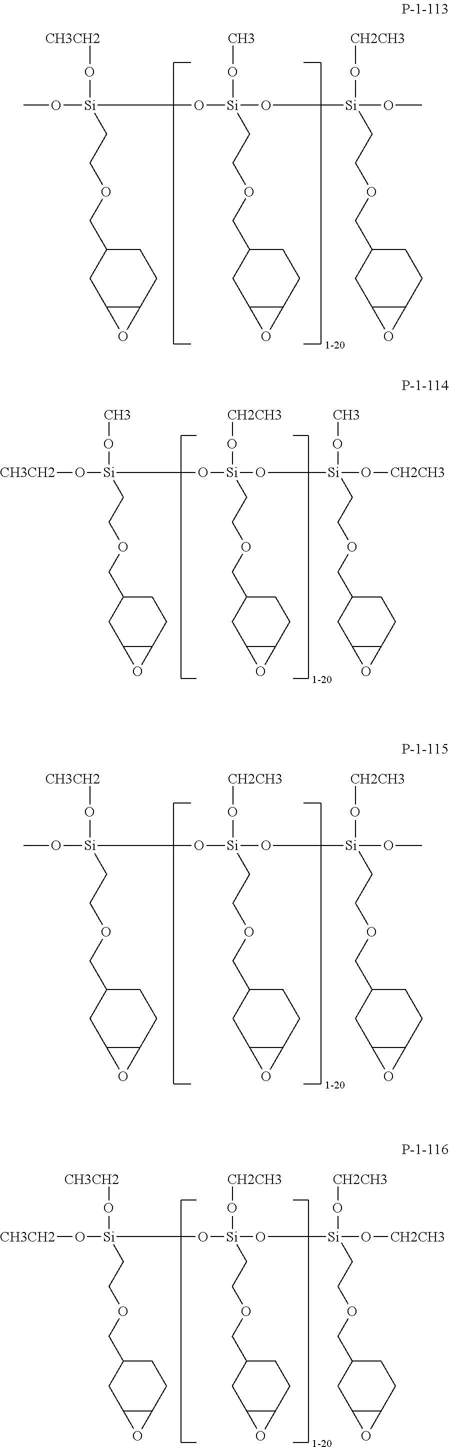

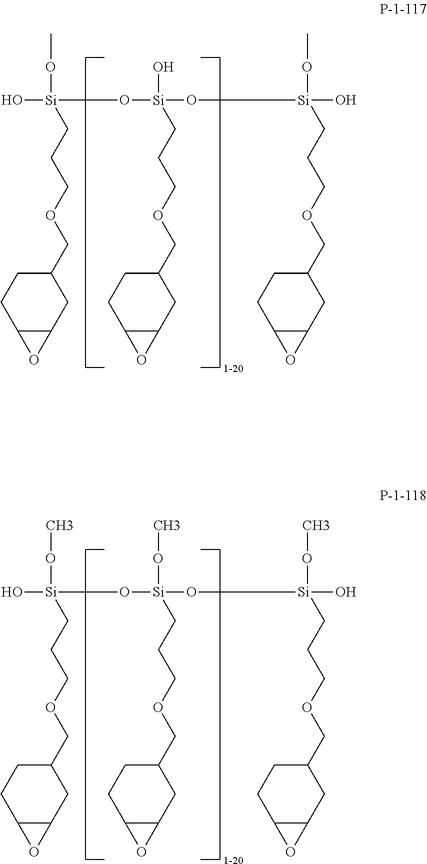

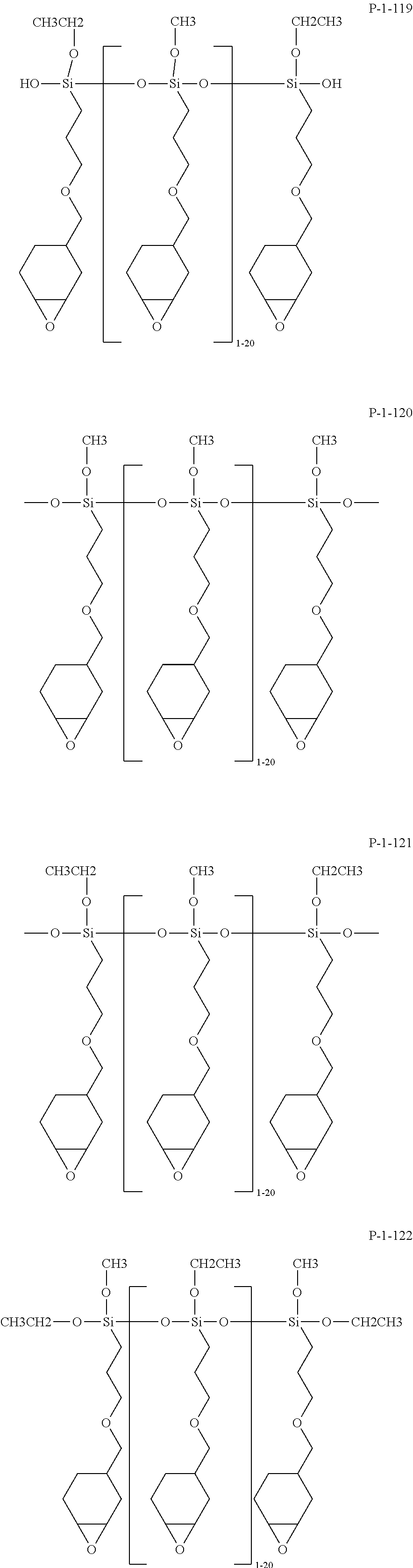

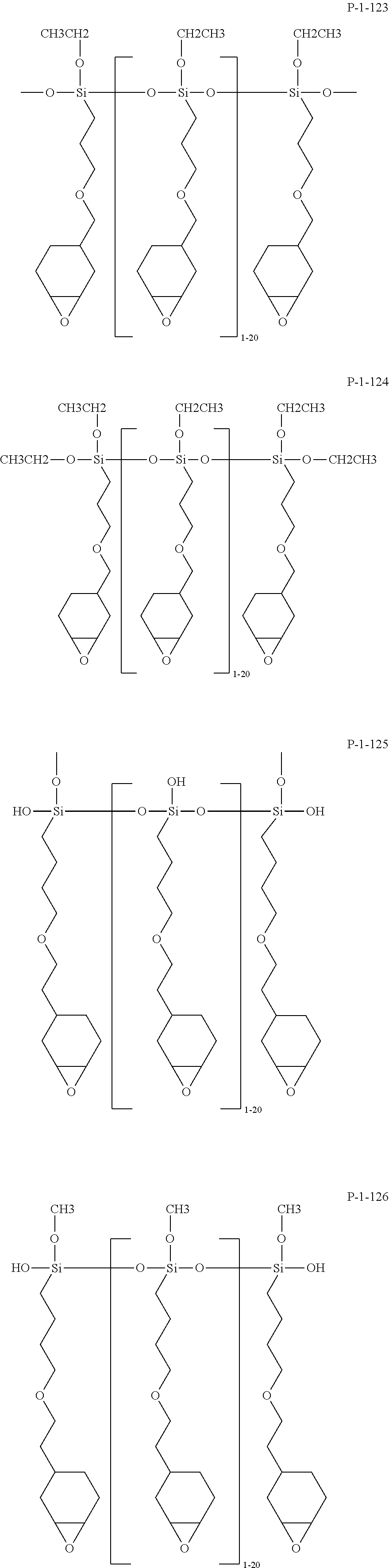

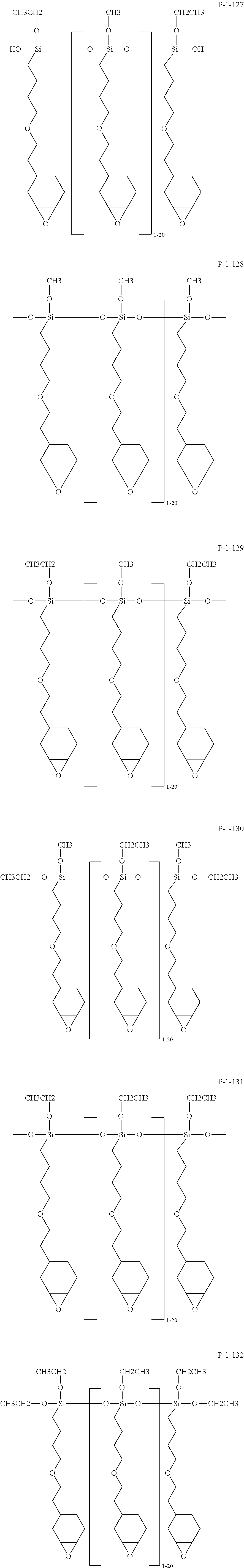

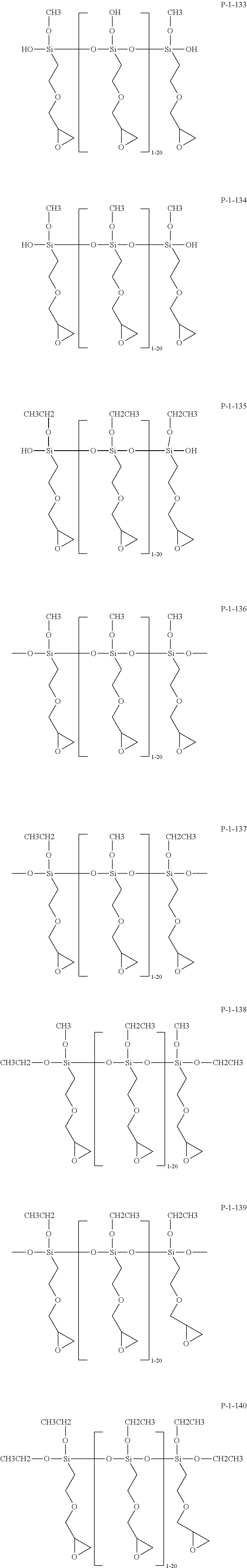

The first monomer may be included in an amount of 1 to 40 wt %, more specifically 1 to 30 wt %, or 1 to 25 wt %, or 5 to 40 wt %, or 5 to 30 wt %, or 5 to 25 wt %, based on the total weight of the composition for protective layer.

The second monomer may be a compound represented by Chemical Formula 2 below.

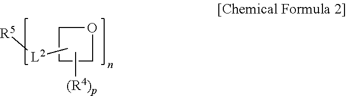

Symbols described in Chemical Formula 2 may be defined as follows.

n may be an integer from 1 to 4.

p may be an integer from 0 to 5.

R⁴ may be selected from the group consisting of hydrogen; deuterium; a hydroxyl group; a nitrile group; an acrylate group; a carbonyl group; an ether group; an ester group; a C₁-C₃₀ alkyl group; a C₂-C₃₀ alkenyl group; a C₂-C₃₀ alkynyl group; a C₃-C₃₀ cycloalkyl group; a C₁-C₃₀ alkoxy group; a C₁-C₃₀ alkylamine group; a C₆-C₃₀ aryl group; a C₂-C₃₀ heterocyclic group comprising at least one heteroatom selected from O, N, S, Si, and P; a C₆-C₃₀ aryloxy group; a C₆-C₃₀ arylamine group; —N(R′)(R″); and a combination thereof. Wherein, when p is an integer of 2 or more, the R⁴ groups may be the same or different.

R⁵ may be selected from the group consisting of hydrogen; deuterium; a hydroxyl group; an acrylate group; a carbonyl group; an ether group; an ester group; a C₁-C₃₀ alkyl group; a C₂-C₃₀ alkenyl group; a C₂-C₃₀ alkynyl group; a C₃-C₃₀ cycloalkyl group; a C₁-C₃₀ alkoxy group; a C₁-C₃₀ alkylamine group; a C₆-C₃₀ aryl group; a C₂-C₃₀ heterocyclic group comprising at least one heteroatom selected from O, N, S, Si, and P; a C₆-C₃₀ aryloxy group; a C₆-C₃₀ arylamine group; —N(R′)(R″); and a combination thereof.

L² may be selected from the group consisting of a single bond; a carbonyl group; an ether group; an ester group; a C₁-C₃₀ alkylene group; a C₂-C₃₀ alkenylene group; a C₂-C₃₀ alkynylene group; a C₃-C₃₀ cycloalkylene group; a C₃-C₃₀ cycloalkenylene group; a C₁-C₃₀ alkoxylene group; a C₁-C₃₀ alkylamine group; a C₆-C₃₀ arylene group; a C₂-C₃₀ heterocyclic group comprising at least one heteroatom selected from O, N, S, Si, and P; a C₆-C₃₀ aryloxy group; a C₆-C₃₀ arylamine group; and a combination thereof.

R′ and R″ may be independently selected from the group consisting of hydrogen; deuterium; a hydroxyl group; an acrylate group; a carbonyl group; an ether group; an ester group; a C₁-C₃₀ alkyl group; a C₂-C₃₀ alkenyl group; a C₂-C₃₀ alkynyl group; a C₃-C₃₀ cycloalkyl group; a C₁-C₃₀ alkoxy group; a C₁-C₃₀ alkylamine group; a C₆-C₃₀ aryl group; a C₂-C₃₀ heterocyclic group comprising at least one heteroatom selected from O, N, S, Si, and P; a C₆-C₃₀ aryloxy group; a C₆-C₃₀ arylamine group; and a combination thereof.

In R⁴, R⁵, R′, R″, and L², the alkyl group, the alkenyl group, the alkynyl group, the cycloalkyl group, the alkoxy group, the alkylamine group, the aryl group, the heterocyclic group, the aryloxy group, the arylamine group, the alkylene group, the alkenylene group, the alkynylene group, the cycloalkylene group, the cycloalkenylene group, the alkoxylene group, and the arylene group may each independently be substituted with one or more substituents selected from the group consisting of deuterium, a halogen group, a hydroxyl group, a nitrile group, a nitro group, a C₁-C₃₀ alkyl group, a C₁-C₃₀ alkoxy group, a C₁-C₃₀ alkylamine group, a C₁-C₃₀ alkylsilyl group, a C₁-C₃₀ alkylthiophene group, a C₂-C₃₀ alkenyl group, a C₂-C₃₀ alkynyl group, a C₃-C₃₀ cycloalkyl group, a C₆-C₃₀ aryl group, a C₆-C₃₀ aryloxy group, a C₆-C₃₀ arylamine group, —N(R′)(R″) (wherein R′ and R″ may be defined as described above), a C₆-C₃₀ arylsilyl group, a C₆-C₃₀ arylthiophene group, a C₆-C₃₀ aryl group substituted with deuterium, a C₇-C₃₀ arylalkyl group, a C₈-C₃₀ arylalkenyl group, a silane group, a siloxane group, a boron group, a thiol group, a germanium group, and a C₂-C₃₀ heterocyclic group, and the substituted substituent may be further substituted with one or more substituents selected from the above-described substituents. For example, these substituted substituents may be additionally substituted with one or more substituents selected from the above-described substituents, and the additionally substituted substituent may be further substituted with one or more substituents selected from the above-described substituents.

The Chemical Formula 2 may be represented by any one of the following Chemical Formula 2-1 and Chemical Formula 2-2.

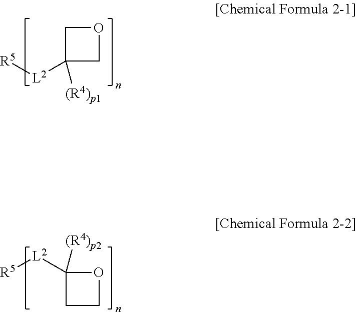

The symbols described in Chemical Formula 2-1 and Chemical Formula 2-2 may be defined as follows.

n, R⁴, R⁵, and L² may be defined identically to the definitions of n, R4, R5, and L2 as defined in Chemical Formula 2.

p1 and p2 may each be an integer of 0 or 1.

The compound represented by Chemical Formula 2 may be one or more of the following compounds.

The second monomer may be one or more compounds represented by the following P-2-1 to P-2-68.

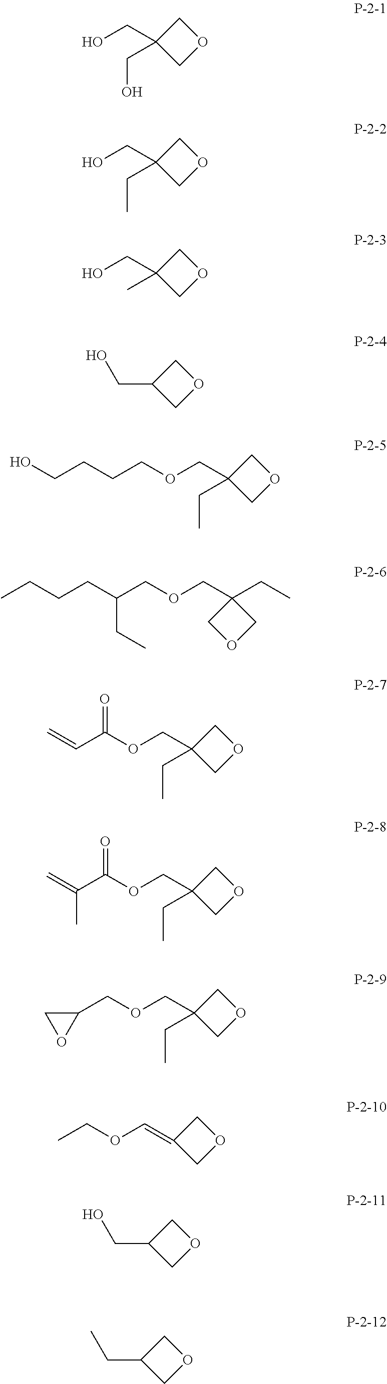

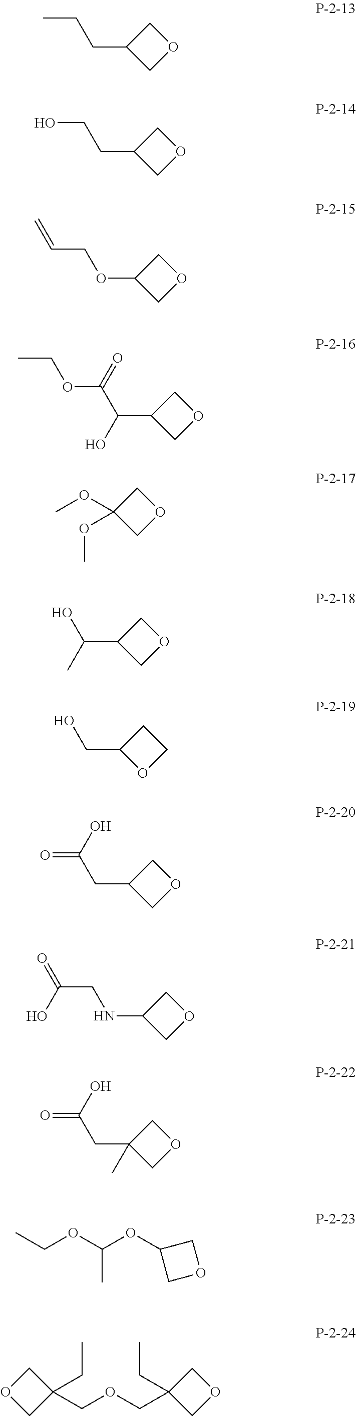

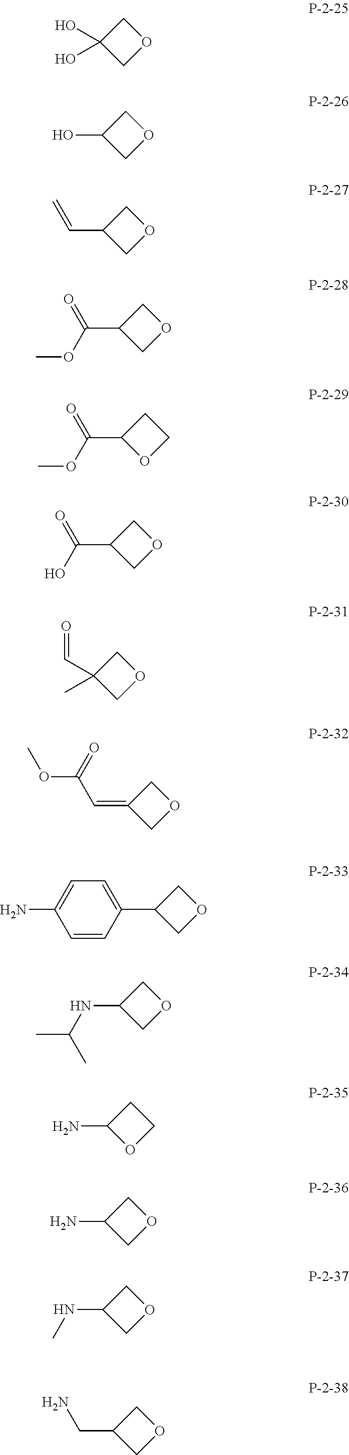

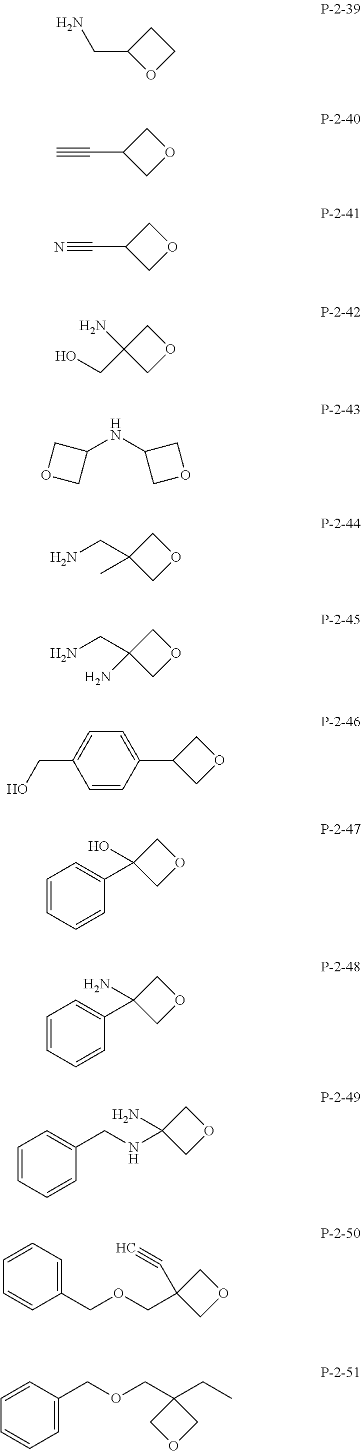

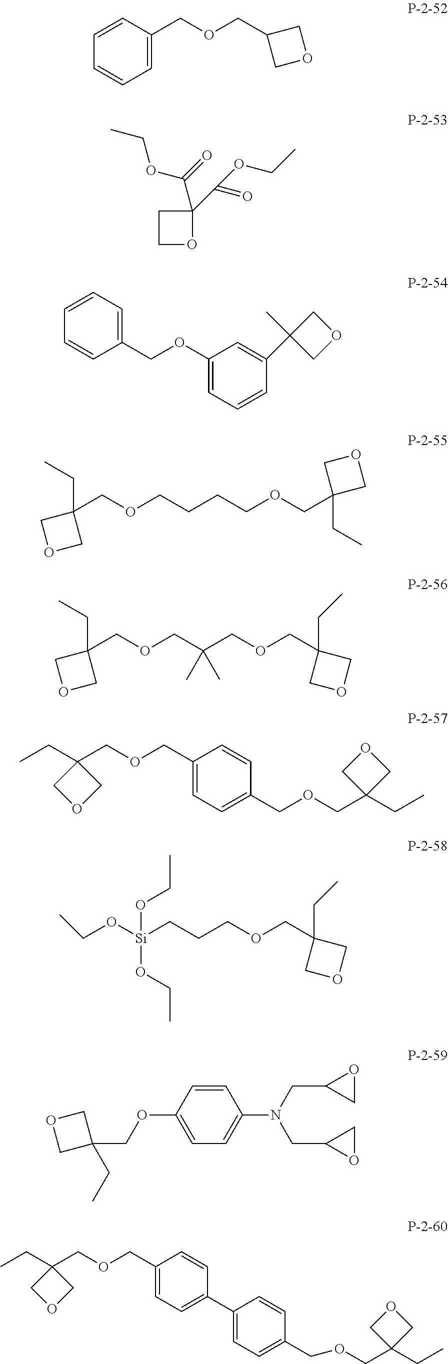

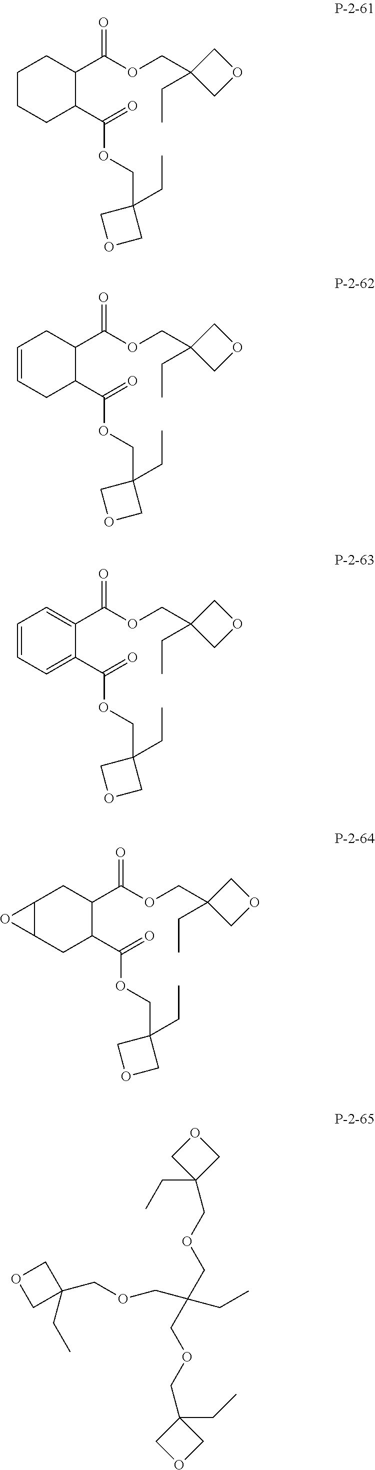 [SMILES: CCC1(COC(=O)C2CCCCC2C(=O)OCC2(CC)COC2)COC1 ; CCC1(COC(=O)C2CC=CCC2C(=O)OCC2(CC)COC2)COC1 ; CCC1(COC(=O)c2ccccc2C(=O)OCC2(CC)COC2)COC1 ; CCC1(COC(=O)C2CC3OC3CC2C(=O)OCC2(CC)COC2)COC1 ; CCC1(COCC(CC)(COCC2(CC)COC2)COCC2(CC)COC2)COC1]

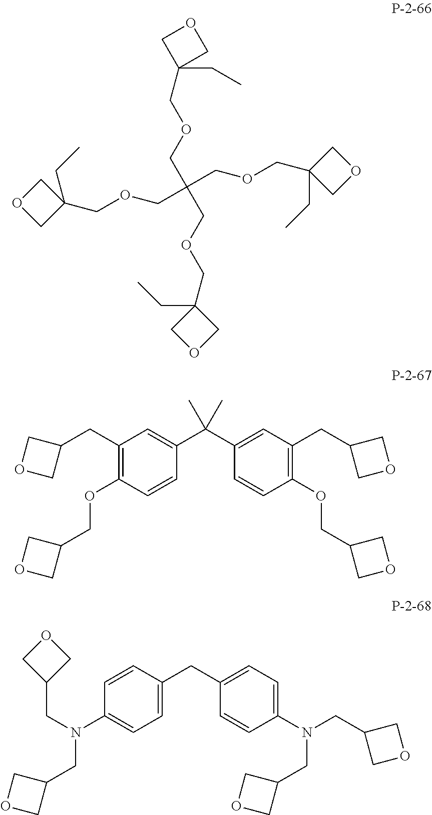 [SMILES: CCC1(COCC(COCC2(CC)COC2)(COCC2(CC)COC2)COCC2(CC)COC2)COC1 ; CC(C)(c1ccc(OCC2COC2)c(CC2COC2)c1)c1ccc(OCC2COC2)c(CC2COC2)c1 ; c1cc(N(CC2COC2)CC2COC2)ccc1Cc1ccc(N(CC2COC2)CC2COC2)cc1]

The second monomer may be comprised in an amount of 1 to 40% by weight, more specifically 1 to 30% by weight, or 1 to 25% by weight, or 5 to 40% by weight, or 5 to 30% by weight, or 5 to 25% by weight, relative to the total amount of the composition for protective layer.

In embodiments of the present invention, when the composition for protective layer comprises the first monomer and the second monomer described above to form a protective layer on a display panel, the physical and chemical performance of the protective layer may be significantly improved due to characteristics of an oxygen-containing cyclic structure during a curing process. The oxygen-containing cyclic structure forms a high-density three-dimensional network during curing, thereby strengthening the mechanical strength of the protective layer and improving resistance to external impact, scratches, and abrasion by exhibiting high hardness. Accordingly, sensitive electronic components such as a display panel may be effectively protected from external stimuli.

### (3) Initiator.

In embodiments of the present invention, the composition for protective layer may comprise an initiator. The initiator may be a photopolymerization initiator, a thermal polymerization initiator, or a combination thereof.

For example, a photopolymerization initiator may be used during UV curing, and the initiator may absorb UV or visible light to initiate a polymerization reaction of a monomer or an oligomer.

A photopolymerization initiator is an initiator generally used in a composition for protective layer, and representative examples comprise a radical initiator and a cationic initiator.

The photopolymerization initiator may comprise a radical initiator, a cationic initiator, or both.

A radical initiator generates free radicals upon irradiation with UV or visible light, and may initiate polymerization to cure the composition. For example, the radical initiator may initiate a radical reaction of an acrylate monomer.

The radical initiator may comprise one or more of, for example, an oxime-based compound, an acetophenone-based compound, a benzophenone-based compound, a thioxanthone-based compound, a benzoin-based compound, a triazine-based compound, a phosphine oxide-based compound, a peroxide-based compound, and an azo bis-based compound, but is not limited thereto.

An oxime-based compound may be an oxime ester-based compound. Examples of the oxime-based compound include, but are not limited to, 2-(o-benzoyloxime)-1-[4-(phenylthio)phenyl]-1,2-octanedione, 1-(o-acetyloxime)-1-[9-ethyl-6-(2-methylbenzoyl)-9H-carbazol-3-yl]ethanone, O-ethoxycarbonyl-α-oxyamino-1-phenylpropan-1-one, 2-dimethylamino-2-(4-methylbenzyl)-1-(4-morpholin-4-yl-phenyl)-butan-1-one, 1-(4-phenylsulfanylphenyl)-butan-1,2-dione-2-oxime-O-benzoate, 1-(4-phenylsulfanylphenyl)-octane-1,2-dione-2-oxime-O-benzoate, 1-(4-phenylsulfanylphenyl)-octan-1-one-oxime-O-acetate, 1-(4-phenylsulfanylphenyl)-butan-1-one-oxime-O-acetate, 1-(4-methylsulfanyl-phenyl)-butan-1-one-oxime-O-acetate, hydroxyimino-(4-methylsulfanyl-phenyl)-acetic acid ethyl ester-O-acetate, and hydroxyimino-(4-methylsulfanyl-phenyl)-acetic acid ethyl ester-O-benzoate.

Examples of an acetophenone-based compound include, but are not limited to, 2,2′-diethoxyacetophenone, 2,2′-dibutoxyacetophenone, 2-hydroxy-2-methylpropiophenone, p-t-butyltrichloroacetophenone, p-t-butyldichloroacetophenone, 4-chloroacetophenone, 2,2′-dichloro-4-phenoxyacetophenone, 2-methyl-1-(4-(methylthio)phenyl)-2-morpholinopropan-1-one, and 2-benzyl-2-dimethylamino-1-(4-morpholinophenyl)-butan-1-one.

Examples of a benzophenone-based compound include, but are not limited to, benzophenone, benzoyl benzoic acid, methyl benzoyl benzoate, 4-phenylbenzophenone, hydroxybenzophenone, acrylated benzophenone, 4,4′-bis(dimethylamino)benzophenone, 4,4′-bis(diethylamino)benzophenone, 4,4′-dimethylaminobenzophenone, 4,4′-dichlorobenzophenone, and 3,3′-dimethyl-2-methoxybenzophenone.

Examples of a thioxanthone-based compound include, but are not limited to, thioxanthone, 2-chlorothioxanthone, 2-methylthioxanthone, isopropylthioxanthone, 2,4-diethylthioxanthone, 2,4-diisopropylthioxanthone, and 2-chlorothioxanthone.

Examples of a benzoin-based compound include, but are not limited to, benzoin, benzoin methyl ether, benzoin ethyl ether, benzoin isopropyl ether, benzoin isobutyl ether, and benzyldimethyl ketal.

Examples of the triazine-based compound include 2,4,6-trichloro-s-triazine, 2-phenyl-4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-biphenyl-4,6-bis(trichloromethyl)-s-triazine, bis(trichloromethyl)-6-styryl-s-triazine, 2-(naphtho-1-yl)-4,6-bis(trichloromethyl)-s-triazine, 2-(4-methoxynaphtho-1-yl)-4,6-bis(trichloromethyl)-s-triazine, 2,4-trichloromethyl(piperonyl)-6-triazine, 2,4-trichloromethyl(4′-methoxystyryl)-6-triazine, and the like, but are not limited thereto.

Examples of the phosphoric acid oxide-based compound include diphenyl(2,4,6-trimethylbenzoyl)phosphine oxide (TPO), ethyl phenyl(2,4,6-trimethylbenzoyl)phosphinate (TPO-L), methyl acrylphosphine oxide, and the like.

Examples of the azobis-based compound include 1,1′-azobiscyclohexane-1-carbonitrile, 2,2′-azobis(2,4-dimethylvaleronitrile), 2,2′-azobis(methyl isobutyrate), 2,2′-azobis(4-methoxy-2,4-dimethylvaleronitrile), α,α′-azobis(isobutylnitrile), 4,4′-azobis(4-cyanovaleric acid), and the like, but are not limited thereto.

As the photopolymerization initiator, in addition to the above-described compounds, a carbazole-based compound, a diketone compound, a sulfonium borate-based compound, a diazo-based compound, an imidazole-based compound, a biimidazole-based compound, or the like may be used.

The cationic initiator may generate cations by irradiation of UV or visible light to initiate polymerization, thereby curing the composition. The cationic initiator may be used to initiate a radical reaction during polymerization of monomers such as epoxy and vinyl ether. For example, the cationic initiator may be classified into an onium salt initiator and a non-onium salt initiator.

Examples of the onium salt initiator include a diaryl iodonium salt, a triarylsulfonium salt, a ferrocenium salt, a sulfonium hexafluoroantimonate salt, a sulfonium hexafluorophosphate salt, and the like, but are not limited thereto.

Examples of the non-onium salt initiator include trifluoromethanesulfonate, tetraphenylborate, iron phenylsulfone, N-hydroxynaphthalimide triflate (NIT), and the like, but are not limited thereto.

The radical initiator and the cationic initiator may be classified into a primary initiator and a secondary initiator according to their roles.

The primary initiator may directly absorb light to generate radicals or cations, thereby inducing an initiation reaction by itself. For example, the primary initiator comprises an acetophenone-based initiator, a triazine-based initiator, and the like.

In the case of the acetophenone-based initiator, examples include acetophenone, 2-hydroxy-2-methylpropiophenone, 1-hydroxycyclohexyl phenyl ketone, 2,2-dimethoxyacetophenone, and the like, but are not limited thereto.

In the case of the triazine-based initiator, examples include 2,4,6-triphenyloxadiazolyl-1,3,5-triazine, hexamethoxymethyltriazine, bis(4-dimethylaminophenyl)-1,3,5-triazine, 2,4,6-triphenyl-1,3,5-triazine, and the like, but are not limited thereto.

The secondary initiator may play an auxiliary role to increase the sensitivity of the primary initiator or to enable activation at a longer wavelength, thereby inducing uniform curing of a coating surface. For example, the secondary initiator comprises an anthracene-based initiator, a thioxanthone-based initiator, a coumarin-based initiator, and the like.

Examples of the anthracene-based initiator include 9,10-diphenylanthracene, 1-chloro-9,10-bis(phenylethynyl)anthracene, 2-ethylanthracene, and the like, but are not limited thereto.

Examples of the thioxanthone-based initiator include isopropyl thioxanthone, 2-chlorothioxanthone, 2,4-diethylthioxanthone, and the like, but are not limited thereto.

Examples of the coumarin-based initiator include coumarin 6, 4-methyl-7-diethylaminocoumarin, 3-phenylcoumarin, and the like, but are not limited thereto.

The photopolymerization initiator may also be used together with a photosensitizer that causes a chemical reaction by absorbing light to reach an excited state and then transferring the energy. Examples of the photosensitizer include tetraethylene glycol bis-3-mercaptopropionate, pentaerythritol tetrakis-3-mercaptopropionate, dipentaerythritol tetrakis-3-mercaptopropionate, and the like, but are not limited thereto.

An initiator may be comprised in an amount of 1 to 40 wt %, specifically 1 to 30 wt %, or 1 to 25 wt %, or 5 to 40 wt %, or 5 to 30 wt %, or 5 to 25 wt % based on the total amount of the composition for protective layer. When the initiator is comprised within the aforementioned range, sufficient crosslinking of a monomer may occur during a protective layer formation process, thereby achieving excellent reliability for a protective effect.

### (4) Other Additives

In embodiments of the present invention, the composition for protective layer may comprise other additives. For example, the composition for protective layer may further comprise an acrylate-based additive, an adhesion promoter, a leveling agent, and an antistatic agent. The acrylate-based additive and the adhesion promoter may serve to improve adhesion to a substrate during protective layer formation. The adhesion promoter may comprise an epoxy silane coupling agent. The leveling agent is an additive that improves surface smoothness, and may serve to allow the composition for protective layer to spread uniformly on the substrate, and may prevent the composition for protective layer from excessively spreading or shrinking through surface tension control. Furthermore, it may serve to improve the flowability and workability of ink in a head of an inkjet printer.

The leveling agent may comprise a silicone-based compound.

The molecular weight of the silicone-based compound may be 5,000 g/mol to 15,000 g/mol.

The molecular weight of the silicone-based compound may be 5,000 g/mol to 10,000 g/mol.

The viscosity of the silicone-based compound may be 100,000 mm²/s to 500,000 mm²/s.

The viscosity of the silicone-based compound may be 10 mm²/s to 40 mm²/s when a mixture of 50 wt % of the silicone-based compound and 50 wt % of propylene glycol methyl ether acetate is measured at 20 °C.

The viscosity of a mixture comprising the silicone-based compound may be 10 mm²/s to 30 mm²/s.

The silicone-based compound preferably comprises a substituent selected from the group consisting of a C1-C40 alkyl group; a C1-C40 alkenyl group; a C1-C40 alkynyl group; a C1-C40 alkoxy group; a C6-C40 aryloxy group; a C1-C40 alkoxycarbonyl group; a carbonyl group; an ether group; an ester group; a carboxyl group; or a combination thereof.

An antistatic agent may serve to control the surface resistance of a protective layer according to embodiments of the present invention to suppress static electricity generation, prevent dust adhesion, and maintain electrical stability. For example, the antistatic agent may comprise a polymer-type antistatic agent, an ionic antistatic agent, a semiconductive filler, an inorganic antistatic agent, an organometallic composite antistatic agent, and the like.

Examples of the polymer-type antistatic agent comprise polyethylene glycol, polyoxyethylene, polyvinylpyrrolidone, polyethyleneimine, and the like, but are not limited thereto.

In the case of an ionic antistatic agent, it may be classified into a cationic ionic antistatic agent and an anionic ionic antistatic agent. In the case of the cationic ionic antistatic agent, there are quaternary ammonium salts, imidazolinium salts, pyridinium salts, and the like, and in the case of the anionic ionic antistatic agent, there are sulfonate salts, carboxylate salts, and the like, but these are not limited thereto.

In the case of a semiconductive filler, there are carbon black, carbon nanotubes, silver nanowires, and the like, but these are not limited thereto.

In the case of an inorganic antistatic agent, there are indium tin oxide, zinc oxide, titanium oxide, silicon oxide, and the like, but these are not limited thereto.

In the case of an organometallic composite antistatic agent, there are conductive polymer mixtures (PEDOT:PSS), silver nanoparticle composites, copper oxide nanocomposites, graphene-metal composites, and the like, but these are not limited thereto.

The other additives described above may be comprised in an amount of 1 to 30 wt %, specifically 1 to 25 wt %, or 5 to 30 wt %, or 5 to 25 wt %, or 10 to 30 wt %, or 10 to 25 wt %, based on the total weight of the composition for protective layer.

According to embodiments of the present invention, a protective layer comprising the composition for protective layer described above may be provided.

According to embodiments of the present invention, a display device comprising the composition for protective layer described above may be provided.

Hereinafter, various embodiments of the present invention will be described in detail with reference to the accompanying drawings.

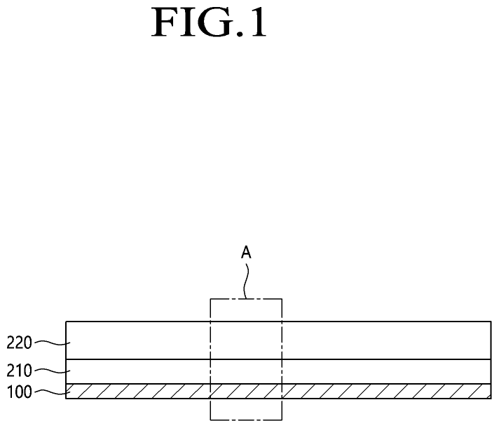

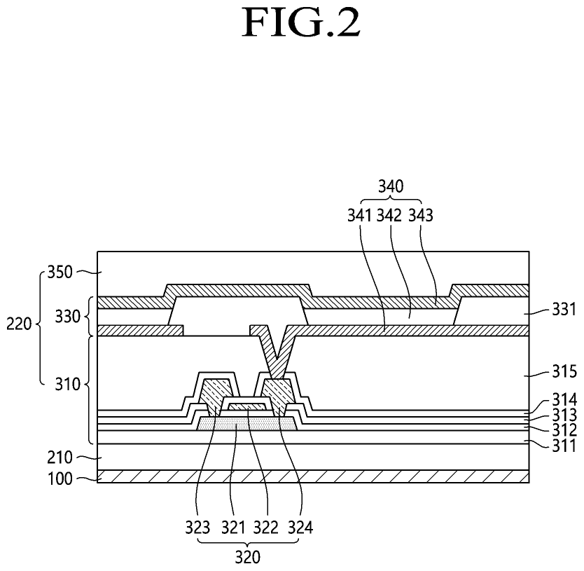

FIG. 1 is an exemplary cross-sectional view schematically illustrating a display device according to embodiments of the present invention, and FIG. 2 is an exemplary cross-sectional view illustrating an enlarged cross-section of region A shown in FIG. 1.

Referring to FIGS. 1 and 2, the display device may comprise a protective layer 100, a substrate 210, and a pixel array layer 220. The display device may be a display element, a display panel, or an electronic device. The pixel array layer 220 may comprise a pixel circuit layer 310, a pixel element layer 330, and an encapsulation layer 350.

The protective layer 100 may be disposed under a display panel 200. The protective layer 100 may be disposed on the other surface of the substrate 210 opposite to one surface of the substrate 210 on which the pixel array layer 220 is disposed. The protective layer 100 may comprise a composition comprising a colorant, a first monomer, and a second monomer as described above. For example, the protective layer 100 may comprise a cured product of the composition comprising the colorant, the first monomer, and the second monomer as described above.

The protective layer 100 may prevent color interference and oxidation of electrodes by minimizing light reflection due to internal light at a lower portion of the display panel by comprising the colorant. The protective layer 100 may effectively protect sensitive electronic components such as the display panel from external stimuli by improving resistance to external impact, scratches, and abrasion by comprising the first monomer and the second monomer.

The substrate 210 may be disposed on the protective layer 100. The substrate 210 may be disposed to directly contact the protective layer 100. The substrate 210 is for supporting various components of the display device and may comprise a light emission area and a non-light emission area surrounding the light emission area. The substrate 210 may be formed of an insulating material such as a glass substrate or a plastic substrate.

The pixel circuit layer 310 may be disposed on the substrate 210. The pixel circuit layer 310 may comprise various insulating layers 311, 312, 313, 314, and 315 and a thin film transistor 320.

A buffer layer 311 may be disposed on the substrate 210. The buffer layer 311 may be a single layer or multiple layers. The buffer layer 311 may serve to delay diffusion of moisture and/or oxygen that has penetrated into the substrate 210.

The thin film transistor 320 may be disposed on the buffer layer 311. The thin film transistor 320 may comprise an active layer 321, a gate electrode 322, a source electrode 323, and a drain electrode 324.

The active layer 321 may be disposed on the buffer layer 311. The active layer 321 may be composed of a silicon semiconductor, an oxide semiconductor, or an organic semiconductor.

A gate insulating layer 312 may be disposed on a portion of an upper surface and a side surface of the active layer 321. The gate insulating layer 312 may also be disposed on the buffer layer 311. The gate insulating layer 312 may be formed of an inorganic insulating material.

The gate electrode 322 may be disposed on the gate insulating layer 312. The gate electrode 322 may comprise various conductive materials. For example, the gate electrode 322 may comprise a metal or an alloy, or may comprise a transparent conductive material. The gate electrode 322 may have a single-layer or multi-layer structure.

A region where the active layer 321 overlaps the gate electrode 322 may be a channel region of the thin film transistor 320, and a region where the active layer 321 does not overlap the gate electrode 322 may be a conductive region.

An interlayer insulating layer 313 may be disposed on the gate electrode 322. The interlayer insulating layer 313 may also be disposed on the gate insulating layer 312. The interlayer insulating layer 313 may be formed of an inorganic insulating material.

A source electrode 323 and a drain electrode 324 may be disposed on the interlayer insulating layer 313. The source electrode 323 and the drain electrode 324 may be electrically and physically connected to a conductive region of the active layer 321.

The source electrode 323 and the drain electrode 324 may be electrically and physically connected to the conductive region of the active layer 321 through a contact hole penetrating the gate insulating layer 312 and the interlayer insulating layer 313.

Although the drain electrode 324 is illustrated in FIG. 2 as being connected to an anode electrode 341 of a light-emitting device 340, the source electrode 323 may also be connected to the anode electrode 341.

The source electrode 323 and the drain electrode 324 may each comprise various conductive materials. For example, the source electrode 323 and the drain electrode 324 may comprise a metal or an alloy, or may comprise a transparent conductive material. The source electrode 323 and the drain electrode 324 may be a single-layer or multi-layer structure.

A passivation layer 314 for insulating the thin film transistor 320 may be disposed on the source electrode 323 and the drain electrode 324. The passivation layer 314 may also be disposed on the interlayer insulating layer 313. The passivation layer 314 may be formed of an inorganic insulating material.

A planarization layer 315 may be disposed on the passivation layer 314. The planarization layer 315 may be formed of an organic insulating material. The planarization layer 315 may be a single-layer or multi-layer structure.

A pixel element layer 330 may be disposed on the planarization layer 315. The pixel element layer 330 may comprise a light-emitting device 340 and a pixel definition layer 331. The light-emitting device 340 may comprise an anode electrode 341, a light-emitting layer 342, and a cathode electrode 343.

The anode electrode 341 may be disposed on the planarization layer 315.

The anode electrode 341 may be electrically and physically connected to the drain electrode 324 of the thin film transistor 320 through the contact hole penetrating the planarization layer 315 and the passivation layer 314.

The pixel definition layer 331 may be formed at boundaries of sub-pixel regions. The pixel definition layer 331 may be formed on the planarization layer 315 to cover an edge of the anode electrode 341 to define the sub-pixel regions. The pixel definition layer 331 may be formed of an organic insulating material. The pixel definition layer 331 may comprise a black material. When the pixel definition layer 331 comprises the black material, it may block both internal light and external light.

The light-emitting layer 342 may be formed on the anode electrode 341 and the pixel definition layer 331. The light-emitting layer 342 may cover the pixel definition layer 331 and the anode electrode 341 not covered by the pixel definition layer 331.

The light-emitting layer 342 may emit any one of red light, green light, blue light, and white light. For example, the light-emitting layer 342 may be a white light-emitting layer that emits white light. The light-emitting layer 342 may be formed in a tandem structure in which two or more stacks are stacked.

The anode electrode 341 may be a reflective electrode comprising a metal material having a low work function and excellent reflection efficiency. The anode electrode 341 may comprise the reflective electrode and a transparent electrode disposed on the reflective electrode.

The cathode electrode 343 may be formed on the light-emitting layer 342. The cathode electrode 343 may be a transmissive electrode. In addition, the cathode electrode 343 may be a semi-transmissive electrode. The cathode electrode 343 may be formed of a thin metal film having semi-transmissivity to light.

Although not illustrated, a capping layer may be disposed on the cathode electrode 343.

An encapsulation layer 350 may be disposed on the pixel element layer 330.

The encapsulation layer 350 may be disposed on the cathode electrode 343. The encapsulation layer may have a single-layer or multi-layer structure. The encapsulation layer 350 may be formed by alternately stacking a plurality of inorganic layers and organic layers.

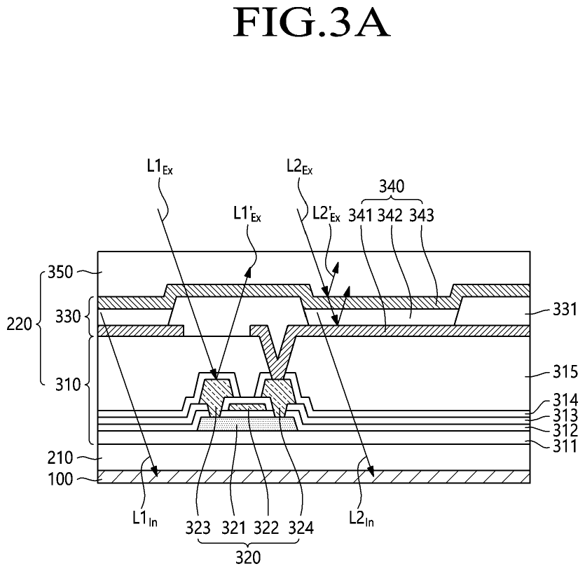

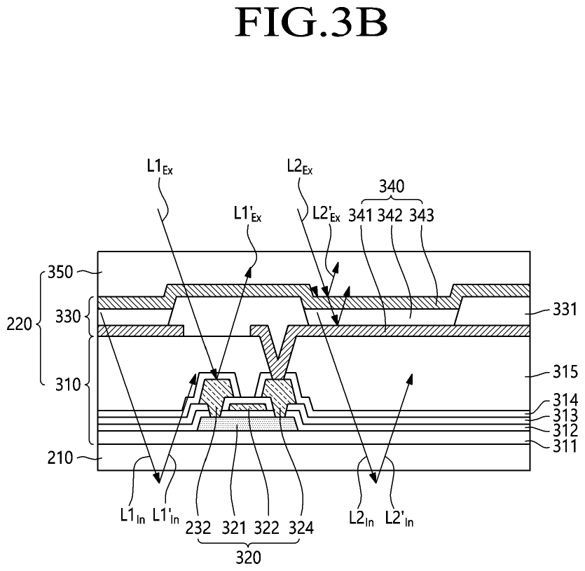

FIGS. 3A and 3B are views illustrating optical paths in a display device according to embodiments of the present invention and a display device according to a comparative example. FIG. 3A illustrates optical paths of external light and internal light in the display device according to the embodiments of the present invention, and FIG. 3B illustrates optical paths of external light and internal light in the display device according to the comparative example.

Referring to FIG. 3A, a portion of first external light L1_{EX} incident on the pixel defining layer 331 may be reflected by a metal layer constituting the thin film transistor 320 and emitted to the outside L1′_{EX}. In addition, a portion of second external light L2_{EX} incident on the light emission layer 342 may be reflected by the anode electrode 341 and the cathode electrode 343 and emitted to the outside L2′_{EX}.

In the case of a top emission type, internal light emitted from the light emission layer 342 may be reflected by the anode electrode 341 and emitted in a front direction of the display device, which is an opposite direction to the substrate 210. Meanwhile, some internal light (L1_{IN}, L2_{IN}) may travel toward the substrate 210. In this case, the first internal light L1_{IN} and the second internal light L2_{IN} may be blocked or absorbed by the protective layer 100 disposed under the substrate 210. The internal light (L1_{IN}, L2_{IN}) blocked or absorbed by the protective layer 100 is not emitted to the outside of the substrate 210 or reflected to travel to the light emission layer 342, which may be advantageous for preventing color interference and oxidation of electrodes.

On the other hand, referring to FIG. 3B, some internal light (L1_{IN}, L2_{IN}) emitted from the light emission layer 342 and traveling toward the substrate 210 may be reflected from under the substrate 210 and travel to the light emission layer 342. Such reflected light (L1′_{IN}, L2′_{IN}) may travel to the light emission layer 342 and interfere with light emitted from the light emission layer 342, causing a color interference phenomenon. In addition, there may be a problem in that oxidation of electrodes occurs due to light incident from under the substrate 210.

According to embodiments of the present invention, the protective layer comprises a colorant and an oxygen-containing cyclic group, thereby having high hardness and light-blocking performance. Accordingly, color interference caused by internal light and external light and oxidation of electrodes can be prevented, so that reliability of the display device can be improved.

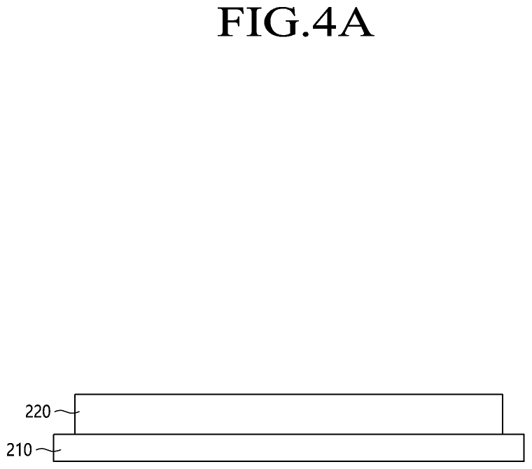

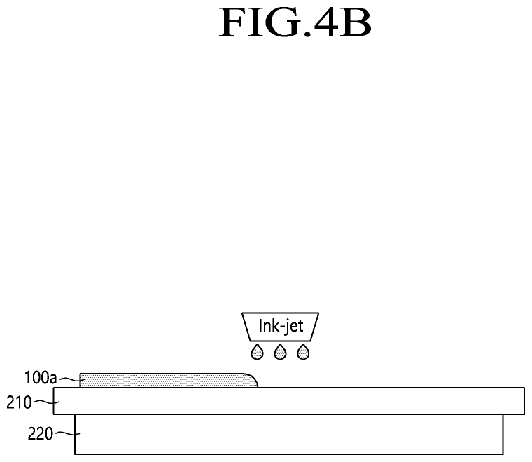

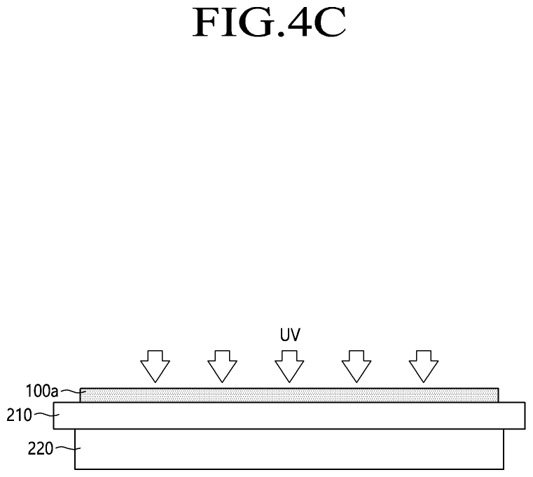

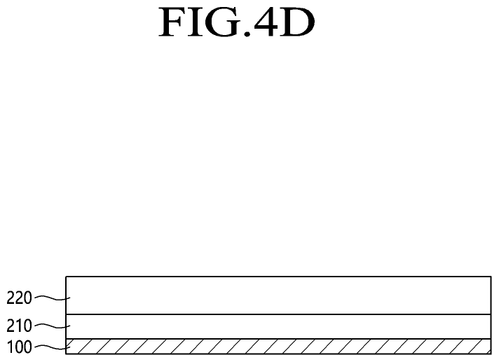

FIGS. 4A to 4D are exemplary process diagrams schematically illustrating manufacturing steps of a display device according to embodiments of the present invention.

A protective layer according to embodiments of the present invention may be formed using a composition for protective layer, which is an ultraviolet (UV) curable ink composition, and an inkjet printing method. The protective layer according to the embodiments of the present invention may comprise preparing a display panel or a substrate, coating an ink composition comprising the composition for protective layer, and curing a coating layer.

Referring to FIG. 4A, first, a step of preparing a substrate 210 may be comprised. The substrate 210 may be surface-treated so that the ink composition is easily coated. Coating performance may be improved by surface-treating the substrate 210 according to surface energy of the substrate 210. For example, the substrate 210 may be surface-treated by cleaning, UV ozone, plasma, or the like. Meanwhile, the substrate 210 may be prepared in a display panel state in which a pixel array layer 220 is formed on one surface of the substrate 210.

Referring to FIG. 4B, a coating layer 100a may be formed by coating the ink composition on the substrate 210. The coating layer 100a may be formed on the other surface of the substrate 210 where the pixel array layer 220 is not disposed.

The coating layer 100a may be formed using an inkjet printing method. An ink composition comprising the composition for protective layer is prepared and supplied to an inkjet printer head, and the ink composition may be discharged such that a thickness of the coating layer is 1 to 100 μm. In this case, for stable discharge of the ink composition from the inkjet printer head, the ink composition may have a low viscosity of about 35 cP.

Referring to FIG. 4C, a protective layer may be formed by exposing the coating layer 100a to ultraviolet (UV) light to perform a curing process. The UV light may be irradiated using a UV-LED light lamp. In consideration of spreadability of the ink composition, the UV curing process may be performed immediately after coating the ink composition.

For example, the UV curing process may be performed under conditions where a distance between the UV-LED light lamp and the coating layer is about 10 cm, an integrated light amount is about 3 J/cm², and a wavelength band is 250 to 400 nm.

Referring to FIG. 4D, the substrate 210 having the protective layer 100 formed thereunder may be cut in units of cells. The substrate 210 may be cut in units of a plurality of cells. The cutting process may be performed using a wheel or a laser.

Hereinafter, embodiments according to the present invention will be described in detail, but the present invention is not limited thereto.

### EXAMPLE

### Synthesis Example

Compounds according to embodiments of the present invention may be prepared by a method such as the following reaction scheme, but are not limited thereto.

The compound represented by Chemical Formula 1 according to the present disclosure may be synthesized through reactions such as Reaction Schemes 1 to 14 below, but the compound represented by Chemical Formula 1 according to the present disclosure is not limited to being synthesized through such reaction schemes.

### 1. Synthesis of P-1-1

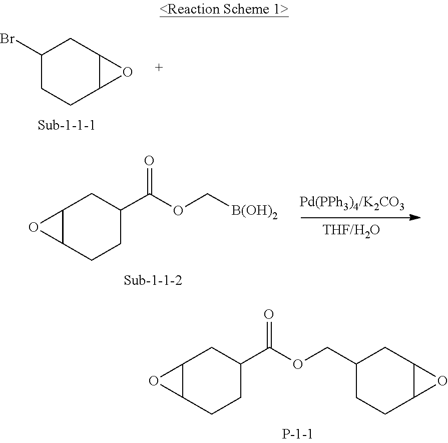 [SMILES: BrC1CCC2OC2C1 ; O=C(OCB(O)O)C1CCC2OC2C1 ; O=C(OCC1CCC2OC2C1)C1CCC2OC2C1]

After dissolving Sub-1-1-1 (3.78 g, 21.5 mmol) in THF in a round-bottom flask, Sub-1-1-2 (4.41 g, 21 mmol), Pd(PPh₃)₄ (0.69 g, 0.6 mmol), K₂CO₃ (8.29 g, 60 mmol), and water were added thereto, and the mixture was stirred at 80 °C. When the reaction was completed, extraction was performed with CH₂Cl₂ and water, and then the organic layer was dried over MgSO₄ and concentrated, and the resulting compound was purified by silica gel column chromatography and recrystallization to obtain 3.65 g of a product.

### 2. Synthesis of P-1-8

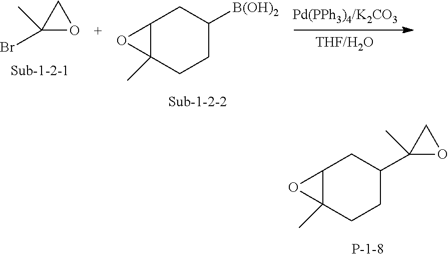

After dissolving Sub-1-2-1 (2.72 g, 20 mmol) in THF in a round-bottom flask, Sub-1-2-2 (3.12 g, 20 mmol), Pd(PPh₃)₄ (0.69 g, 0.6 mmol), K₂CO₃ (8.29 g, 60 mmol), and water were added thereto, and the mixture was stirred at 80 °C. When the reaction was completed, extraction was performed with CH₂Cl₂ and water, and then the organic layer was dried over MgSO₄ and concentrated, and the resulting compound was purified by silica gel column chromatography and recrystallization to obtain 2.65 g of a product.

### 3. Synthesis of P-1-11

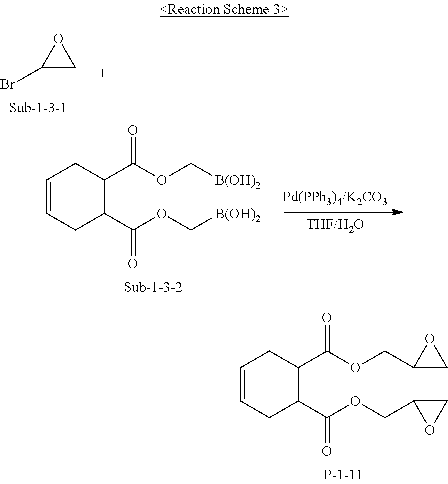

After dissolving Sub-1-3-1 (5.36 g, 44 mmol) in THF in a round-bottom flask, Sub-1-3-2 (5.72 g, 20 mmol), Pd(PPh₃)₄ (0.69 g, 0.6 mmol), K₂CO₃ (8.29 g, 60 mmol), and water were added thereto, and the mixture was stirred at 80 °C. When the reaction was completed, extraction was performed with CH₂Cl₂ and water, and then the organic layer was dried over MgSO₄ and concentrated, and the resulting compound was purified by silica gel column chromatography and recrystallization to obtain 4.51 g of a product.

### 4. Synthesis of P-1-14

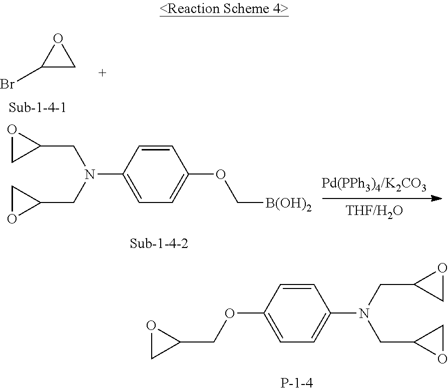

Sub-1-4-1 (2.56 g, 21 mmol) was dissolved in THF in a round-bottom flask, and then Sub-1-4-2 (5.63 g, 20.2 mmol), Pd(PPh₃)₄ (0.69 g, 0.6 mmol), K₂CO₃ (8.29 g, 60 mmol), and water were added thereto, followed by stirring at 80 °C. When the reaction was completed, extraction was performed with CH₂Cl₂ and water, and then the organic layer was dried over MgSO₄ and concentrated, and the resulting compound was purified by silica gel column chromatography and recrystallization to obtain 4.43 g of a product.

### 5. Synthesis of P-1-29

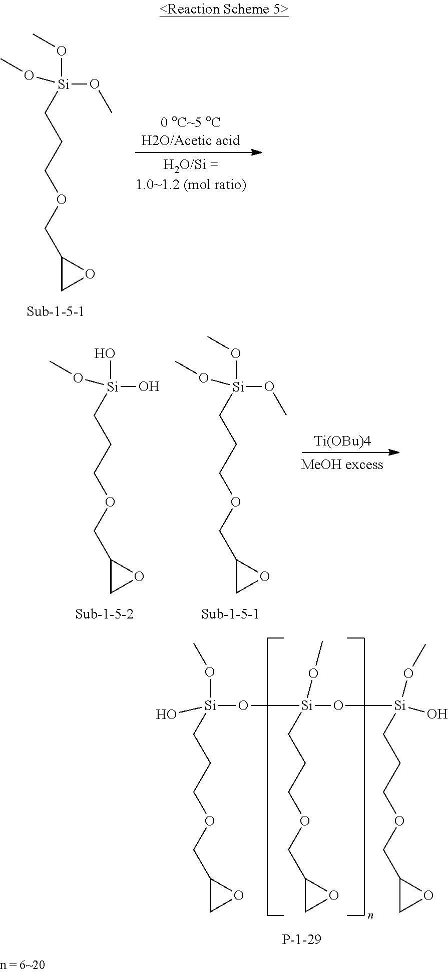

Sub-1-5-1 was dissolved in distilled water, and then acetic acid was added dropwise thereto, followed by stirring while maintaining a low temperature of 0 to 5 °C, and distillation under reduced pressure at 30 °C or lower to obtain an intermediate product Sub-1-5-2. At this time, the molar ratio of distilled water to Si was maintained at 1.0 to 1.2. Thereafter, Ti(OBu)₄ and MeOH were added to Sub-1-5-2 and Sub-1-5-1 to obtain a product. The degree of polymerization (n) of the product may be adjusted by adjusting the molar ratio of water to Si or by adding a catalyst.

### 6. Synthesis of P-1-32

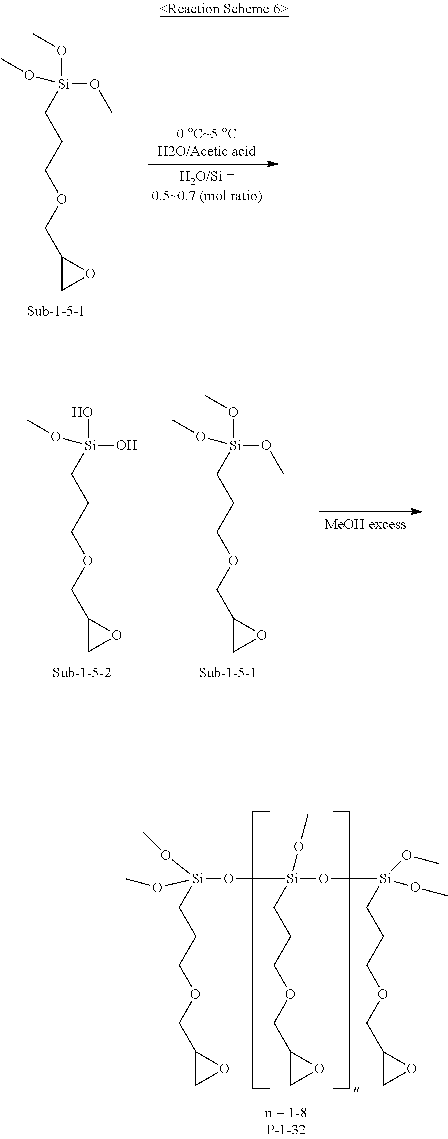

Sub-1-5-1 was dissolved in distilled water, and then acetic acid was added dropwise thereto, followed by stirring while maintaining a low temperature of 0 to 5 °C, and distillation under reduced pressure at 30 °C or lower to obtain an intermediate product Sub-1-5-2. At this time, the molar ratio of distilled water to Si was maintained at 0.5 to 0.7. Thereafter, MeOH was added to Sub-1-5-2 and Sub-1-5-1 to obtain a product. The degree of polymerization (n) of the product may be adjusted by adjusting the molar ratio of water to Si or by adding a catalyst.

### 7. Synthesis of P-1-61

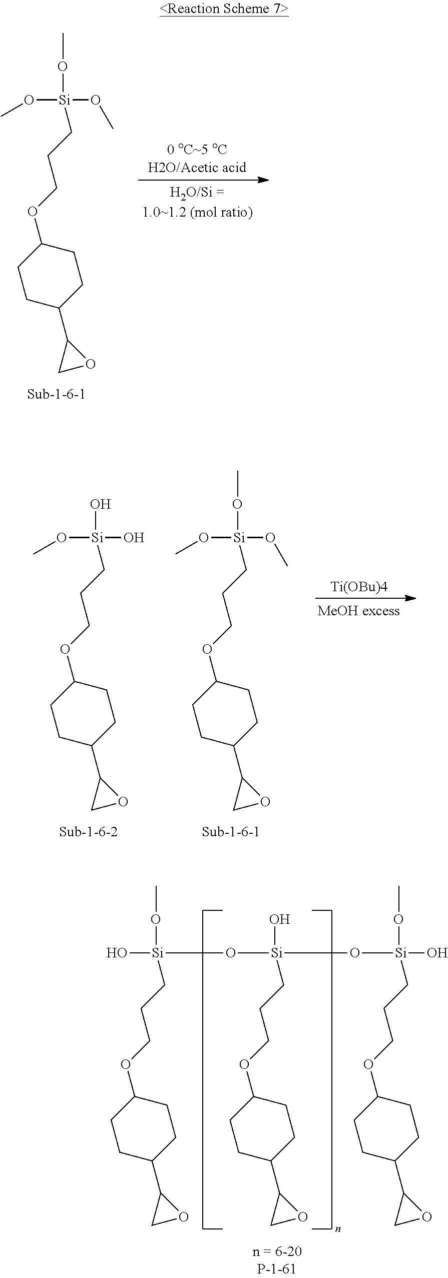

Sub-1-6-1 was dissolved in distilled water, and then acetic acid was added dropwise thereto, followed by stirring while maintaining a low temperature of 0 to 5 °C, and distillation under reduced pressure at 30 °C or lower to obtain an intermediate product Sub-1-6-2. At this time, the molar ratio of distilled water to Si was maintained at 1.0 to 1.2. Thereafter, Ti(OBu)₄ and MeOH were added to Sub-1-6-2 and Sub-1-6-1 to obtain a product. The degree of polymerization (n) of the product may be adjusted by adjusting the molar ratio of water to Si or by adding a catalyst.

### 8. Synthesis of P-1-67

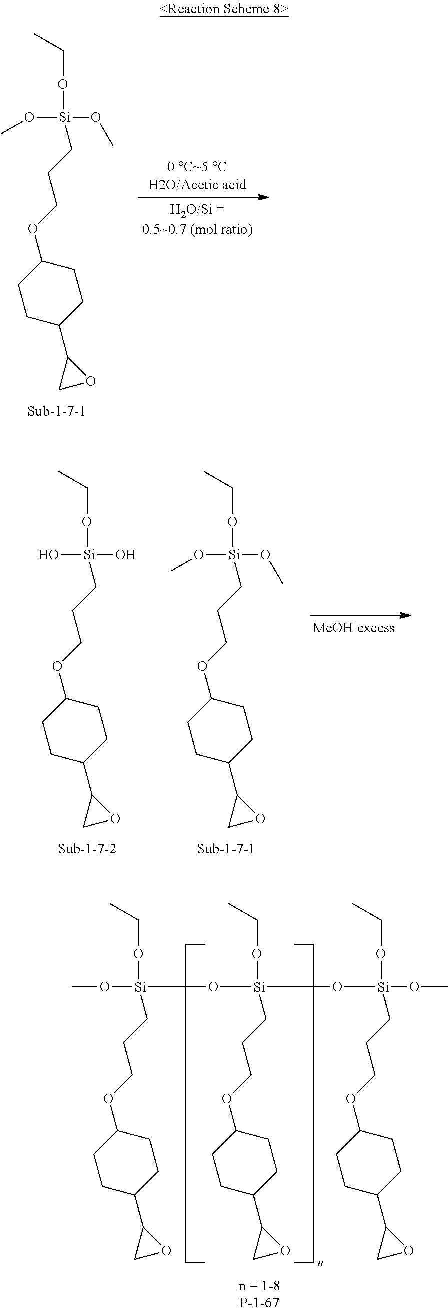

Sub-1-7-1 was dissolved in distilled water, acetic acid was added dropwise thereto, and the mixture was maintained at a low temperature of 0 to 5 °C, stirred, and distilled under reduced pressure at 30 °C or lower to obtain an intermediate product Sub-1-7-2. At this time, a molar ratio of the distilled water to Si was maintained at 0.5 to 0.7. Thereafter, MeOH was added to Sub-1-7-2 and Sub-1-7-1 to obtain a product. The degree of polymerization (n) of the product can be adjusted by adjusting a molar ratio of water to Si or by adding a catalyst.

### 9. Synthesis of P-1-69

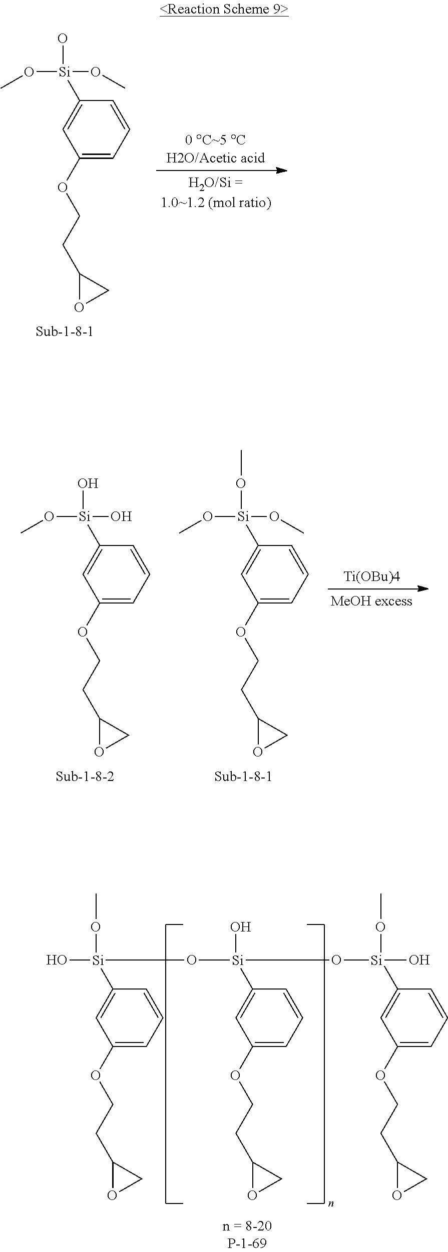

Sub-1-8-1 was dissolved in distilled water, acetic acid was added dropwise thereto, and the mixture was maintained at a low temperature of 0 to 5 °C, stirred, and distilled under reduced pressure at 30 °C or lower to obtain an intermediate product Sub-1-8-2. At this time, a molar ratio of the distilled water to Si was maintained at 1.0 to 1.2. Thereafter, Ti(OBu)₄ and MeOH were added to Sub-1-8-2 and Sub-1-8-1 to obtain a product. The degree of polymerization (n) of the product can be adjusted by adjusting a molar ratio of water to Si or by adding a catalyst.

### 10. Synthesis of P-1-75

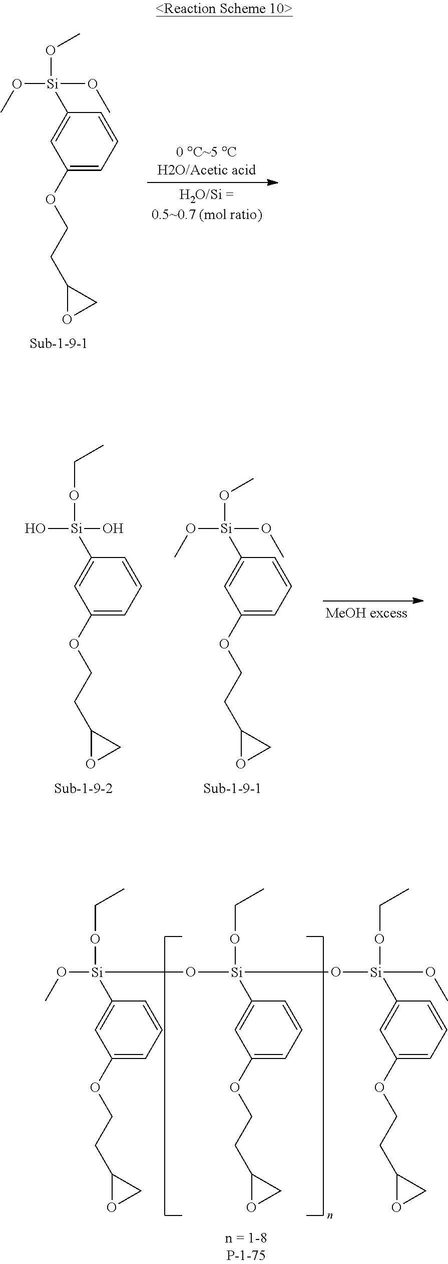

Sub-1-9-1 was dissolved in distilled water, acetic acid was added dropwise thereto, and the mixture was maintained at a low temperature of 0 to 5 °C, stirred, and distilled under reduced pressure at 30 °C or lower to obtain an intermediate product Sub-1-9-2. At this time, a molar ratio of the distilled water to Si was maintained at 0.5 to 0.7. Thereafter, MeOH was added to Sub-1-9-2 and Sub-1-9-1 to obtain a product. The degree of polymerization (n) of the product can be adjusted by adjusting a molar ratio of water to Si or by adding a catalyst.

### 11. Synthesis of P-1-85

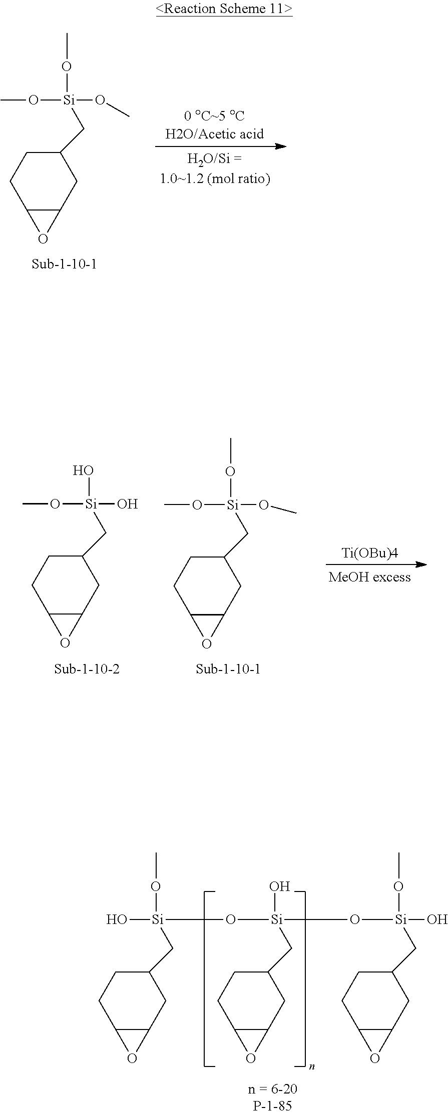

Sub-1-10-1 was dissolved in distilled water, acetic acid was added dropwise thereto, and the mixture was maintained at a low temperature of 0 to 5 °C, stirred, and distilled under reduced pressure at 30 °C or lower to obtain an intermediate product Sub-1-10-2. At this time, a molar ratio of the distilled water to Si was maintained at 1.0 to 1.2. Thereafter, Ti(OBu)₄ and MeOH were added to Sub-1-10-2 and Sub-1-10-1 to obtain a product. The degree of polymerization (n) of the product can be adjusted by adjusting a molar ratio of water to Si or by adding a catalyst.

### 12. Synthesis of P-1-91

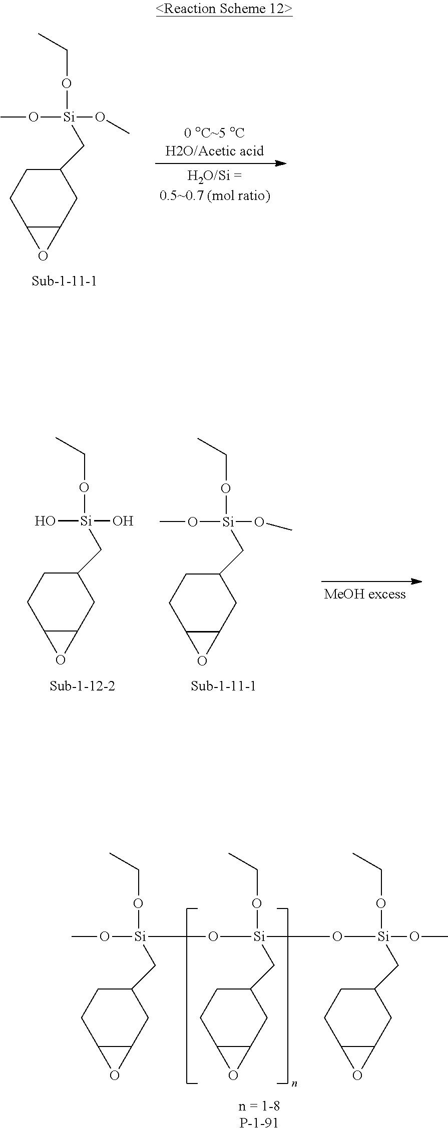

After dissolving Sub-1-11-1 in distilled water, acetic acid was added dropwise, and the mixture was stirred while maintaining a low temperature of 0 to 5 °C, followed by distillation under reduced pressure at 30 °C or lower to obtain an intermediate product Sub-1-11-2. At this time, the molar ratio of distilled water to Si was maintained at 0.5 to 0.7. Thereafter, MeOH was added to Sub-1-11-2 and Sub-1-11-1 to obtain a product. The degree of polymerization (n) of the product may be controlled by adjusting the molar ratio of water to Si or by adding a catalyst.

### 13. Synthesis of P-1-109

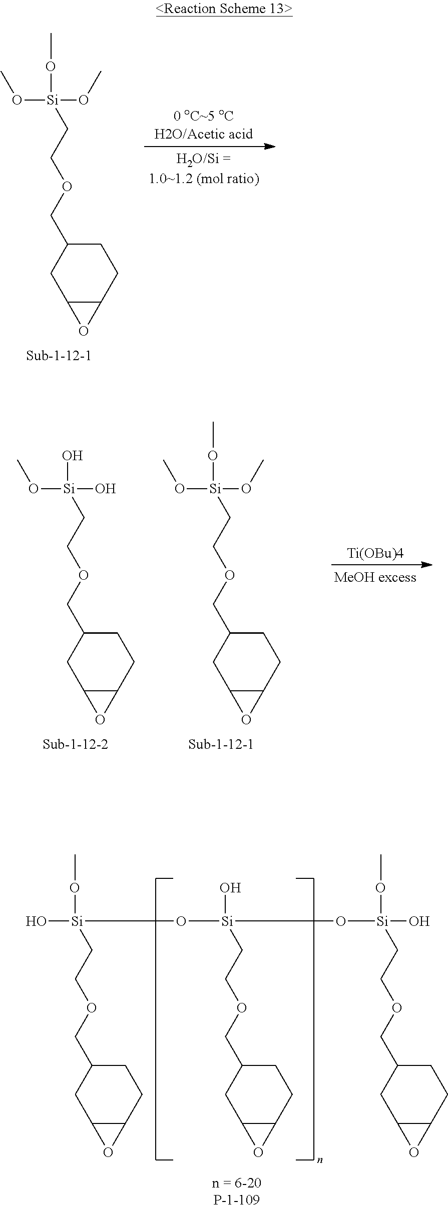

After dissolving Sub-1-12-1 in distilled water, acetic acid was added dropwise, and the mixture was stirred while maintaining a low temperature of 0 to 5 °C, followed by distillation under reduced pressure at 30 °C or lower to obtain an intermediate product Sub-1-12-2. At this time, the molar ratio of distilled water to Si was maintained at 1.0 to 1.2. Thereafter, Ti(OBu)₄ and MeOH were added to Sub-1-12-2 and Sub-1-12-1 to obtain a product. The degree of polymerization (n) of the product may be controlled by adjusting the molar ratio of water to Si or by adding a catalyst.

### 14. Synthesis of P-1-115

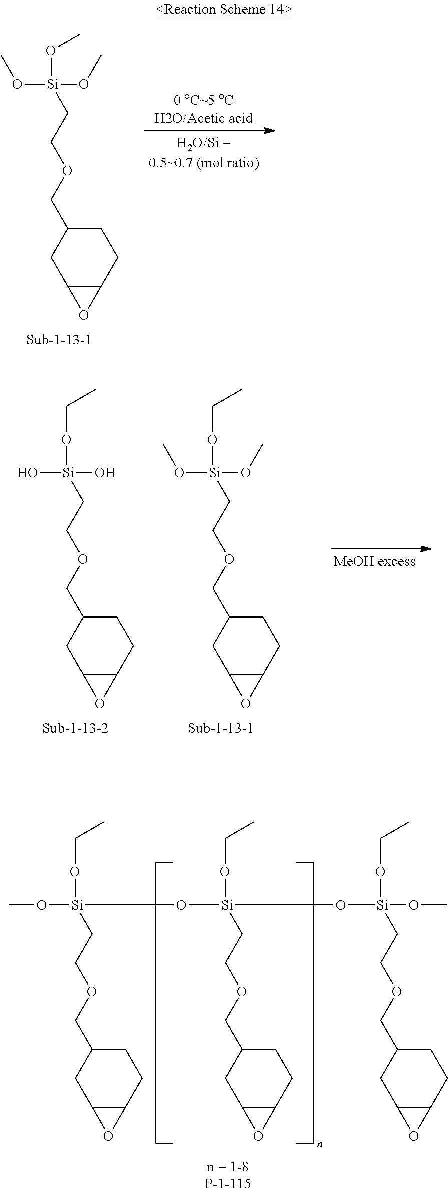

After dissolving Sub-1-13-1 in distilled water, acetic acid was added dropwise, and the mixture was stirred while maintaining a low temperature of 0 to 5 °C, followed by distillation under reduced pressure at 30 °C or lower to obtain an intermediate product Sub-1-13-2. At this time, the molar ratio of distilled water to Si was maintained at 0.5 to 0.7. Thereafter, MeOH was added to Sub-1-13-2 and Sub-1-13-1 to obtain a product. The degree of polymerization (n) of the product may be controlled by adjusting the molar ratio of water to Si or by adding a catalyst.

The compound represented by Chemical Formula 2 according to the present disclosure may be synthesized through reactions such as Reaction Schemes 15 to 20 below, but the compound represented by Chemical Formula 2 according to the present disclosure is not limited to being synthesized through such reaction schemes.

### 1. Synthesis of P-2-1

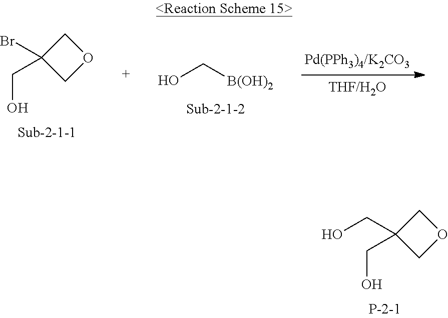 [SMILES: OCC1(Br)COC1 ; OCB(O)O ; OCC1(CO)COC1]

After dissolving Sub-2-1-1 (3.32 g, 20 mmol) in THF in a round-bottom flask, Sub-2-1-2 (1.52 g, 20 mmol), Pd(PPh₃)₄ (0.69 g, 0.6 mmol), K₂CO₃ (8.29 g, 60 mmol), and water were added thereto, and the mixture was stirred at 80 °C. When the reaction was completed, extraction was performed with CH₂Cl₂ and water, and then the organic layer was dried over MgSO₄ and concentrated, and the resulting compound was purified by silica gel column chromatography and recrystallization to obtain 1.95 g of a product.

### 2. Synthesis of P-2-5

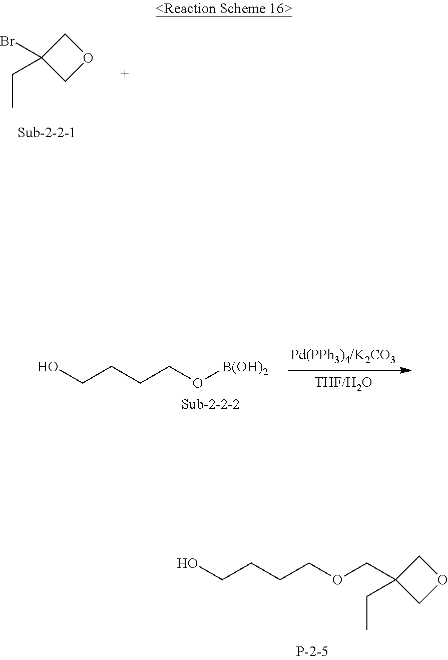

After dissolving Sub-2-2-1 (3.44 g, 21 mmol) in THF in a round-bottom flask, Sub-2-2-2 (2.71 g, 20.2 mmol), Pd(PPh3)4 (0.69 g, 0.6 mmol), K2CO3 (8.29 g, 60 mmol), and water were added thereto, and the mixture was stirred at 80 °C. When the reaction was completed, extraction was performed with CH2Cl2 and water, and then the organic layer was dried over MgSO4 and concentrated, and the resulting compound was purified by silica gel column chromatography and recrystallization to obtain 2.91 g of a product.

### 3. Synthesis of P-2-21

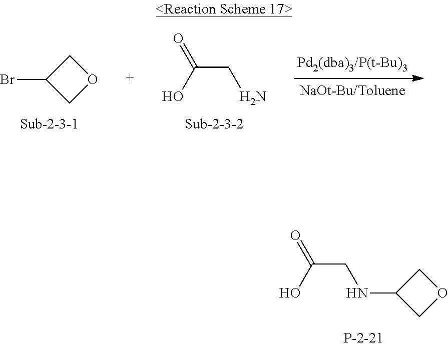 [SMILES: BrC1COC1 ; NCC(=O)O ; O=C(O)CNC1COC1]

After dissolving Sub-2-3-1 (3.4 g, 25 mmol) in toluene in a round-bottom flask, Sub-2-3-2 (3.75 g, 50 mmol), Pd₂(dba)₃ (0.7 g, 0.8 mmol), 50% P(t-Bu)₃ (1 ml, 2 mmol), and NaOt-Bu (7.34 g, 76.3 mmol) were added thereto, and the mixture was stirred at 40 °C. When the reaction was completed, extraction was performed with CH₂Cl₂ and water, and then the organic layer was dried over MgSO₄ and concentrated, and the resulting compound was purified by silica gel column chromatography and recrystallization to obtain 2.23 g of a product.

### 4. Synthesis of P-2-60

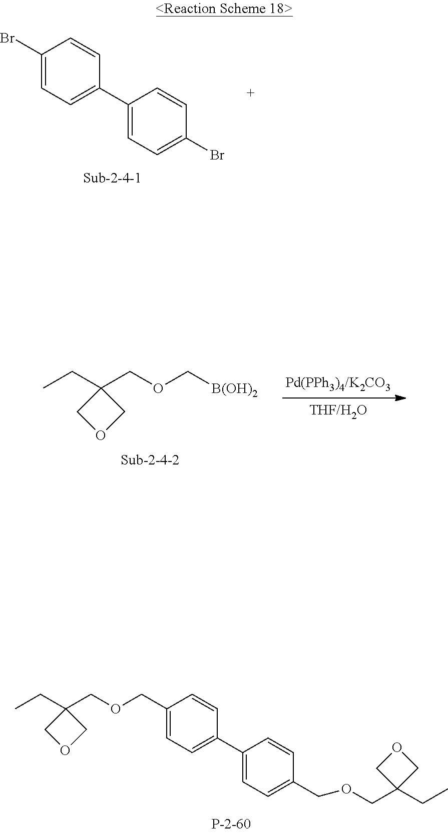 [SMILES: Brc1ccc(-c2ccc(Br)cc2)cc1 ; CCC1(COCB(O)O)COC1 ; CCC1(COCc2ccc(-c3ccc(COCC4(CC)COC4)cc3)cc2)COC1]

After dissolving Sub-2-4-1 (6.2 g, 20 mmol) in THF in a round-bottom flask, Sub-2-4-2 (7.65 g, 44 mmol), Pd(PPh₃)₄ (0.69 g, 0.6 mmol), K₂CO₃ (8.28 g, 59.9 mmol), and water were added thereto, and the mixture was stirred at 80 °C. When the reaction was completed, extraction was performed with CH₂Cl₂ and water, and then the organic layer was dried over MgSO₄ and concentrated, and the resulting compound was purified by silica gel column chromatography and recrystallization to obtain 6.15 g of a product.

### 5. Synthesis of P-2-32

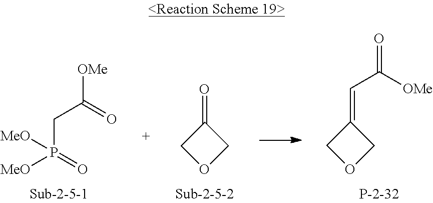 [SMILES: COC(=O)CP(=O)(OC)OC ; O=C1COC1 ; COC(=O)C=C1COC1]

25 ml of tetrahydrofuran (THF) and NaH (725 mg) were added to a reactor substituted with N₂ gas, the reactor was cooled to 0 °C, and Sub-2-5-1 (5 g, 27.47 mmol) was diluted in 10 ml of THF and then added dropwise while maintaining the temperature at 0 °C, followed by stirring for 1 hour to form an enolate. Sub-2-5-2 (1.98 g, 27.5 mmol) was dissolved in THF and slowly added to the enolate solution, the temperature was raised to 20 to 25 °C and the mixture was stirred for 1 hour, and then NH₄Cl was added at 0 °C to remove NaH, and after purification with ethyl acetate and distillation under reduced pressure, 2.94 g of a product was obtained.

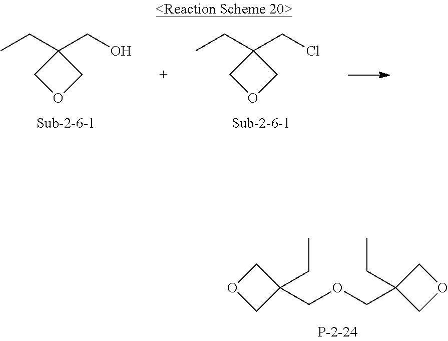

Sub-2-6-1 (3.13 g, 27 mmol) was dissolved in toluene in a round-bottom flask, the temperature was raised to 100 °C, Sub-2-6-2 (3.98 g, 29.7 mmol) and a 30 wt % NaOH aqueous solution (3.24 ml) were simultaneously added dropwise, and the temperature was maintained for 3 hours. After the reaction was completed, the mixture was washed with water, toluene was recovered under reduced pressure, and then distillation was performed to obtain 4.34 g of a product.

### Preparation Example 1: Preparation of Black Colorant

15 g of Carbon Black W-7016 (Basf), 8.5 g of Disperbyk 163 (BYK), and 6.5 g of SR-3613 (SMS) were dispersed together with 70 g of propylene glycol methyl ether acetate for 10 hours using 100 g of zirconia beads (Toray) having a diameter of 0.5 mm in a paint shaker (Asada) to obtain a dispersion.

### [1. Preparation of Protective Layer Composition]

Protective layer compositions for a panel lower protective layer were prepared with compositions (wt %) as shown in Table 1 below.

TABLE 1

| | Example | Example | Example | Example | Example | Example | Example | Example | Example | Example |
|---|---|---|---|---|---|---|---|---|---|---|
| | 1 | 2 | 3 | 4 | 5 | 6 | 7 | 8 | 9 | 10 |
| Black | 10 | 10 | 10 | 10 | 10 | 10 | 10 | 10 | 10 | 10 |
| Colorant | | | | | | | | | | |
| P-1-1 | 22.5 | | | | | | | | | |
| P-1-2 | | 22.5 | | | | | | | | |
| P-1-19 | | | 22.5 | | | | | | | |
| P-1-18 | | | | 22.5 | | | | | | |
| P-1-16 | | | | | 22.5 | | | | | |
| P-1-6 | | | | | | 22.5 | | | | |
| P-1-10 | | | | | | | 22.5 | | | |
| P-1-12 | | | | | | | | 22.5 | | |
| P-1-14 | | | | | | | | | 22.5 | |
| P-1-20 | | | | | | | | | | 22.5 |
| P-2-2 | 21.96 | 21.96 | 21.96 | 21.96 | 21.96 | 21.96 | 21.96 | 21.96 | 21.96 | 21.96 |
| Acrylate- | 14.04 | 14.04 | 14.04 | 14.04 | 14.04 | 14.04 | 14.04 | 14.04 | 14.04 | 14.04 |
| based | | | | | | | | | | |
| additive | | | | | | | | | | |
| M140 | | | | | | | | | | |
| (Miwon | | | | | | | | | | |
| Co.) | | | | | | | | | | |
| Acrylate- | 10 | 10 | 10 | 10 | 10 | 10 | 10 | 10 | 10 | 10 |
| based | | | | | | | | | | |
| additive | | | | | | | | | | |
| HDDA | | | | | | | | | | |
| (Miwon | | | | | | | | | | |
| Co.) | | | | | | | | | | |
| Initiator TPO | 6 | 6 | 6 | 6 | 6 | 6 | 6 | 6 | 6 | 6 |
| Initiator NIT | 15 | 15 | 15 | 15 | 15 | 15 | 15 | 15 | 15 | 15 |
| Adhesion | 0.5 | 0.5 | 0.5 | 0.5 | 0.5 | 0.5 | 0.5 | 0.5 | 0.5 | 0.5 |
| promoter | | | | | | | | | | |
| KBM-403 | | | | | | | | | | |
| (SHINETSU | | | | | | | | | | |
| Co.) | | | | | | | | | | |
| | Example | Example | Example | Example | Example | Example | Example | Example | Example | Example |
| | 11 | 12 | 13 | 14 | 15 | 16 | 17 | 18 | 19 | 20 |
| Black | 10 | 10 | 10 | 10 | 10 | 10 | 10 | 10 | 10 | 10 |
| Colorant | | | | | | | | | | |
| P-1-22 | 22.5 | | | | | | | | | |
| P-1-24 | | 22.5 | | | | | | | | |
| P-1-26 | | | 22.5 | | | | | | | |
| P-1-28 | | | | 22.5 | | | | | | |
| P-1-29 | | | | | 22.5 | | | | | |
| P-1-30 | | | | | | 22.5 | | | | |
| P-1-31 | | | | | | | 22.5 | | | |
| P-1-32 | | | | | | | | 22.5 | | |
| P-1-33 | | | | | | | | | 22.5 | |
| P-1-34 | | | | | | | | | | 22.5 |
| P-2-2 | 21.96 | | | | | | | | | |
| P-2-5 | | 21.96 | 21.96 | 21.96 | 21.96 | 21.96 | 21.96 | 21.96 | 21.96 | 21.96 |
| Acrylate- | 14.04 | 14.04 | 14.04 | 14.04 | 14.04 | 14.04 | 14.04 | 14.04 | 14.04 | 14.04 |
| based | | | | | | | | | | |
| additive | | | | | | | | | | |
| M140 | | | | | | | | | | |
| (Miwon | | | | | | | | | | |
| Co.) | | | | | | | | | | |
| Acrylate- | 10 | 10 | 10 | 10 | 10 | 10 | 10 | 10 | 10 | 10 |
| based | | | | | | | | | | |
| additive | | | | | | | | | | |
| HDDA | | | | | | | | | | |
| (Miwon | | | | | | | | | | |
| Co.) | | | | | | | | | | |
| Initiator TPO | 6 | 6 | 6 | 6 | 6 | 6 | 6 | 6 | 6 | 6 |
| Initiator NIT | 15 | 15 | 15 | 15 | 15 | 15 | 15 | 15 | 15 | 15 |
| Adhesion | 0.5 | 0.5 | 0.5 | 0.5 | 0.5 | 0.5 | 0.5 | 0.5 | 0.5 | 0.5 |
| promoter | | | | | | | | | | |
| KBM-403 | | | | | | | | | | |
| (SHINETSU | | | | | | | | | | |
| Co.) | | | | | | | | | | |
| | Example | Example | Example | Example | Example | Example | Example | Example | Example | Example |
| | 21 | 22 | 23 | 24 | 25 | 26 | 27 | 28 | 29 | 30 |
| Black | 10 | 10 | 10 | 10 | 10 | 10 | 10 | 10 | 10 | 10 |
| Colorant | | | | | | | | | | |
| P-1-35 | 22.5 | | | | | | | | | |
| P-1-36 | | 22.5 | | | | | | | | |
| P-1-38 | | | 22.5 | | | | | | | |
| P-1-40 | | | | 22.5 | | | | | | |
| P-1-42 | | | | | 22.5 | | | | | |
| P-1-44 | | | | | | 22.5 | | | | |
| P-1-50 | | | | | | | 22.5 | | | |
| P-1-54 | | | | | | | | 22.5 | | |
| P-1-58 | | | | | | | | | 22.5 | |
| P-1-66 | | | | | | | | | | 22.5 |
| P-2-5 | 21.96 | 21.96 | | | | | | | | |
| P-2-8 | | | 21.96 | 21.96 | 21.96 | 21.96 | 21.96 | 21.96 | 21.96 | 21.96 |
| Acrylate- | 14.04 | 14.04 | 14.04 | 14.04 | 14.04 | 14.04 | 14.04 | 14.04 | 14.04 | 14.04 |
| based | | | | | | | | | | |
| additive | | | | | | | | | | |
| M140 | | | | | | | | | | |
| (Miwon | | | | | | | | | | |
| Co.) | | | | | | | | | | |
| Acrylate- | 10 | 10 | 10 | 10 | 10 | 10 | 10 | 10 | 10 | 10 |
| based | | | | | | | | | | |
| additive | | | | | | | | | | |
| HDDA | | | | | | | | | | |
| (Miwon | | | | | | | | | | |
| Co.) | | | | | | | | | | |
| Initiator TPO | 6 | 6 | 6 | 6 | 6 | 6 | 6 | 6 | 6 | 6 |
| Initiator NIT | 15 | 15 | 15 | 15 | 15 | 15 | 15 | 15 | 15 | 15 |
| Adhesion | 0.5 | 0.5 | 0.5 | 0.5 | 0.5 | 0.5 | 0.5 | 0.5 | 0.5 | 0.5 |
| promoter | | | | | | | | | | |
| KBM-403 | | | | | | | | | | |
| (SHINETSU | | | | | | | | | | |
| Co.) | | | | | | | | | | |
| | Example | Example | Example | Example | Example | Example | Example | Example | Example | Example |
| | 31 | 32 | 33 | 34 | 35 | 36 | 37 | 38 | 39 | 40 |
| Black | 10 | 10 | 10 | 10 | 10 | 10 | 10 | 10 | 10 | 10 |
| Colorant | | | | | | | | | | |
| P-1-1 | 23.1 | | | | | | | | | |
| P-1-2 | | 23.1 | | | | | | | | |
| P-1-19 | | | 23.1 | | | | | | | |
| P-1-18 | | | | 23.1 | | | | | | |
| P-1-16 | | | | | 23.1 | | | | | |
| P-1-6 | | | | | | 23.1 | | | | |
| P-1-10 | | | | | | | 23.1 | | | |
| P-1-12 | | | | | | | | 23.1 | | |
| P-1-14 | | | | | | | | | 23.1 | |
| P-1-20 | | | | | | | | | | 23.1 |
| P-2-8 | 21.36 | 21.36 | 21.36 | | | | | | | |
| P-2-15 | | | | 21.36 | 21.36 | 21.36 | 21.36 | 21.36 | 21.36 | 21.36 |
| Acrylate- | 14.04 | 14.04 | 14.04 | 14.04 | 14.04 | 14.04 | 14.04 | 14.04 | 14.04 | 14.04 |
| based | | | | | | | | | | |
| additive | | | | | | | | | | |
| M140 | | | | | | | | | | |
| (Miwon | | | | | | | | | | |
| Co.) | | | | | | | | | | |
| Acrylate- | 10 | 10 | 10 | 10 | 10 | 10 | 10 | 10 | 10 | 10 |
| based | | | | | | | | | | |
| additive | | | | | | | | | | |
| HDDA | | | | | | | | | | |
| (Miwon | | | | | | | | | | |
| Co.) | | | | | | | | | | |
| Initiator TPO | 6 | 6 | 6 | 6 | 6 | 6 | 6 | 6 | 6 | 6 |
| Initiator NIT | 15 | 15 | 15 | 15 | 15 | 15 | 15 | 15 | 15 | 15 |
| Adhesion | 0.5 | 0.5 | 0.5 | 0.5 | 0.5 | 0.5 | 0.5 | 0.5 | 0.5 | 0.5 |
| promoter | | | | | | | | | | |
| KBM-403 | | | | | | | | | | |
| (SHINETSU | | | | | | | | | | |
| Co.) | | | | | | | | | | |
| | Example | Example | Example | Example | Example | Example | Example | Example | Example | Example |
| | 41 | 42 | 43 | 44 | 45 | 46 | 47 | 48 | 49 | 50 |
| Black | 10 | 10 | 10 | 10 | 10 | 10 | 10 | 10 | 10 | 10 |
| Colorant | | | | | | | | | | |
| P-1-22 | 23.1 | | | | | | | | | |
| P-1-24 | | 23.1 | | | | | | | | |
| P-1-26 | | | 23.1 | | | | | | | |
| P-1-28 | | | | 23.1 | | | | | | |
| P-1-29 | | | | | 23.1 | | | | | |
| P-1-30 | | | | | | 23.1 | | | | |
| P-1-31 | | | | | | | 23.1 | | | |
| P-1-32 | | | | | | | | 23.1 | | |
| P-1-33 | | | | | | | | | 23.1 | |
| P-1-34 | | | | | | | | | | 23.1 |
| P-2-15 | 21.36 | 21.36 | 21.36 | 21.36 | | | | | | |
| P-2-24 | | | | | 21.36 | 21.36 | 21.36 | 21.36 | 21.36 | 21.36 |
| Acrylate- | 14.04 | 14.04 | 14.04 | 14.04 | 14.04 | 14.04 | 14.04 | 14.04 | 14.04 | 14.04 |
| based | | | | | | | | | | |
| additive | | | | | | | | | | |
| M140 | | | | | | | | | | |
| (Miwon | | | | | | | | | | |
| Co.) | | | | | | | | | | |
| Acrylate- | 10 | 10 | 10 | 10 | 10 | 10 | 10 | 10 | 10 | 10 |
| based | | | | | | | | | | |
| additive | | | | | | | | | | |
| HDDA | | | | | | | | | | |
| (Miwon | | | | | | | | | | |
| Co.) | | | | | | | | | | |
| Initiator TPO | 6 | 6 | 6 | 6 | 6 | 6 | 6 | 6 | 6 | 6 |
| Initiator NIT | 15 | 15 | 15 | 15 | 15 | 15 | 15 | 15 | 15 | 15 |
| Adhesion | 0.5 | 0.5 | 0.5 | 0.5 | 0.5 | 0.5 | 0.5 | 0.5 | 0.5 | 0.5 |
| promoter | | | | | | | | | | |
| KBM-403 | | | | | | | | | | |
| (SHINETSU | | | | | | | | | | |
| Co.) | | | | | | | | | | |
| | Example | Example | Example | Example | Example | Example | Example | Example | Example | Example |
| | 51 | 52 | 53 | 54 | 55 | 56 | 57 | 58 | 59 | 60 |
| Black | 10 | 10 | 10 | 10 | 10 | 10 | 10 | 10 | 10 | 10 |
| Colorant | | | | | | | | | | |
| P-1-35 | 23.1 | | | | | | | | | |
| P-1-36 | | 23.1 | | | | | | | | |
| P-1-38 | | | 23.1 | | | | | | | |
| P-1-40 | | | | 23.1 | | | | | | |
| P-1-42 | | | | | 23.1 | | | | | |
| P-1-44 | | | | | | 23.1 | | | | |
| P-1-50 | | | | | | | 23.1 | | | |
| P-1-54 | | | | | | | | 23.1 | | |
| P-1-58 | | | | | | | | | 23.1 | |
| P-1-66 | | | | | | | | | | 23.1 |
| P-2-24 | 21.36 | 21.36 | 21.36 | 21.36 | 21.36 | | | | | |
| P-2-32 | | | | | | 21.36 | 21.36 | 21.36 | 21.36 | 21.36 |
| Acrylate- | 14.04 | 14.04 | 14.04 | 14.04 | 14.04 | 14.04 | 14.04 | 14.04 | 14.04 | 14.04 |
| based | | | | | | | | | | |
| additive | | | | | | | | | | |
| M140 | | | | | | | | | | |
| (Miwon | | | | | | | | | | |
| Co.) | | | | | | | | | | |
| Acrylate- | 10 | 10 | 10 | 10 | 10 | 10 | 10 | 10 | 10 | 10 |
| based | | | | | | | | | | |
| additive | | | | | | | | | | |
| HDDA | | | | | | | | | | |
| (Miwon | | | | | | | | | | |
| Co.) | | | | | | | | | | |
| Initiator TPO | 6 | 6 | 6 | 6 | 6 | 6 | 6 | 6 | 6 | 6 |
| Initiator NIT | 15 | 15 | 15 | 15 | 15 | 15 | 15 | 15 | 15 | 15 |
| Adhesion | 0.5 | 0.5 | 0.5 | 0.5 | 0.5 | 0.5 | 0.5 | 0.5 | 0.5 | 0.5 |
| promoter | | | | | | | | | | |
| KBM-403 | | | | | | | | | | |
| (SHINETSU | | | | | | | | | | |
| Co.) | | | | | | | | | | |
| | Example | Example | Example | Example | Example | Example | Example | Example | Example | Example |
| | 61 | 62 | 63 | 64 | 65 | 66 | 67 | 68 | 69 | 70 |
| Black | 10 | 10 | 10 | 10 | 10 | 10 | 10 | 10 | 10 | 10 |
| Colorant | | | | | | | | | | |
| P-1-74 | 24.3 | | | | | | | | | |
| P-1-78 | | 24.3 | | | | | | | | |
| P-1-86 | | | 24.3 | | | | | | | |
| P-1-90 | | | | 24.3 | | | | | | |
| P-1-94 | | | | | 24.3 | | | | | |
| P-1-98 | | | | | | 24.3 | | | | |
| P-1-104 | | | | | | | 24.3 | | | |
| P-1-108 | | | | | | | | 24.3 | | |
| P-1-110 | | | | | | | | | 24.3 | |
| P-1-111 | | | | | | | | | | 24.3 |
| P-2-32 | 20.16 | 20.16 | 20.16 | 20.16 | 20.16 | 20.16 | | | | |
| P-2-40 | | | | | | | 20.16 | 20.16 | 20.16 | 20.16 |
| Acrylate- | 14.04 | 14.04 | 14.04 | 14.04 | 14.04 | 14.04 | 14.04 | 14.04 | 14.04 | 14.04 |
| based | | | | | | | | | | |
| additive | | | | | | | | | | |
| M140 | | | | | | | | | | |
| (Miwon | | | | | | | | | | |
| Co.) | | | | | | | | | | |
| Acrylate- | 10 | 10 | 10 | 10 | 10 | 10 | 10 | 10 | 10 | 10 |
| based | | | | | | | | | | |
| additive | | | | | | | | | | |
| HDDA | | | | | | | | | | |
| (Miwon | | | | | | | | | | |
| Co.) | | | | | | | | | | |
| Initiator TPO | 6 | 6 | 6 | 6 | 6 | 6 | 6 | 6 | 6 | 6 |
| Initiator NIT | 15 | 15 | 15 | 15 | 15 | 15 | 15 | 15 | 15 | 15 |
| Adhesion | 0.5 | 0.5 | 0.5 | 0.5 | 0.5 | 0.5 | 0.5 | 0.5 | 0.5 | 0.5 |
| promoter | | | | | | | | | | |
| KBM-403 | | | | | | | | | | |
| (SHINETSU | | | | | | | | | | |
| Co.) | | | | | | | | | | |
| | Example | Example | Example | Example | Example | Example | Example | Example | Example | Example |
| | 71 | 72 | 73 | 74 | 75 | 76 | 77 | 78 | 79 | 80 |
| Black | 10 | 10 | 10 | 10 | 10 | 10 | 10 | 10 | 10 | 10 |
| Colorant | | | | | | | | | | |
| P-1-1 | | | | | | | | 24.3 | | |
| P-1-18 | | | | | | | | | 24.3 | |
| P-1-12 | | | | | | | | | | 24.3 |
| P-1-118 | 24.3 | | | | | | | | | |
| P-1-122 | | 24.3 | | | | | | | | |
| P-1-126 | | | 24.3 | | | | | | | |
| P-1-130 | | | | 24.3 | | | | | | |
| P-1-134 | | | | | 24.3 | | | | | |
| P-1-138 | | | | | | 24.3 | | | | |
| P-1-140 | | | | | | | 24.3 | | | |
| P-2-40 | 20.16 | 20.16 | 20.16 | 20.16 | 20.16 | 20.16 | 20.16 | | | |
| P-2-56 | | | | | | | | 20.16 | 20.16 | 20.16 |
| Acrylate- | 14.04 | 14.04 | 14.04 | 14.04 | 14.04 | 14.04 | 14.04 | 14.04 | 14.04 | 14.04 |
| based | | | | | | | | | | |
| additive | | | | | | | | | | |
| M140 | | | | | | | | | | |
| (Miwon | | | | | | | | | | |
| Co.) | | | | | | | | | | |
| Acrylate- | 10 | 10 | 10 | 10 | 10 | 10 | 10 | 10 | 10 | 10 |
| based | | | | | | | | | | |
| additive | | | | | | | | | | |
| HDDA | | | | | | | | | | |
| (Miwon | | | | | | | | | | |
| Co.) | | | | | | | | | | |
| Initiator TPO | 6 | 6 | 6 | 6 | 6 | 6 | 6 | 6 | 6 | 6 |
| Initiator NIT | 15 | 15 | 15 | 15 | 15 | 15 | 15 | 15 | 15 | 15 |
| Adhesion | 0.5 | 0.5 | 0.5 | 0.5 | 0.5 | 0.5 | 0.5 | 0.5 | 0.5 | 0.5 |
| promoter | | | | | | | | | | |
| KBM-403 | | | | | | | | | | |
| (SHINETSU | | | | | | | | | | |
| Co.) | | | | | | | | | | |
| | Example | Example | Example | Example | Example | Example | Example | Example | Example | Example |
| | 81 | 82 | 83 | 84 | 85 | 86 | 87 | 88 | 89 | 90 |
| Black | 10 | 10 | 10 | 10 | 10 | 10 | 10 | 10 | 10 | 10 |
| Colorant | | | | | | | | | | |
| P-1-24 | 24.3 | | | | | | | | | |
| P-1-29 | | | | | | | | | 24.3 | |
| P-1-30 | | | | | | | | | | 24.3 |
| P-1-32 | | 24.3 | | | | | | | | |
| P-1-38 | | | 24.3 | | | | | | | |
| P-1-54 | | | | 24.3 | | | | | | |
| P-1-90 | | | | | 24.3 | | | | | |
| P-1-110 | | | | | | 24.3 | | | | |
| P-1-126 | | | | | | | 24.3 | | | |
| P-1-140 | | | | | | | | 24.3 | | |
| P-2-56 | 20.16 | 20.16 | 20.16 | 20.16 | 20.16 | 20.16 | 20.16 | 20.16 | | |
| P-2-61 | | | | | | | | | 20.16 | 20.16 |
| Acrylate- | 14.04 | 14.04 | 14.04 | 14.04 | 14.04 | 14.04 | 14.04 | 14.04 | 14.04 | 14.04 |
| based | | | | | | | | | | |
| additive | | | | | | | | | | |
| M140 | | | | | | | | | | |
| (Miwon | | | | | | | | | | |
| Co.) | | | | | | | | | | |
| Acrylate- | 10 | 10 | 10 | 10 | 10 | 10 | 10 | 10 | 10 | 10 |
| based | | | | | | | | | | |
| additive | | | | | | | | | | |
| HDDA | | | | | | | | | | |
| (Miwon | | | | | | | | | | |
| Co.) | | | | | | | | | | |
| Initiator TPO | 6 | 6 | 6 | 6 | 6 | 6 | 6 | 6 | 6 | 6 |
| Initiator NIT | 15 | 15 | 15 | 15 | 15 | 15 | 15 | 15 | 15 | 15 |
| Adhesion | 0.5 | 0.5 | 0.5 | 0.5 | 0.5 | 0.5 | 0.5 | 0.5 | 0.5 | 0.5 |
| promoter | | | | | | | | | | |
| KBM-403 | | | | | | | | | | |
| (SHINETSU | | | | | | | | | | |
| Co.) | | | | | | | | | | |
| | Example | Example | Example | Example | Example | Example | Example | Example | Example | Example |
| | 91 | 92 | 93 | 94 | 95 | 96 | 97 | 98 | 99 | 100 |
| Black | 10 | 10 | 10 | 10 | 10 | 10 | 10 | 10 | 10 | 10 |
| Colorant | | | | | | | | | | |
| P-1-31 | 25 | | | | | | | | | |
| P-1-32 | | 25 | | | | | | | | |
| P-1-33 | | | 25 | | | | | | | |
| P-1-34 | | | | 25 | | | | | | |
| P-1-35 | | | | | 25 | | | | | |
| P-1-36 | | | | | | 25 | | | | |
| P-1-38 | | | | | | | 25 | | | |
| P-1-40 | | | | | | | | 25 | | |
| P-1-42 | | | | | | | | | 25 | |
| P-1-44 | | | | | | | | | | 25 |
| P-2-61 | 19.46 | 19.46 | 19.46 | 19.46 | 19.46 | 19.46 | 19.46 | 19.46 | 19.46 | |
| P-2-63 | | | | | | | | | | 19.46 |
| Acrylate- | 14.04 | 14.04 | 14.04 | 14.04 | 14.04 | 14.04 | 14.04 | 14.04 | 14.04 | 14.04 |
| based | | | | | | | | | | |
| additive | | | | | | | | | | |
| M140 | | | | | | | | | | |
| (Miwon | | | | | | | | | | |
| Co.) | | | | | | | | | | |
| Acrylate- | 10 | 10 | 10 | 10 | 10 | 10 | 10 | 10 | 10 | 10 |
| based | | | | | | | | | | |
| additive | | | | | | | | | | |
| HDDA | | | | | | | | | | |
| (Miwon | | | | | | | | | | |
| Co.) | | | | | | | | | | |
| Initiator TPO | 6 | 6 | 6 | 6 | 6 | 6 | 6 | 6 | 6 | 6 |
| Initiator NIT | 15 | 15 | 15 | 15 | 15 | 15 | 15 | 15 | 15 | 15 |
| Adhesion | 0.5 | 0.5 | 0.5 | 0.5 | 0.5 | 0.5 | 0.5 | 0.5 | 0.5 | 0.5 |
| promoter | | | | | | | | | | |
| KBM-403 | | | | | | | | | | |
| (SHINETSU | | | | | | | | | | |
| Co.) | | | | | | | | | | |
| | Example | Example | Example | Example | Example | Example | Example | Example | Example | Example |
| | 101 | 102 | 103 | 104 | 105 | 106 | 107 | 108 | 109 | 110 |
| Black | 10 | 10 | 10 | 10 | 10 | 10 | 10 | 10 | 10 | 10 |
| Colorant | | | | | | | | | | |
| P-1-50 | 25 | | | | | | | | | |
| P-1-54 | | 25 | | | | | | | | |
| P-1-58 | | | 25 | | | | | | | |
| P-1-66 | | | | 25 | | | | | | |
| P-1-74 | | | | | 25 | | | | | |
| P-1-78 | | | | | | 25 | | | | |
| P-1-86 | | | | | | | 25 | | | |
| P-1-90 | | | | | | | | 25 | | |
| P-1-94 | | | | | | | | | 25 | |
| P-1-98 | | | | | | | | | | 25 |
| P-2-63 | 19.46 | 19.46 | 19.46 | 19.46 | 19.46 | 19.46 | 19.46 | 19.46 | 19.46 | 19.46 |
| Acrylate- | 14.04 | 14.04 | 14.04 | 14.04 | 14.04 | 14.04 | 14.04 | 14.04 | 14.04 | 14.04 |
| based | | | | | | | | | | |
| additive | | | | | | | | | | |
| M140 | | | | | | | | | | |
| (Miwon | | | | | | | | | | |
| Co.) | | | | | | | | | | |
| Acrylate- | 10 | 10 | 10 | 10 | 10 | 10 | 10 | 10 | 10 | 10 |
| based | | | | | | | | | | |
| additive | | | | | | | | | | |
| HDDA | | | | | | | | | | |
| (Miwon | | | | | | | | | | |
| Co.) | | | | | | | | | | |
| Initiator TPO | 6 | 6 | 6 | 6 | 6 | 6 | 6 | 6 | 6 | 6 |
| Initiator NIT | 15 | 15 | 15 | 15 | 15 | 15 | 15 | 15 | 15 | 15 |
| Adhesion | 0.5 | 0.5 | 0.5 | 0.5 | 0.5 | 0.5 | 0.5 | 0.5 | 0.5 | 0.5 |
| promoter | | | | | | | | | | |
| KBM-403 | | | | | | | | | | |
| (SHINETSU | | | | | | | | | | |
| Co.) | | | | | | | | | | |
| | Example | Example | Example | Example | Example | Example | Example | Example | Example | Example |
| | 111 | 112 | 113 | 114 | 115 | 116 | 117 | 118 | 119 | 120 |
| Black | 10 | 10 | 10 | 10 | 10 | 10 | 10 | 10 | 10 | 10 |
| Colorant | | | | | | | | | | |
| P-1-104 | 25 | | | | | | | | | |
| P-1-108 | | 25 | | | | | | | | |
| P-1-110 | | | 25 | | | | | | | |
| P-1-111 | | | | 25 | | | | | | |
| P-1-118 | | | | | 25 | | | | | |
| P-1-122 | | | | | | 25 | | | | |
| P-1-126 | | | | | | | 25 | | | |
| P-1-130 | | | | | | | | 25 | | |
| P-1-134 | | | | | | | | | 25 | |
| P-1-138 | | | | | | | | | | 25 |
| P-2-66 | 19.46 | 19.46 | 19.46 | 19.46 | 19.46 | 19.46 | 19.46 | 19.46 | 19.46 | 19.46 |
| Acrylate- | 14.04 | 14.04 | 14.04 | 14.04 | 14.04 | 14.04 | 14.04 | 14.04 | 14.04 | 14.04 |
| based | | | | | | | | | | |
| additive | | | | | | | | | | |
| M140 | | | | | | | | | | |
| (Miwon | | | | | | | | | | |
| Co.) | | | | | | | | | | |
| Acrylate- | 10 | 10 | 10 | 10 | 10 | 10 | 10 | 10 | 10 | 10 |
| based | | | | | | | | | | |
| additive | | | | | | | | | | |
| HDDA | | | | | | | | | | |
| (Miwon | | | | | | | | | | |
| Co.) | | | | | | | | | | |
| Initiator TPO | 6 | 6 | 6 | 6 | 6 | 6 | 6 | 6 | 6 | 6 |
| Initiator NIT | 15 | 15 | 15 | 15 | 15 | 15 | 15 | 15 | 15 | 15 |
| Adhesion | 0.5 | 0.5 | 0.5 | 0.5 | 0.5 | 0.5 | 0.5 | 0.5 | 0.5 | 0.5 |
| promoter | | | | | | | | | | |
| KBM-403 | | | | | | | | | | |
| (SHINETSU | | | | | | | | | | |
| Co.) | | | | | | | | | | |

| | | Comparative | Comparative |
|---|---|---|---|
| | Example 121 | Example 1 | Example 2 |
| Black | 10 | 10 | 10 |
| Colorant | | | |
| P-1-1 | | 44.46 | |
| P-1-140 | 25 | | |
| P-2-2 | | | 44.46 |
| P-2-66 | 19.46 | | |
| Acrylate- | 14.04 | 14.04 | 14.04 |
| based | | | |
| additive | | | |
| M140 | | | |
| (Miwon | | | |
| Co.) | | | |
| Acrylate- | 10 | 10 | 10 |
| based | | | |
| additive | | | |
| HDDA | | | |
| (Miwon | | | |
| Co.) | | | |
| Initiator TPO | 6 | 6 | 6 |
| Initiator NIT | 15 | 15 | 15 |
| Adhesion | 0.5 | 0.5 | 0.5 |
| promoter | | | |
| KBM-403 | | | |
| (SHINETSU | | | |
| Co.) | | | |

### [2. Preparation of Protective Layer]

### 1) Substrate Preparation Step

A 100 mm×100 mm bare glass substrate was prepared, and cleaning of the substrate was performed by performing UV ozone treatment and plasma treatment.

### 2) Ink Composition Application Step

Ink compositions each comprising the composition for protective layers of Comparative Examples 1 to 2 and Examples 1 to 121 prepared in Table 1 were supplied to a KM1024i inkjet printer head from Konica Minolta, and the ink compositions were ejected such that a film application thickness was 12 m to form a coating layer.

### 3) Exposure Step

A protective layer was prepared by performing a UV curing process on the coating layer applied to the substrate using a UV-LED light lamp from Phoseon Technology at a wavelength of 250 to 400 nm under conditions of a distance between the lamp and the coating layer of about 10 cm and an accumulated light dose of about 3 J/cm².

### 3. [Measurement of Hardness of Protective Layer]

The hardness of the protective layer was evaluated using a pencil hardness test method (KS M ISO 15184 test standard). A pencil for hardness measurement is selected, the pencil is held upright and abraded with sandpaper to make it flat, and then the pencil is fixed using a pencil hardness tester. After fixing the protective layers prepared in the Comparative Examples and Examples to a stage, the pencil to be tested is fixed at an angle of 45 degrees, the weight of a weight is adjusted to 750 g, and the speed is set to 100 mm/min. When the surface of the protective layer is scratched, the hardness is evaluated according to whether the surface is damaged, and the results are shown in Table 2.

### <Hardness Evaluation Criteria>

Low hardness B<HB<F<1H<2H High hardness

TABLE 2

| | Hardness |
|---|---|
| Comparative Example 1 | B |
| Comparative Example 2 | HB |
| Example 1 | 1H |
| Example 2 | 1H |
| Example 3 | 1H |
| Example 4 | 1H |
| Example 5 | 2H |
| Example 6 | 2H |
| Example 7 | 1H |
| Example 8 | 1H |
| Example 9 | 1H |
| Example 10 | 1H |
| Example 11 | 1H |
| Example 12 | 1H |
| Example 13 | 2H |
| Example 14 | 1H |
| Example 15 | 1H |
| Example 16 | 1H |
| Example 17 | 1H |
| Example 18 | 1H |
| Example 19 | 1H |
| Example 20 | 2H |
| Example 21 | 2H |
| Example 22 | 1H |
| Example 23 | 1H |
| Example 24 | 1H |
| Example 25 | 1H |
| Example 26 | 1H |
| Example 27 | 1H |
| Example 28 | 2H |
| Example 29 | 1H |
| Example 30 | 1H |
| Example 31 | 1H |
| Example 32 | 1H |
| Example 33 | 1H |
| Example 34 | 1H |
| Example 35 | 2H |
| Example 36 | 2H |
| Example 37 | 1H |
| Example 38 | 1H |
| Example 39 | 1H |
| Example 40 | 1H |
| Example 41 | 1H |
| Example 42 | 1H |
| Example 43 | 2H |
| Example 44 | 1H |
| Example 45 | 1H |
| Example 46 | 1H |
| Example 47 | 1H |
| Example 48 | 1H |
| Example 49 | 1H |
| Example 50 | 1H |
| Example 51 | 2H |
| Example 52 | 2H |
| Example 53 | 1H |
| Example 54 | 1H |
| Example 55 | 1H |
| Example 56 | 1H |
| Example 57 | 1H |
| Example 58 | 1H |
| Example 59 | 2H |
| Example 60 | 1H |
| Example 61 | 1H |
| Example 62 | 1H |
| Example 63 | 1H |
| Example 64 | 1H |
| Example 65 | 1H |
| Example 66 | 1H |
| Example 67 | 1H |
| Example 68 | 1H |
| Example 69 | 1H |
| Example 70 | 2H |
| Example 71 | 2H |
| Example 72 | 1H |
| Example 73 | 1H |
| Example 74 | 1H |
| Example 75 | 1H |
| Example 76 | 1H |
| Example 77 | 1H |
| Example 78 | 1H |
| Example 79 | 1H |
| Example 80 | 1H |
| Example 81 | 1H |
| Example 82 | 1H |
| Example 83 | 2H |
| Example 84 | 2H |
| Example 85 | 1H |
| Example 86 | 1H |
| Example 87 | 1H |
| Example 88 | 1H |
| Example 89 | 1H |
| Example 90 | 1H |
| Example 91 | 1H |
| Example 92 | 1H |
| Example 93 | 1H |
| Example 94 | 1H |
| Example 95 | 1H |
| Example 96 | 1H |
| Example 97 | 2H |
| Example 98 | 2H |
| Example 99 | 1H |
| Example 100 | 1H |
| Example 101 | 1H |
| Example 102 | 1H |
| Example 103 | 1H |
| Example 104 | 1H |
| Example 105 | 1H |
| Example 106 | 1H |
| Example 107 | 1H |
| Example 108 | 1H |
| Example 109 | 1H |
| Example 110 | 2H |
| Example 111 | 2H |
| Example 112 | 1H |
| Example 113 | 1H |
| Example 114 | 1H |
| Example 115 | 1H |
| Example 116 | 1H |
| Example 117 | 1H |
| Example 118 | 1H |
| Example 119 | 2H |
| Example 120 | 2H |
| Example 121 | 1H |

In Table 2, it can be confirmed that the Examples have superior hardness compared to the Comparative Examples. This is considered to be a result of the fact that when an epoxy-based monomer and an oxetane-based monomer are used together, the effect of improving the crosslinking density of the epoxy-based monomer and the compensation for flexibility of the oxetane-based monomer are balanced, so that an intermediate strength range of 1H to 2H can be stably secured, the epoxy-based monomer provides basic strength through an inorganic-organic hybrid structure, and the oxetane-based monomer prevents brittleness by controlling the crosslinking reaction rate.

On the other hand, it was confirmed that when only an epoxy-based monomer is used as in Comparative Example 1, the crosslinking density excessively increases and brittleness is intensified. Although high hardness can be expected, it was confirmed that it was actually evaluated as grade B in the pencil test due to the occurrence of cracks. In particular, the flexibility provided by the oxetane-based monomer is insufficient, so the brittleness of the film increases, and since there is no shock absorption capability, scratch sensitivity may increase in actual application.

It was confirmed that when the oxetane-based monomer is used alone as in Comparative Example 2, the formation of a crosslinking network is incomplete, resulting in a weak surface of grade HB. This is considered to be a result of poor load distribution capability due to the absence of a three-dimensional network of the epoxy-based monomer.

The present invention is not limited to the embodiments but may be manufactured in various different forms.

The above description is merely an illustrative explanation of the present invention, and those of ordinary skill in the art to which the present invention pertains will be able to make various modifications without departing from the essential characteristics of the present invention.

Therefore, the embodiments disclosed in the present invention are not intended to limit the present invention but to explain it, and the spirit and scope of the present invention are not limited by these embodiments. The scope of protection of the present invention should be interpreted by the claims, and all technologies within the scope equivalent thereto should be interpreted as being included in the scope of rights of the present invention.

What is claimed is:

1. A composition for protective layer comprising:
a colorant;
a first monomer comprising an oxygen-containing cyclic group; and
a second monomer comprising an oxygen-containing cyclic group.

2. The composition for protective layer of claim 1, wherein the first monomer comprises an epoxy group, and
the second monomer comprises an oxetane group.

3. The composition for protective layer of claim 1, wherein the first monomer is a compound represented by Chemical Formula 1 below: 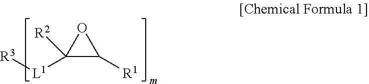
in Chemical Formula 1,
m is an integer of 1 to 4,
R¹ and R² are each independently selected from the group consisting of hydrogen; deuterium; a carbonyl group; an ether group; an ester group; a C₁-C₃₀ alkyl group; a C₂-C₃₀ alkenyl group; a C₂-C₃₀ alkynyl group; a C₃-C₃₀ cycloalkyl group; a C₁-C₃₀ alkoxy group; a C₁-C₃₀ alkylamine group; a C₆-C₃₀ aryl group; a C₂-C₃₀ heterocyclic group comprising at least one heteroatom selected from O, N, S, Si, and P; a C₆-C₃₀ aryloxy group; a C₆-C₃₀ arylamine group; and combinations thereof,
R³ is selected from the group consisting of hydrogen; deuterium; a carbonyl group; an ether group; an ester group; a C₁-C₃₀ alkyl group; a C₂-C₃₀ alkenyl group; a C₂-C₃₀ alkynyl group; a C₃-C₃₀ cycloalkyl group; a C₁-C₃₀ alkoxy group; a C₁-C₃₀ alkylamine group; a C₆-C₃₀ aryl group; a C₂-C₃₀ heterocyclic group comprising at least one heteroatom selected from O, N, S, Si, and P; a C₆-C₃₀ aryloxy group; a C₆-C₃₀ arylamine group; and combinations thereof,
L¹ is selected from the group consisting of a single bond; a carbonyl group; an ether group; an ester group; a C₁-C₃₀ alkylene group; a C₂-C₃₀ alkenylene group; a C₂-C₃₀ alkynylene group; a C₃-C₃₀ cycloalkylene group; a C₃-C₃₀ cycloalkenylene group; a C₁-C₃₀ alkoxylene group; a C₁-C₃₀ alkylamine group; a C₆-C₃₀ arylene group; a C₂-C₃₀ heterocyclic group comprising at least one heteroatom selected from O, N, S, Si, and P; a C₆-C₃₀ aryloxy group; a C₆-C₃₀ arylamine group; and combinations thereof,
R¹ and L¹ may be bonded to each other to form a ring, and
in R¹ to R³ and L¹, the alkyl group, alkenyl group, alkynyl group, cycloalkyl group, alkoxy group, alkylamine group, aryl group, heterocyclic group, aryloxy group, arylamine group, alkylene group, alkenylene group, alkynylene group, cycloalkylene group, cycloalkenylene group, alkoxylene group, and arylene group may each independently be substituted with one or more substituents selected from the group consisting of deuterium, a halogen group, a hydroxy group, a nitrile group, a nitro group, a C₁-C₃₀ alkyl group, a C₁-C₃₀ alkoxy group, a C₁-C₃₀ alkylamine group, a C₁-C₃₀ alkylsilyl group, a C₁-C₃₀ alkylthiophene group, a C₂-C₃₀ alkenyl group, a C₂-C₃₀ alkynyl group, a C₃-C₃₀ cycloalkyl group, a C₆-C₃₀ aryl group, a C₆-C₃₀ aryloxy group, a C₆-C₃₀ arylamine group, a C₆-C₃₀ arylsilyl group, a C₆-C₃₀ arylthiophene group, a C₆-C₃₀ aryl group substituted with deuterium, a C₇-C₃₀ arylalkyl group, a C₈-C₃₀ arylalkenyl group, a silane group, a siloxane group, a boron group, a thiol group, a germanium group, and a C₂-C₃₀ heterocyclic group, and the substituted substituent may be further substituted with one or more substituents selected from the substituents.

4. The composition for protective layer of claim 1, wherein the first monomer is one or more of compounds represented by Chemical Formulas P-1-1 to P-1-140 below:

[chemical structure]

[chemical structure]

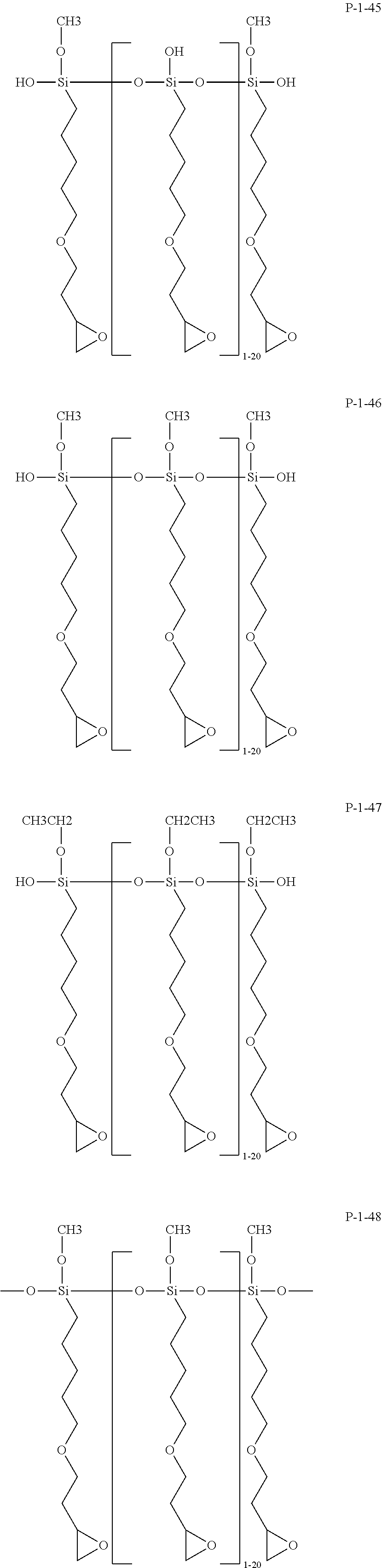

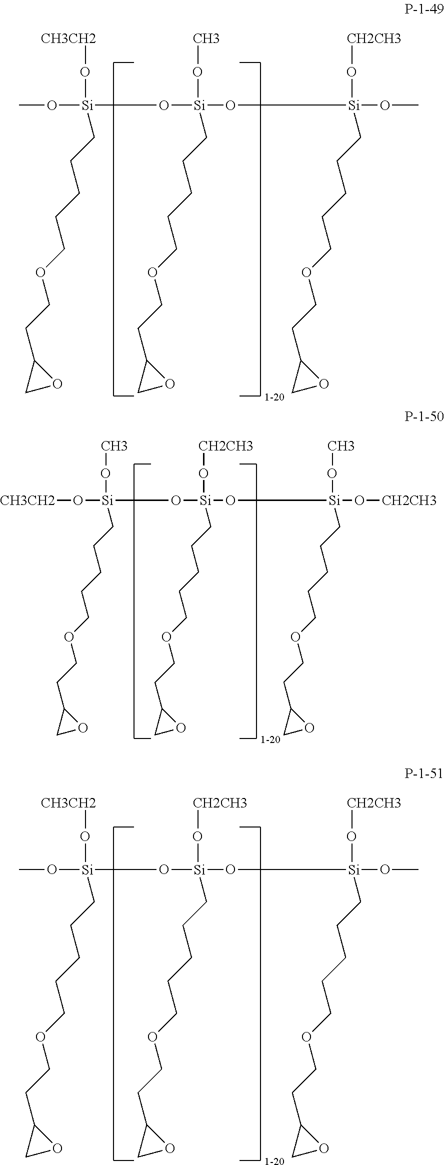

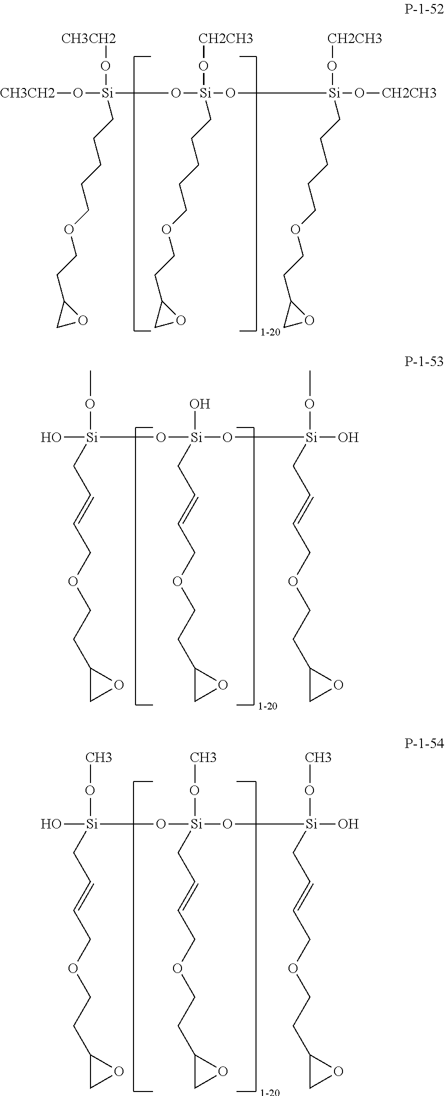

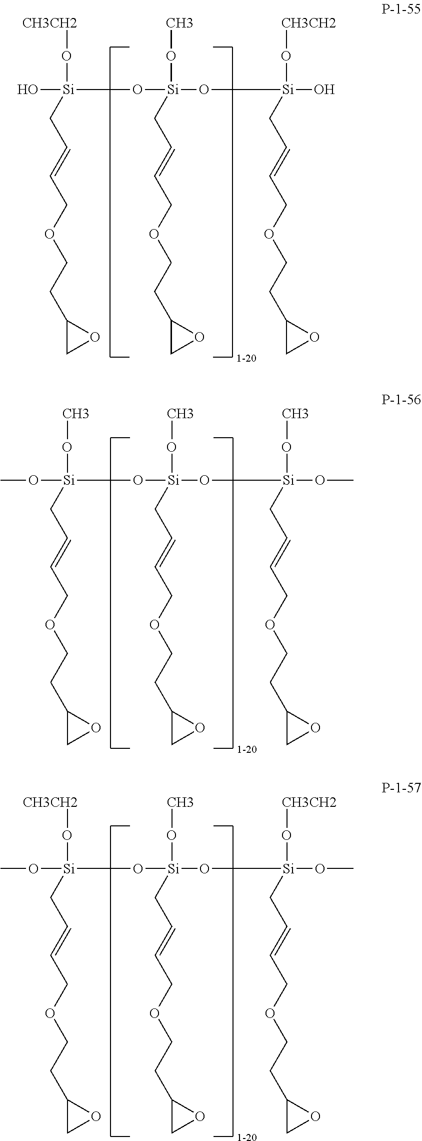

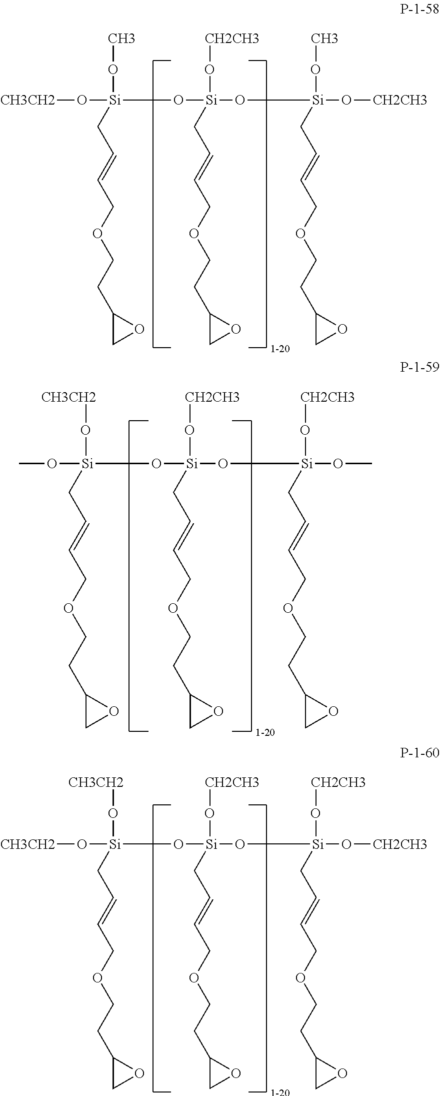

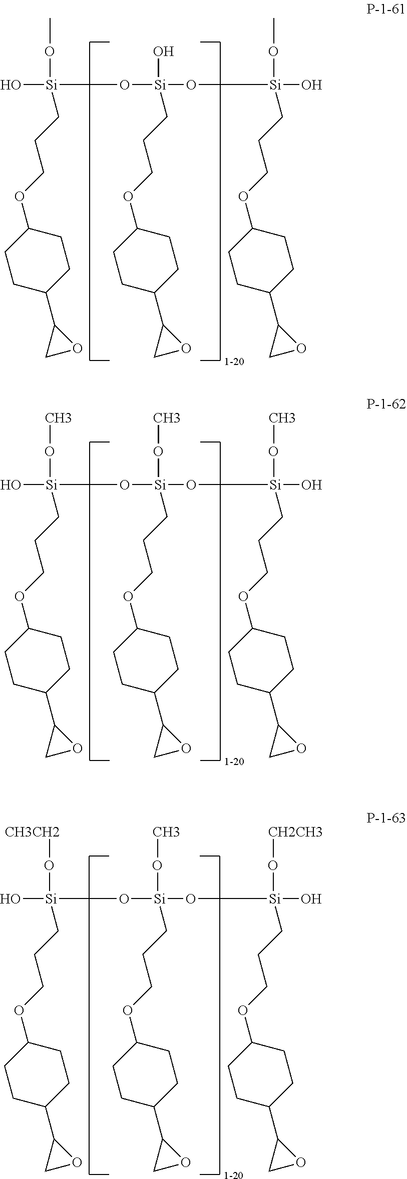

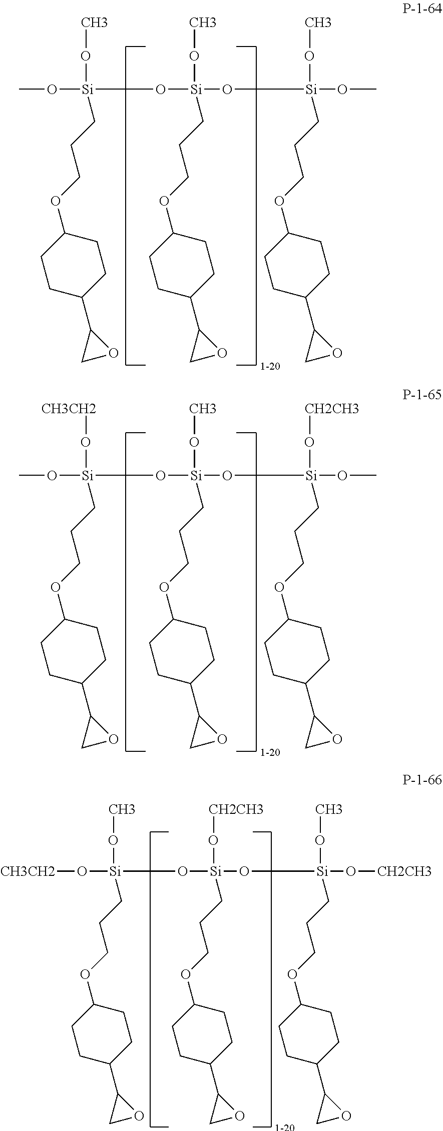

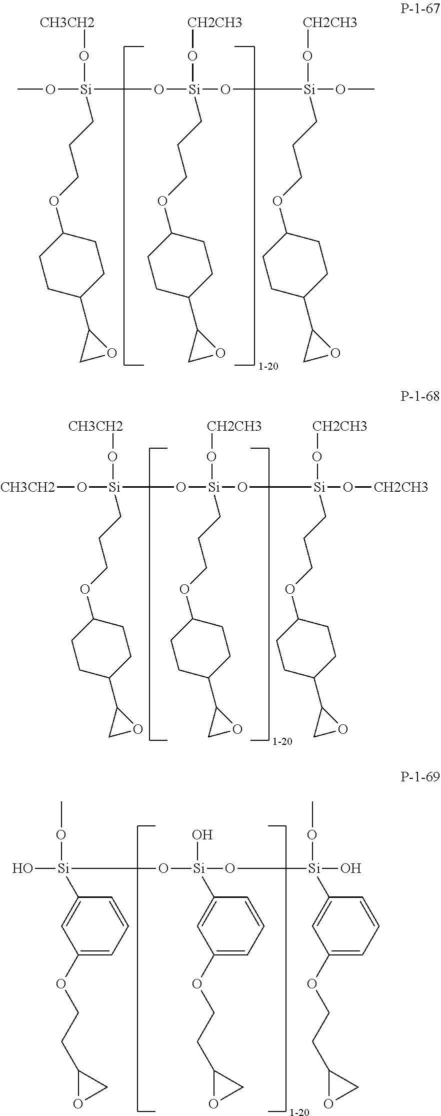

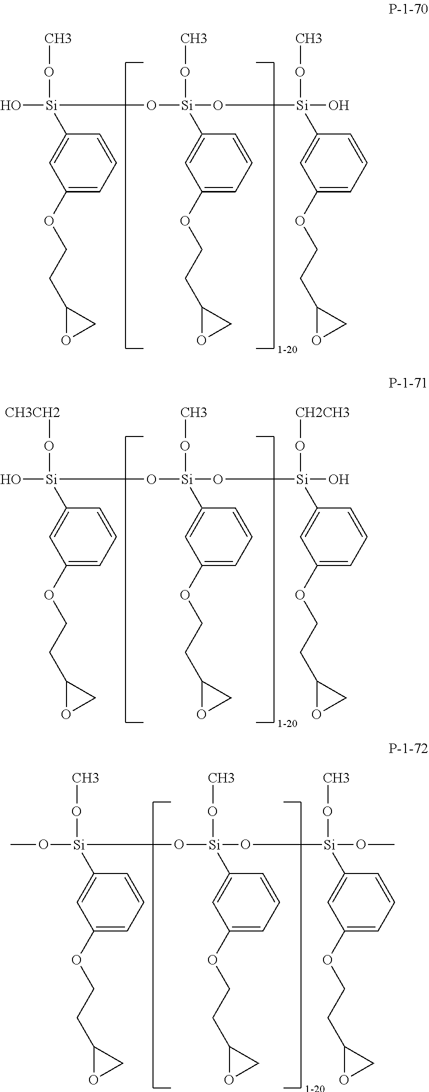

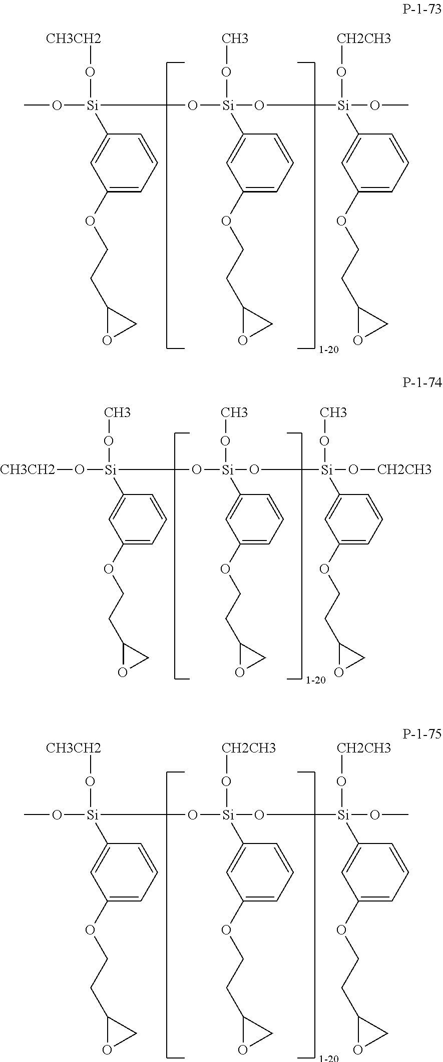

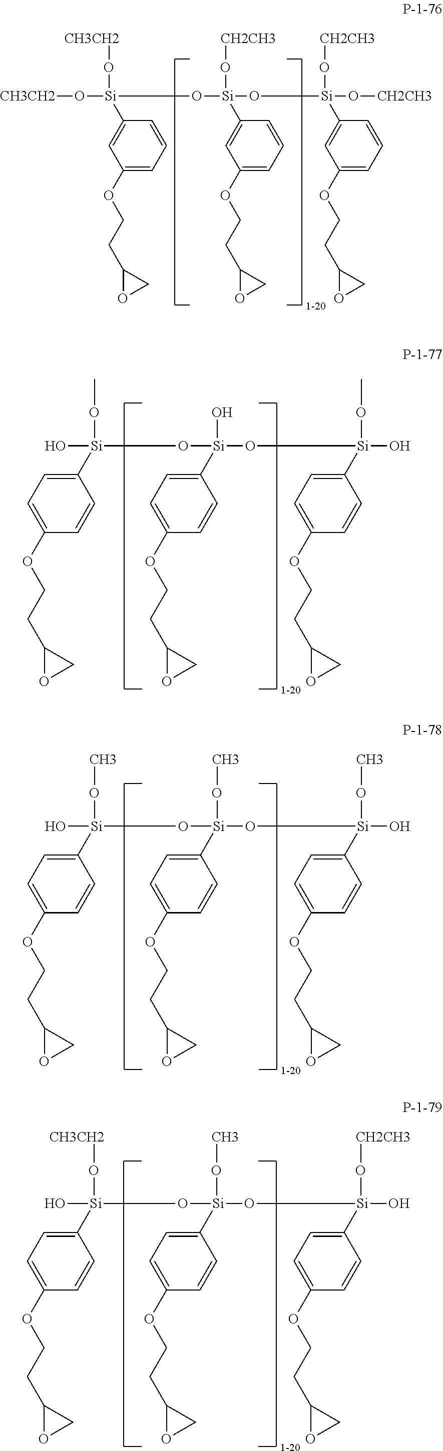

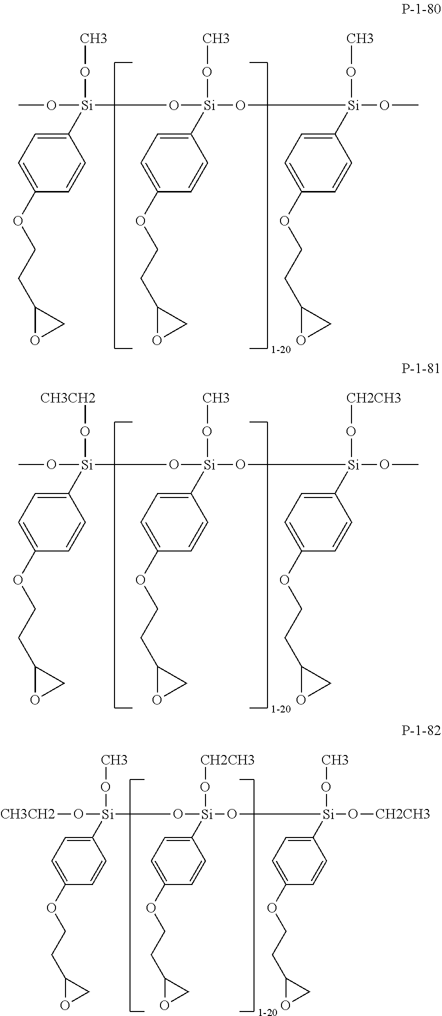

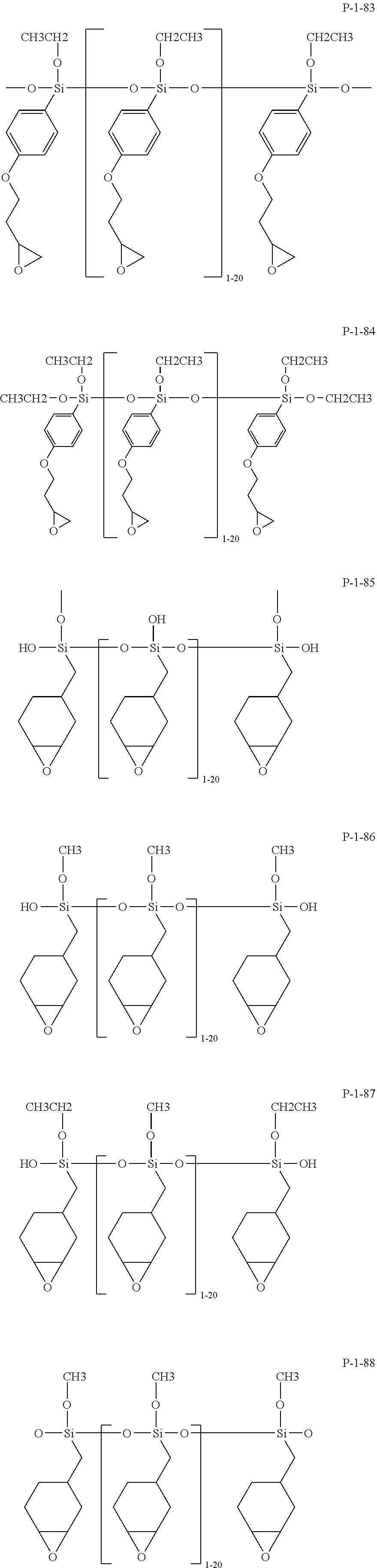

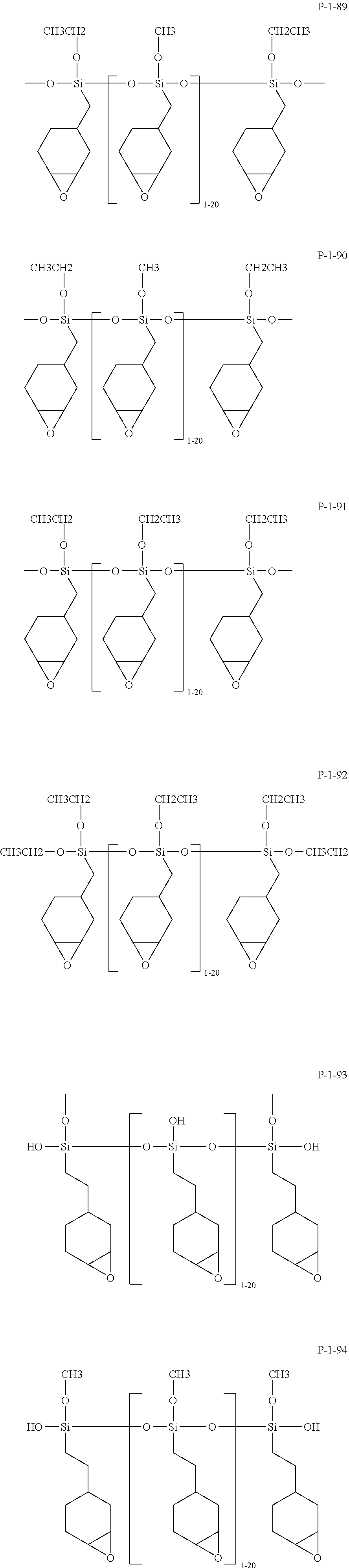

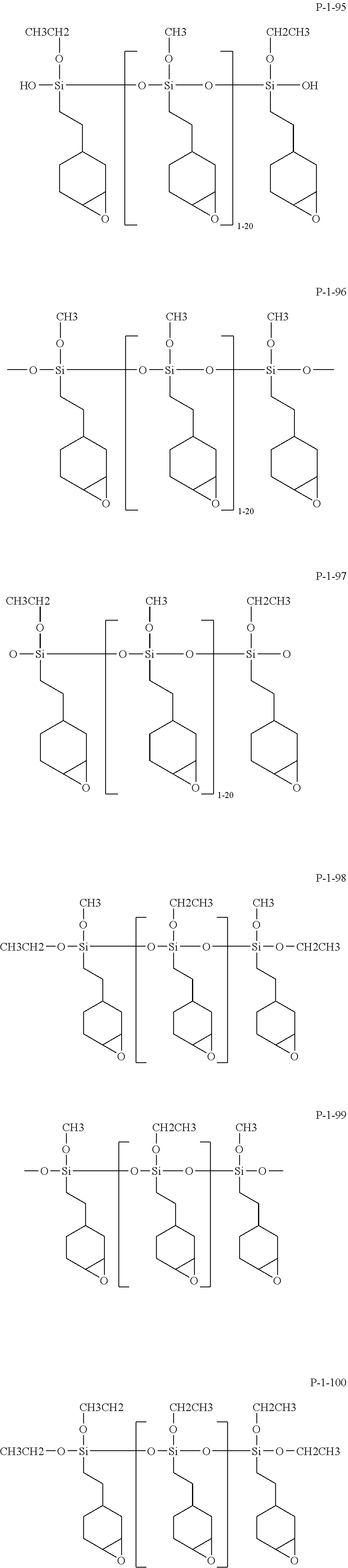

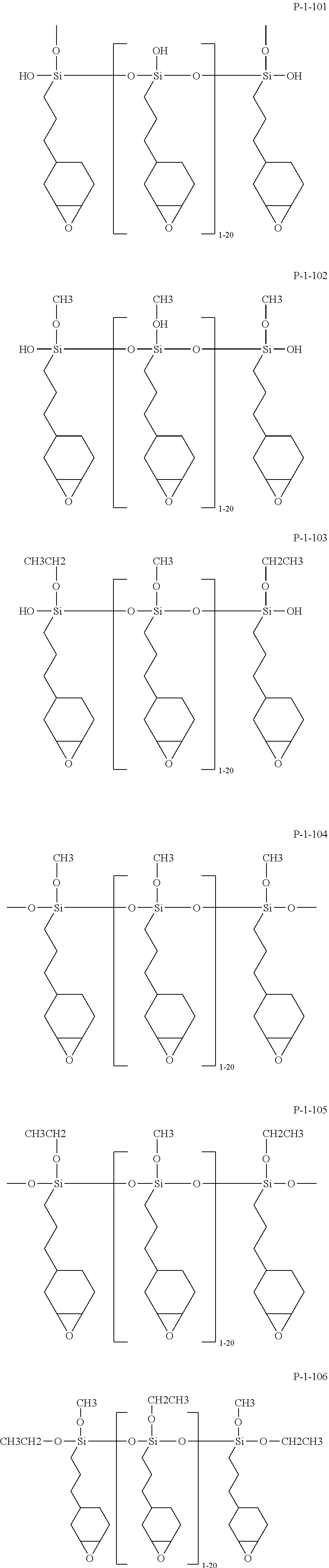

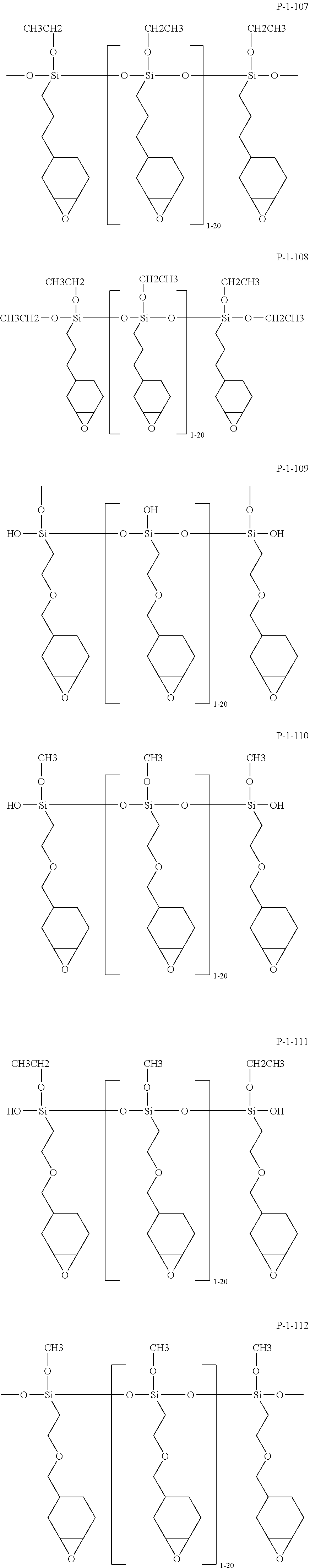

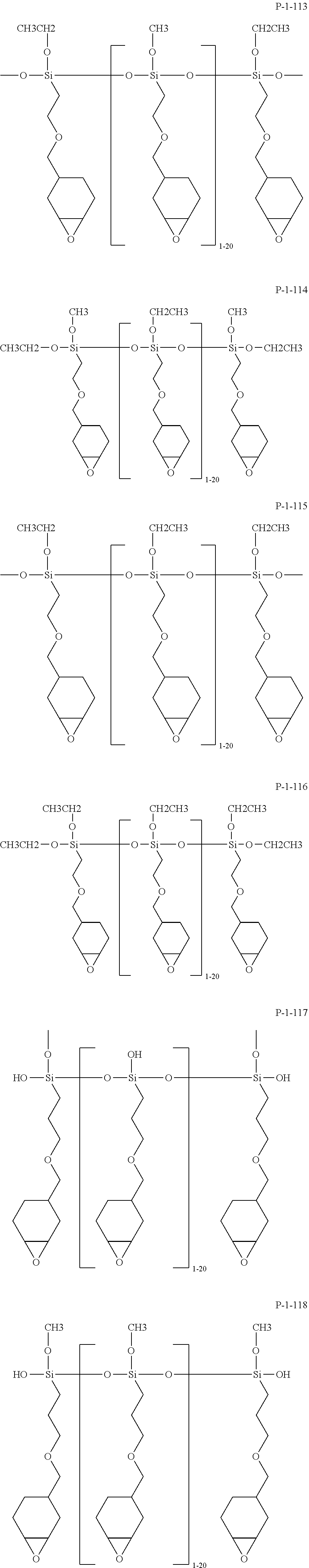

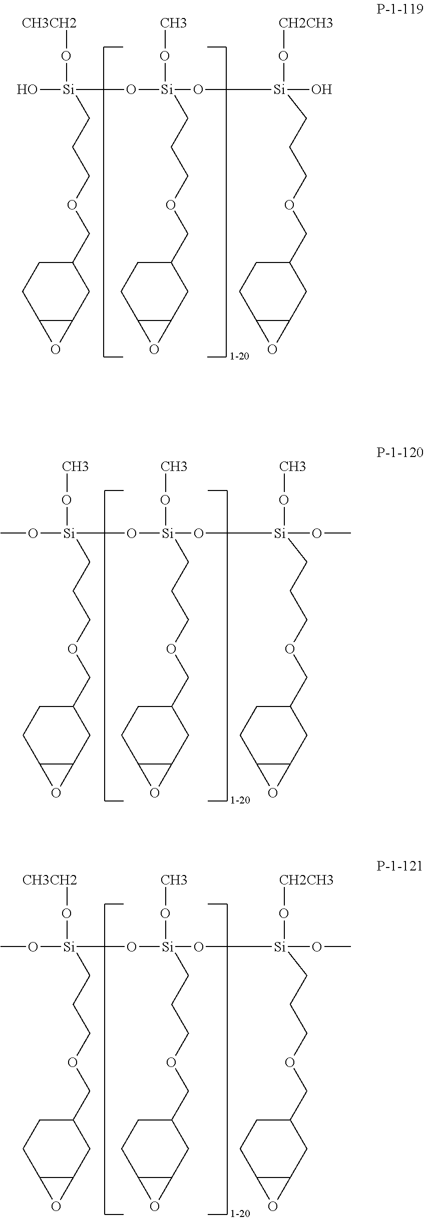

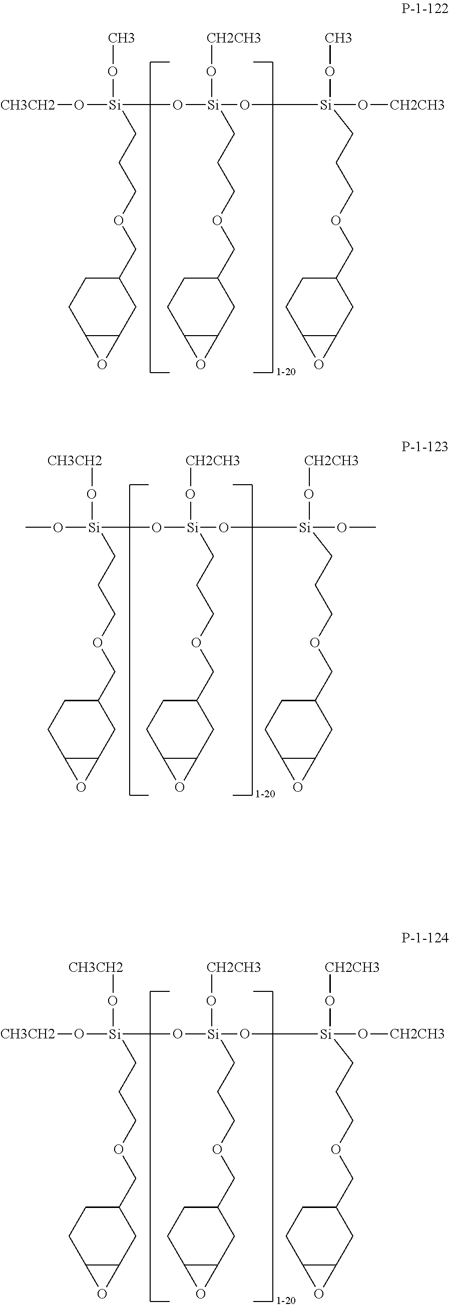

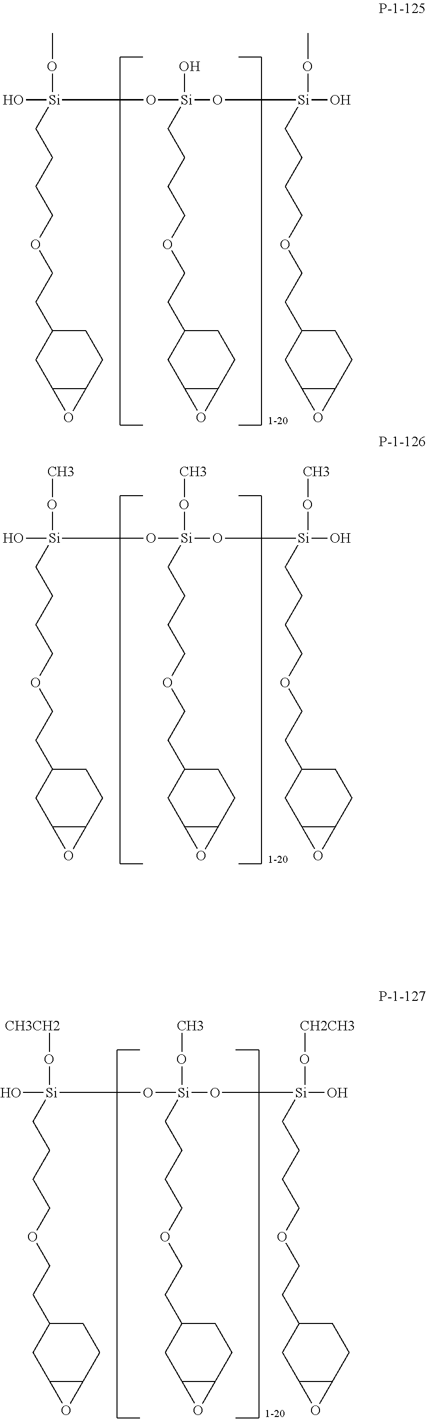

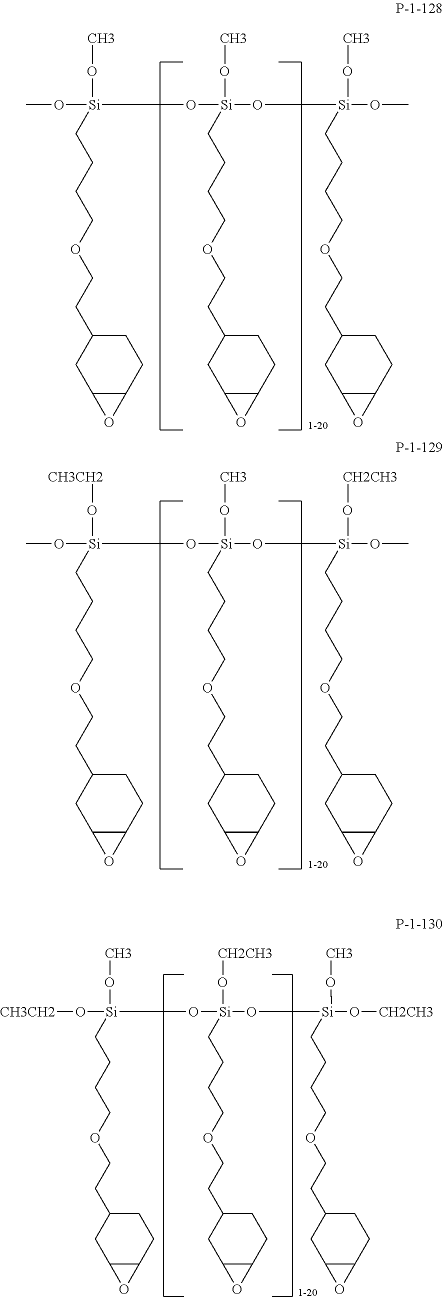

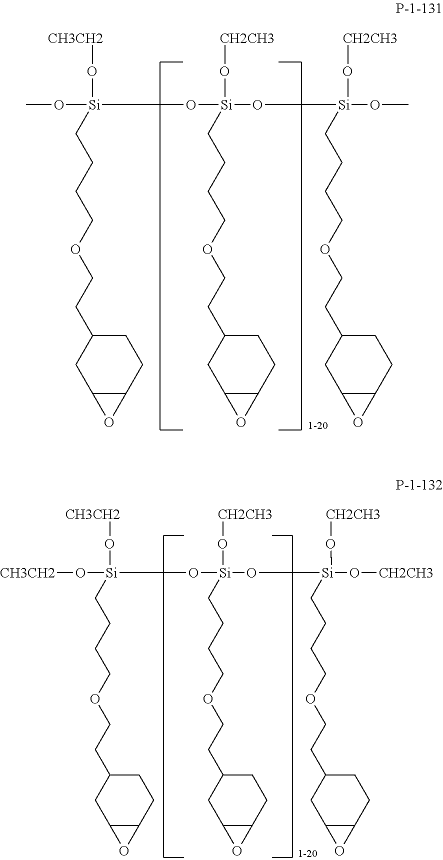

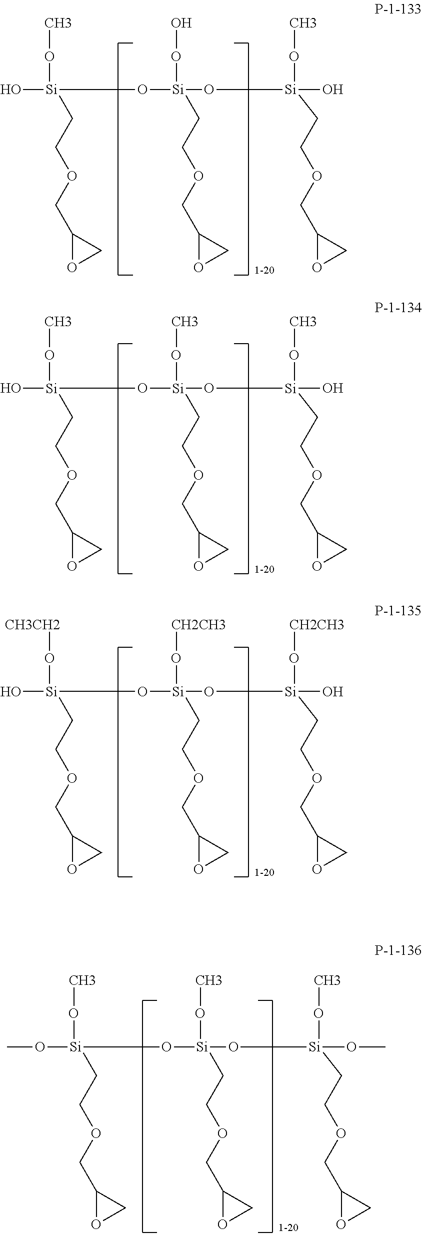

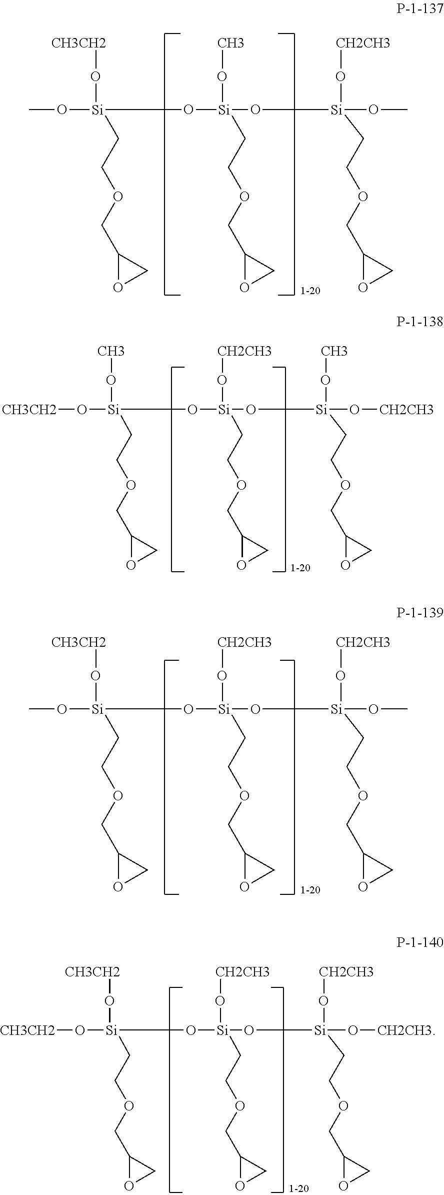

5. The composition for protective layer of claim 1, wherein the second monomer is a compound represented by Chemical Formula 2 below: 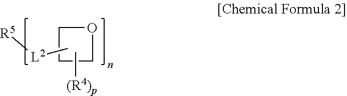
in Chemical Formula 2,
n is an integer of 1 to 4,
p is an integer of 0 to 5,
R⁴ is selected from the group consisting of hydrogen; deuterium; a hydroxy group; a nitrile group; an acrylate group; a carbonyl group; an ether group; an ester group; a C₁-C₃₀ alkyl group; a C₂-C₃₀ alkenyl group; a C₂-C₃₀ alkynyl group; a C₃-C₃₀ cycloalkyl group; a C₁-C₃₀ alkoxy group; a C₁-C₃₀ alkylamine group; a C₆-C₃₀ aryl group; a C₂-C₃₀ heterocyclic group comprising at least one heteroatom selected from O, N, S, Si, and P; a C₆-C₃₀ aryloxy group; a C₆-C₃₀ arylamine group; —N(R′)(R″); and combinations thereof, and when p is an integer of 2 or more, R⁴ are the same as or different from each other,
R⁵ is selected from the group consisting of hydrogen; deuterium; a hydroxy group; an acrylate group; a carbonyl group; an ether group; an ester group; a C₁-C₃₀ alkyl group; a C₂-C₃₀ alkenyl group; a C₂-C₃₀ alkynyl group; a C₃-C₃₀ cycloalkyl group; a C₁-C₃₀ alkoxy group; a C₁-C₃₀ alkylamine group; a C₆-C₃₀ aryl group; a C₂-C₃₀ heterocyclic group comprising at least one heteroatom selected from O, N, S, Si, and P; a C₆-C₃₀ aryloxy group; a C₆-C₃₀ arylamine group; —N(R′)(R″); and combinations thereof,
L² is selected from the group consisting of a single bond; a carbonyl group; an ether group; an ester group; a C₁-C₃₀ alkylene group; a C₂-C₃₀ alkenylene group; a C₂-C₃₀ alkynylene group; a C₃-C₃₀ cycloalkylene group; a C₃-C₃₀ cycloalkenylene group; a C₁-C₃₀ alkoxylene group; a C₁-C₃₀ alkylamine group; a C₆-C₃₀ arylene group; a C₂-C₃₀ heterocyclic group comprising at least one heteroatom selected from O, N, S, Si, and P; a C₆-C₃₀ aryloxy group; a C₆-C₃₀ arylamine group; and combinations thereof,
R′ and R″ are each independently selected from the group consisting of hydrogen; deuterium; a hydroxy group; an acrylate group; a carbonyl group; an ether group; an ester group; a C₁-C₃₀ alkyl group; a C₂-C₃₀ alkenyl group; a C₂-C₃₀ alkynyl group; a C₃-C₃₀ cycloalkyl group; a C₁-C₃₀ alkoxy group; a C₁-C₃₀ alkylamine group; a C₆-C₃₀ aryl group; a C₂-C₃₀ heterocyclic group comprising at least one heteroatom selected from O, N, S, Si, and P; a C₆-C₃₀ aryloxy group; a C₆-C₃₀ arylamine group; and combinations thereof, and
in R⁴, R⁵, R′, R″, and L², the alkyl group, alkenyl group, alkynyl group, cycloalkyl group, alkoxy group, alkylamine group, aryl group, heterocyclic group, aryloxy group, arylamine group, alkylene group, alkenylene group, alkynylene group, cycloalkylene group, cycloalkenylene group, alkoxylene group, and arylene group may each independently be substituted with one or more substituents selected from the group consisting of deuterium, a halogen group, a hydroxy group, a nitrile group, a nitro group, a C₁-C₃₀ alkyl group, a C₁-C₃₀ alkoxy group, a C₁-C₃₀ alkylamine group, a C₁-C₃₀ alkylsilyl group, a C₁-C₃₀ alkylthiophene group, a C₂-C₃₀ alkenyl group, a C₂-C₃₀ alkynyl group, a C₃-C₃₀ cycloalkyl group, a C₆-C₃₀ aryl group, a C₆-C₃₀ aryloxy group, a C₆-C₃₀ arylamine group, —N(R′)(R″) (wherein R′ and R″ may be defined as described above), a C₆-C₃₀ arylsilyl group, a C₆-C₃₀ arylthiophene group, a C₆-C₃₀ aryl group substituted with deuterium, a C₇-C₃₀ arylalkyl group, a C₈-C₃₀ arylalkenyl group, a silane group, a siloxane group, a boron group, a thiol group, a germanium group, and a C₂-C₃₀ heterocyclic group, and the substituted substituent may be further substituted with one or more substituents selected from the substituents.

6. The composition for protective layer of claim 5, wherein the second monomer is a compound represented by any one of Chemical Formula 2-1 and Chemical Formula 2-2 below: 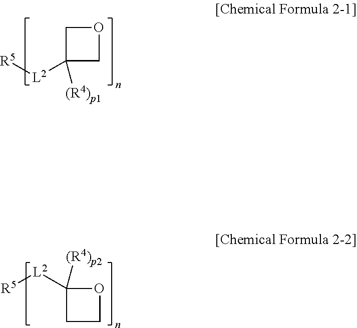
in Chemical Formula 2-1 and Chemical Formula 2-2,
n, R⁴, R⁵, and L² are defined the same as the definitions of n, R⁴, R⁵, and L² defined in Chemical Formula 2, and
p1 and p2 are each an integer of 0 or 1.

7. The composition for protective layer of claim 1, wherein the second monomer is one or more of compounds represented by Chemical Formulas P-2-1 to P-2-68 below:

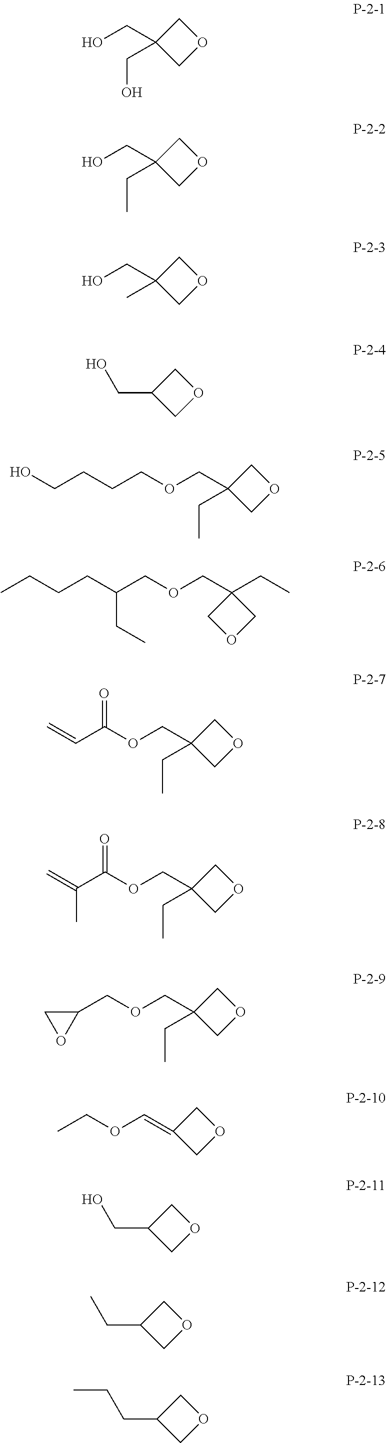

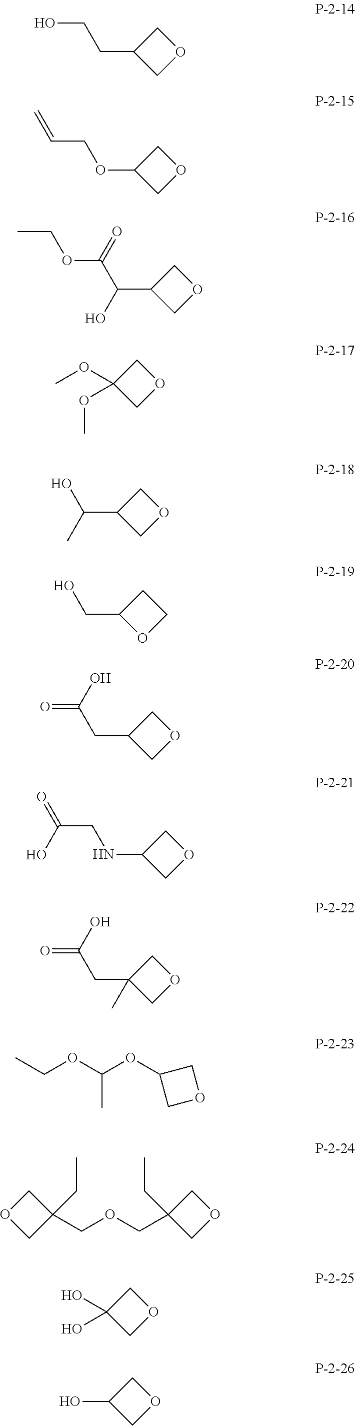

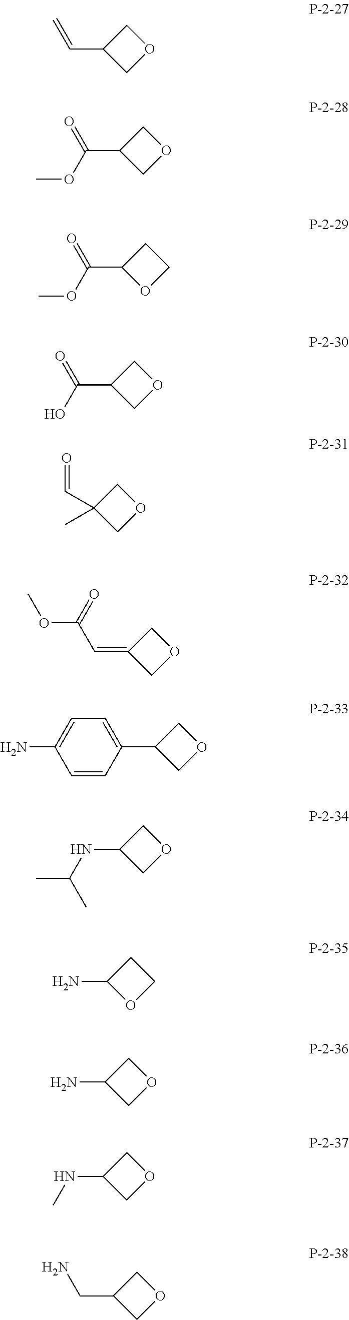

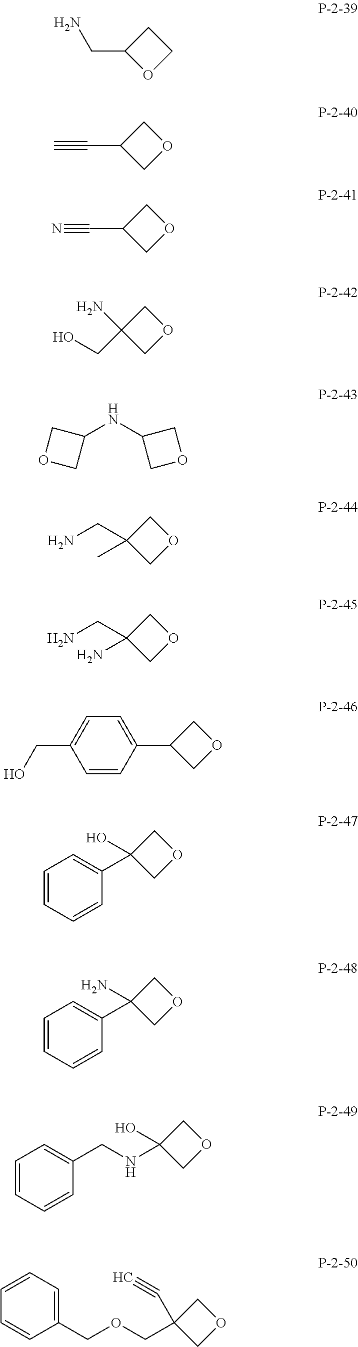

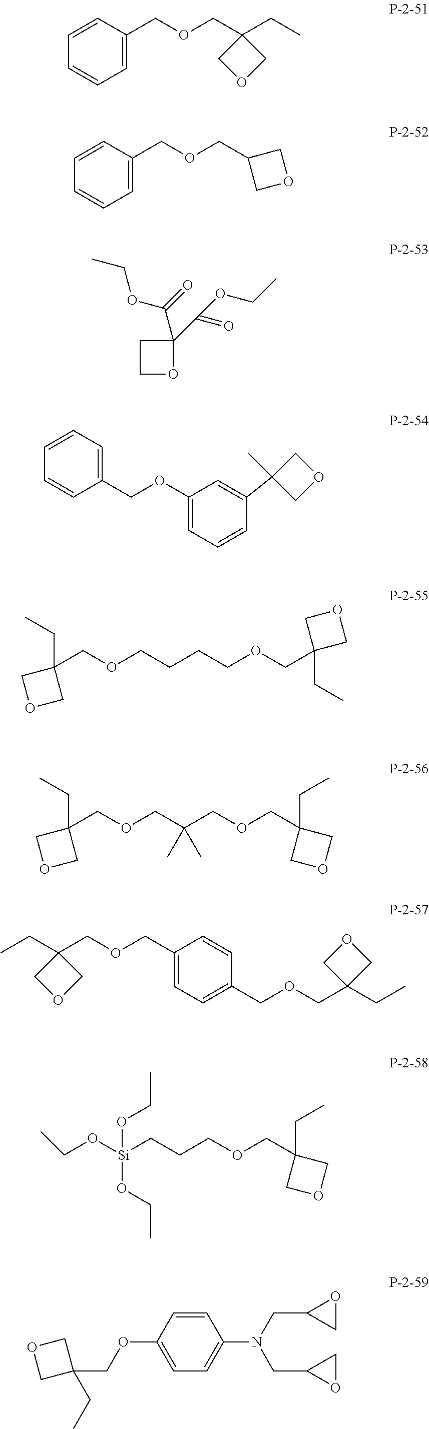

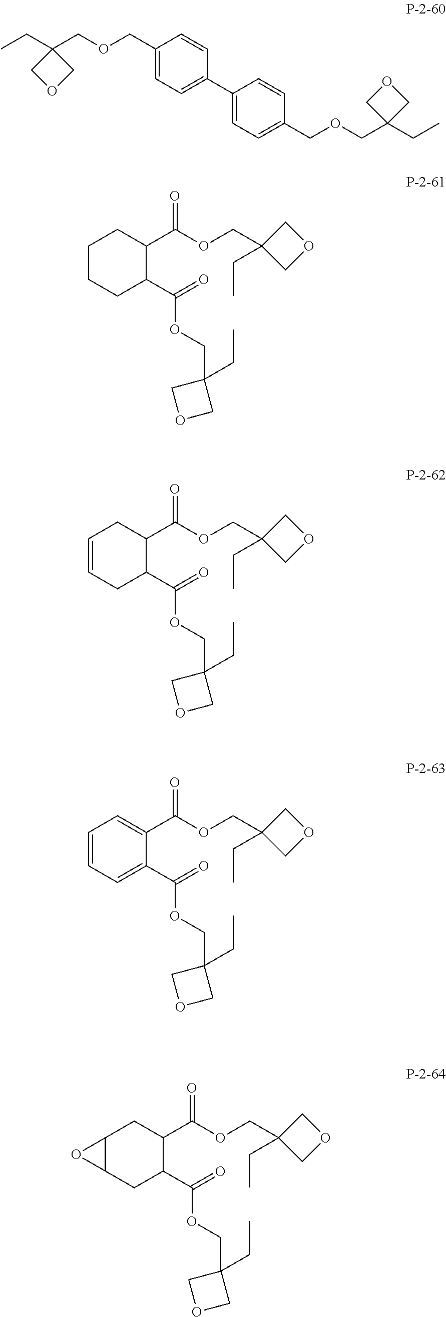 [SMILES: CCC1(COCc2ccc(-c3ccc(COCC4(CC)COC4)cc3)cc2)COC1 ; CCC1(COC(=O)C2CCCCC2C(=O)OCC2(CC)COC2)COC1 ; CCC1(COC(=O)C2CC=CCC2C(=O)OCC2(CC)COC2)COC1 ; CCC1(COC(=O)c2ccccc2C(=O)OCC2(CC)COC2)COC1 ; CCC1(COC(=O)C2CC3OC3CC2C(=O)OCC2(CC)COC2)COC1]

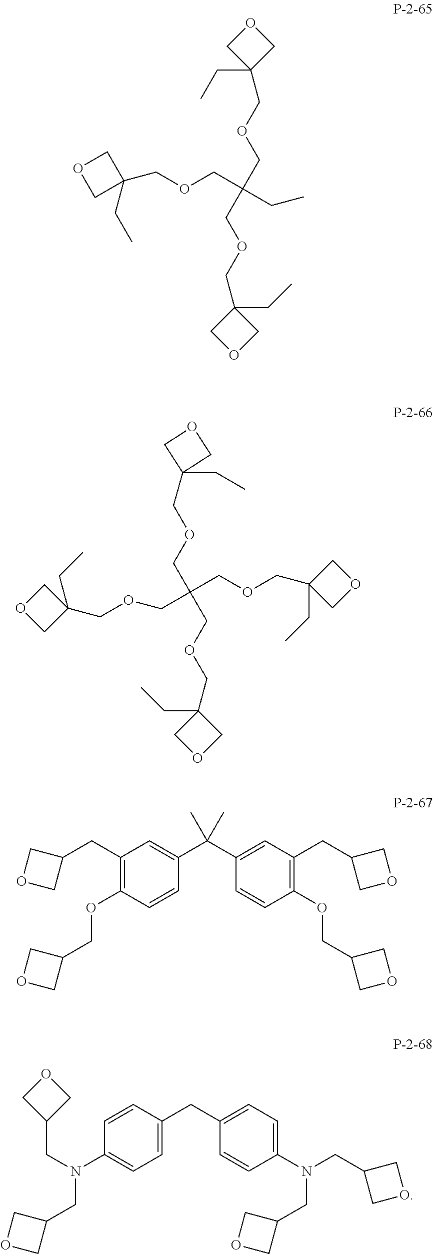 [SMILES: CCC1(COCC(CC)(COCC2(CC)COC2)COCC2(CC)COC2)COC1 ; CCC1(COCC(COCC2(CC)COC2)(COCC2(CC)COC2)COCC2(CC)COC2)COC1 ; CC(C)(c1ccc(OCC2COC2)c(CC2COC2)c1)c1ccc(OCC2COC2)c(CC2COC2)c1 ; c1cc(N(CC2COC2)CC2COC2)ccc1Cc1ccc(N(CC2COC2)CC2COC2)cc1]

8. The composition for protective layer of claim 1, wherein the colorant comprises a black pigment.

9. The composition for protective layer of claim 1, further comprising an initiator.

10. The composition for protective layer of claim 9, wherein the initiator is a cationic initiator.

11. A protective layer comprising the composition for protective layer of claim 1.

12. A display device comprising:
a substrate;
a pixel array layer on the substrate; and
a protective layer disposed under the substrate and comprising the composition for protective layer of claim 1.

13. The display device of claim 12, wherein the protective layer is disposed to contact the substrate.
